(19) United States
(12) Patent Application Publication
(10) Pub. No.: US 2026/0220338 A1
(43) Pub. Date: Jul. 30, 2026

(54) Technique For Generating Expected Inference Simulation Result Of Artificial Intelligence Model

(71) Applicant: NOTA, INC., Daejeon (KR)

(72) Inventors: Shinkook CHOI, Daejeon (KR); TAIREN PIAO, Daejeon (KR); Thibault Castells, Daejeon (KR); Beomwoo KANG, Daejeon (KR); Donggeun KIM, Daejeon (KR); Jinsol KIM, Daejeon (KR); Huiseong GIM, Daejeon (KR); Jinhyeok PARK, Daejeon (KR); Chanil PARK, Daejeon (KR); Hyungkeun PARK, Daejeon (KR); Junho SHIN, Daejeon (KR); Kyunghwan SHIM, Daejeon (KR); Jaewoong YUN, Daejeon (KR); Dongryeol LEE, Daejeon (KR); Seongun HONG, Daejeon (KR); Jaewoo Song, Tseung Kwan O (HK)

(73) Assignee: NOTA, INC., Daejeon (KR)

(21) Appl. No.: 19/346,223

(22) Filed: Sep. 30, 2025

(30) Foreign Application Priority Data
Jan. 24, 2025 (KR) 10-2025-0011968
Jan. 25, 2025 (KR) 10-2025-0012056
Feb. 20, 2025 (KR) 10-2025-0022595
Feb. 26, 2025 (KR) 10-2025-0025384
Aug. 28, 2025 (KR) 10-2025-0120844

(51) Int. Cl. G06F 30/27

(52) U.S. Cl. CPC G06F 30/27

(57) ABSTRACT

A method comprises receiving an intermediate representation structure that represents a target artificial intelligence model, with a node corresponding to an atomic operator independent of a framework and a module dependent on a target framework of the target artificial intelligence model, wherein the intermediate representation structure has a hierarchical structure in which one or more nodes constitute the module, receiving target platform information for identifying a target platform on which the target artificial intelligence model is to be executed and input data to be used in a simulation process of the target artificial intelligence model and generating an expected inference simulation result for a case where the target artificial intelligence model with the input data is to be executed on the target platform, without executing the target artificial intelligence model on the target platform, by using the intermediate representation structure, the target platform information, and the input data.

### CROSS-REFERENCE TO RELATED APPLICATIONS

This application claims priority to and the benefit of Korean Patent Application No. 10-2025-0120844 filed in the Korean Intellectual Property Office on 28 Aug. 2025, Korean Patent Application No. 10-2025-0011968 filed in the Korean Intellectual Property Office on 24 Jan. 2025, Korean Patent Application No. 10-2025-0012056 filed in the Korean Intellectual Property Office on 25 Jan. 2025, Korean Patent Application No. 10-2025-0022595 filed in the Korean Intellectual Property Office on 20 Feb. 2025, and Korean Patent Application No. 10-2025-0025384 filed in the Korean Intellectual Property Office on 26 Feb. 2025 the entire contents of which are incorporated herein by reference.

### TECHNICAL FIELD

This disclosure relates to artificial intelligence technology, and more particularly, to a simulation of an artificial intelligence model.

### BACKGROUND ART

With the advancement of artificial intelligence technology, artificial intelligence models are showing innovative results in various fields such as image recognition, natural language processing, speech recognition, etc. These artificial intelligence models are mostly designed to perform specific tasks by learning a vast amount of data, and their performance tends to be proportional to the complexity of the model and the amount of training data. As the complexity of the model increases, the required amount of computation and memory usage also increase exponentially.

In particular, as the processing speed of processors increases, large-scale artificial intelligence models are emerging, and these large-scale artificial intelligence models include parameters numbering in the billions. A vast amount of computing resources is required to train and perform inference on these models. The use of computing resources can lead to high operating costs in a cloud environment, and becomes a major limiting factor that makes the deployment and utilization of models difficult in environments with limited resources, such as edge devices.

To solve these problems, research on optimization techniques for artificial intelligence models is being conducted. Optimization techniques may include methods such as compression and quantization. For example, compression can reduce the size of a model and decrease unnecessary computations by removing parameters or connections that do not significantly contribute to the model's performance. Quantization can reduce memory usage and the amount of computation by representing the model's parameters and activation values with a lower bit width.

European Patent Publication EP 4439275 A1 can be considered prior art.

### SUMMARY OF THE INVENTION

The present disclosure has been devised in response to the aforementioned background art, and has an object of efficiently achieving performance transformation or performance optimization of artificial intelligence models.

Technical objects of the present disclosure are not restricted to the technical object mentioned above. Other unmentioned technical objects will be apparently appreciated by those skilled in the art by referencing the following description.

According to an embodiment of the present disclosure, a method, performed by a computing device, for converting a source artificial intelligence model to a target artificial intelligence model for a framework transformation is disclosed. The method comprises: receiving the source artificial intelligence model executable in a first framework, transforming source operators included in the source artificial intelligence model into a source intermediate representation structure including source modules dependent on the first framework and nodes independent of a framework, generating a target intermediate representation structure including target modules dependent on a second framework and the nodes independent of a framework, by using information about the second framework to which the source artificial intelligence model is to be converted, and generating the target artificial intelligence model in which the source operators of the source artificial intelligence model are converted to target operators, by transforming the target modules of the target intermediate representation structure into the target operators executable in the second framework, wherein the source modules and the target modules are configured with a combination of the nodes, and each of the nodes corresponds to an atomic operator independent of a framework.

According to an embodiment of the present disclosure, the transforming the source operators into the source intermediate representation structure including the source modules dependent on the first framework and the nodes independent of a framework comprises: generating the source intermediate representation structure that represents the source artificial intelligence model with a source module and a node, by transforming each of the source operators constituting the source artificial intelligence model into the source module configured with the nodes independent of a framework, wherein the source modules correspond to the source operators dependent on the first framework.

According to an embodiment of the present disclosure, the method further comprises: transforming the source intermediate representation structure into a universal intermediate representation structure for transformation to another framework which is different from the first framework, and wherein the generating the target intermediate representation structure comprises: transforming the universal intermediate representation structure into the target intermediate representation structure including the target modules dependent on the second framework and the nodes independent of a framework, by using the information about the second framework to which the source artificial intelligence model is to be converted.

According to an embodiment of the present disclosure, the universal intermediate representation structure, as an intermediate representation independent of a framework, comprises a combination of nodes corresponding to a minimum unit of atomic operators universally applicable to a plurality of frameworks.

According to an embodiment of the present disclosure, the transforming the source intermediate representation structure into the universal intermediate representation structure comprises: generating the universal intermediate representation structure by: removing the source modules dependent on the first framework and maintaining the nodes independent of a framework, on the source intermediate representation structure, or modifying the source intermediate representation structure such that a single node is included in a single source module.

According to an embodiment of the present disclosure, the transforming the universal intermediate representation structure into the target intermediate representation structure including the target modules dependent on the second framework and the nodes independent of a framework comprises: grouping the nodes included in the universal intermediate representation structure by using the information about the second framework to which the source artificial intelligence model is to be converted as a grouping condition, and generating the target modules dependent on the second framework according to a result of the grouping, wherein the target modules correspond to the target operators.

According to an embodiment of the present disclosure, the target intermediate representation structure comprises: a node; a tensor connecting nodes; a target module that represents information dependent on the second framework and is configured with one or more nodes; and a tensor connecting target modules, the source intermediate representation structure comprises: a node; a tensor connecting nodes; a source module that represents information dependent on the first framework and is configured with one or more nodes; and a tensor connecting source modules, and the target intermediate representation structure and the source intermediate representation structure further comprise an argument representing a value used for an operator to operate.

According to an embodiment of the present disclosure, the source module in the source intermediate representation structure comprises: an input tensor, an output tensor, a source operator dependent on the first framework, nodes existing within the source module, an original module at a time of generation of the source intermediate representation structure, and original nodes at the time of generation of the source intermediate representation structure, the target module in the target intermediate representation structure comprises: an input tensor, an output tensor, a target operator dependent on the second framework, nodes existing within the target module, an original module at a time of generation of the target intermediate representation structure, and original nodes at the time of generation of the source intermediate representation structure, and a node in the source intermediate representation structure or the target intermediate representation structure comprises: an input tensor, an output tensor, an atomic operator corresponding to a node, and original nodes at the time of generation of the source intermediate representation structure.

According to an embodiment of the present disclosure, the transforming the source operators into the source intermediate representation structure comprises: transforming the source operators included in the source artificial intelligence model into a combination of the nodes, by using a lookup table that represents a transformation relationship between the source operators of the first framework and the nodes.

According to an embodiment of the present disclosure, the transforming the source operators into the source intermediate representation structure comprises: transforming each of the source operators included in the source artificial intelligence model into the source module which is a combination of the nodes, and transforming an argument of the source operators into an argument of a node included in the source module, by using a lookup table including the transformation relationship between the source operators of the first framework and the nodes and the argument used for an operator to operate in the first framework.

According to an embodiment of the present disclosure, the transforming the source operators into the source intermediate representation structure comprises: identifying a combination of nodes that matches a combination of the source operator of the source artificial intelligence model and the first framework, by using a lookup table that identifies a combination of nodes that matches a combination of a type of framework and a type of operator, and transforming each of the source operators constituting the source artificial intelligence model into the source module, by configuring a single module with the identified combination of nodes.

According to an embodiment of the present disclosure, the generating the target intermediate representation structure comprises: determining a recombination scheme of the nodes for compatibility with the second framework, by using a lookup table that represents a transformation relationship between the target operators of the second framework and the nodes, and generating the target modules dependent on the second framework, by grouping the nodes by using the determined recombination scheme.

According to an embodiment of the present disclosure, the generating the target artificial intelligence model comprises: generating the target artificial intelligence model compatible with the second framework, by transforming arguments of the nodes included in the target modules into arguments of the target operators of the second framework, by using a lookup table representing a transformation relationship between the second framework and nodes and an argument used for an operator to operate in the second framework.

According to an embodiment of the present disclosure, the transforming the source operators into the source intermediate representation structure comprises: transforming the source operators included in the source artificial intelligence model into a combination of the nodes, by using a lookup table that uses an operator for each framework as a key and a node corresponding to an atomic operator as a value.

According to an embodiment of the present disclosure, the generating the target artificial intelligence model comprises: generating a quantization operator and a dequantization operator corresponding to the second framework, by using quantization information of a tensor included in the target intermediate representation structure, wherein the quantization operator and the dequantization operator are added to the target operators when transforming the target modules of the target intermediate representation structure into the target operators executable in the second framework.

According to an embodiment of the present disclosure, the method further comprises identifying a mode of the received source artificial intelligence model, wherein when the received source artificial intelligence model is identified as a first mode in which the model is executed after representing operations as a graph, the transforming into the source intermediate representation structure is performed on the received source artificial intelligence model, when the received source artificial intelligence model is identified as a second mode in which the model is executed in an operation unit without representing operations as a graph, a model optimization tool is applied on the source artificial intelligence model and the transforming into the source intermediate representation structure is performed on the source artificial intelligence model to which the model optimization tool is applied, and the model optimization tool comprises at least one of a compressor, a graph optimizer, and a quantizer.

According to an embodiment of the present disclosure, the method further comprises changing a configuration of the target modules included in the target intermediate representation structure, by using a model optimization tool comprising at least one of a compressor, a graph optimizer, and a quantizer. Wherein the generating the target artificial intelligence model comprises generating the target artificial intelligence model executable in the second framework, by converting the target modules with the changed configuration in the target intermediate representation structure into the target operators executable in the second framework.

According to an embodiment of the present disclosure, when information of a target hardware on which the target artificial intelligence model is to be deployed is received, the information of the target hardware is stored in the target modules and a tensor in the target intermediate representation structure. The generating the target artificial intelligence model comprises generating the target artificial intelligence model by removing a target module or a node corresponding to an operator that is not supportable on the target hardware, by using the information of the target hardware in the target intermediate representation structure.

According to an embodiment of the present disclosure, when information of a target hardware and a target compiler on which the target artificial intelligence model is to be deployed is received, a node supportable on the target hardware and the target compiler and a module including the supportable node are added to the target intermediate representation structure, or a node unsupportable on the target hardware and the target compiler and a module including the unsupportable node are deleted from the target intermediate representation structure.

According to an embodiment of the present disclosure, the method further comprises: when information of a target hardware on which the target artificial intelligence model is to be deployed is received, a graph optimization step of deleting a node on the target intermediate representation structure, deleting at least one node among nodes included in the target intermediate representation structure, or moving at least one node among the nodes included in the target intermediate representation structure from a first target module to a second target module on the target intermediate representation structure, by using the information of the target hardware.

According to an embodiment of the present disclosure, a non-transitory computer-readable medium storing a computer program is disclosed. The computer program, when executed by a computing device, allows the computing device to perform operations for converting a source artificial intelligence model to a target artificial intelligence model for a framework transformation. The operations comprises: receiving the source artificial intelligence model executable in a first framework, transforming source operators included in the source artificial intelligence model into a source intermediate representation structure including source modules dependent on the first framework and nodes independent of a framework, generating a target intermediate representation structure including target modules dependent on a second framework and the nodes independent of a framework, by using information about the second framework to which the source artificial intelligence model is to be converted, and generating the target artificial intelligence model in which the source operators of the source artificial intelligence model are converted to target operators, by transforming the target modules of the target intermediate representation structure into the target operators executable in the second framework, wherein the source modules and the target modules are configured with a combination of the nodes, and each of the nodes corresponds to an atomic operator independent of a framework.

According to an embodiment of the present disclosure, a computing device for converting a source artificial intelligence model to a target artificial intelligence model for framework transformation is disclosed. The computing device comprises at least one processor. The at least one processor is configured to: receive the source artificial intelligence model executable in a first framework, transform source operators included in the source artificial intelligence model into a source intermediate representation structure including source modules dependent on the first framework and nodes independent of a framework, generate a target intermediate representation structure including target modules dependent on a second framework and the nodes independent of a framework, by using information about the second framework to which the source artificial intelligence model is to be converted, and generate the target artificial intelligence model in which the source operators of the source artificial intelligence model are converted to target operators, by transforming the target modules of the target intermediate representation structure into the target operators executable in the second framework, wherein the source modules and the target modules are configured with a combination of the nodes, and each of the nodes corresponds to an atomic operator independent of a framework.

According to an embodiment of the present disclosure, a method, performed by a computing device, for transforming performance of an artificial intelligence model is disclosed. The method comprises: receiving an intermediate representation structure that represents a target artificial intelligence model which is an object of performance transformation, with a node corresponding to an atomic operator independent of a framework and a module dependent on a target framework of the target artificial intelligence model, wherein the intermediate representation structure has a hierarchical structure in which one or more nodes constitute the module, changing at least a part of the intermediate representation structure by applying a model optimization tool to the intermediate representation structure, and outputting a target artificial intelligence model to which a performance transformation has been applied, by using the changed intermediate representation structure.

According to an embodiment of the present disclosure, the changing at least a part of the intermediate representation structure comprises: determining an object of change among nodes and tensors connecting the nodes within the intermediate representation structure, by using information of the module of the intermediate representation structure, and changing at least a part of the intermediate representation structure by changing the determined object of change by using the model optimization tool.

According to an embodiment of the present disclosure, when at least a part of the intermediate representation structure is changed, the hierarchical structure of the intermediate representation structure is maintained before and after the change of the intermediate representation structure, as information of the module is used as optimization reference information used by the model optimization tool.

According to an embodiment of the present disclosure, the changing at least a part of the intermediate representation structure is characterized by maintaining a dependency relationship of the module to the target framework before and after the change of the intermediate representation structure, by applying the model optimization tool by using information of the target framework included in the intermediate representation structure.

According to an embodiment of the present disclosure, the model optimization tool comprises at least one of: a compressor for lightweighting of the target artificial intelligence model, a graph optimizer for increasing an execution efficiency of the target artificial intelligence model, and a quantizer for reducing at least one of a size and an amount of computation of the target artificial intelligence model, and wherein when a plurality of model optimization tools are applied to the intermediate representation structure, an intermediate representation structure to which a first change by one model optimization tool is applied is input to another model optimization tool, and a second change is applied to the intermediate representation structure to which the first change is applied by the other model optimization tool.

According to an embodiment of the present disclosure, the intermediate representation structure is a graph structure comprising: a node, a module configured with one or more nodes, and a tensor that represents an input of a module, an output of a module, a weight input to the module, and an activation input to the module, on the intermediate representation structure. Wherein optimization reference information to be used for an operation of the model optimization tool is stored in the intermediate representation structure, and the optimization reference information comprises channel axis tracking information, information indicating whether compression is possible, target hardware information, target framework information, and quantization information.

According to an embodiment of the present disclosure, the optimization reference information to be used by the model optimization tool among the optimization reference information stored in the intermediate representation structure becomes different according to a type of the model optimization tool.

According to an embodiment of the present disclosure, when the model optimization tool is a compressor, a first optimization reference information representing a compressible operator among operators of the target artificial intelligence model within the intermediate representation structure is used in the compressor. When the model optimization tool is a graph optimizer, a second optimization reference information comprising quantization information for determining whether to change a module of the intermediate representation structure within the intermediate representation structure is used in the graph optimizer. When the model optimization tool is a quantizer, a third optimization reference information comprising target platform information on which the target artificial intelligence model is to be executed within the intermediate representation structure is used in the quantizer.

According to an embodiment of the present disclosure, the changing at least a part of the intermediate representation structure comprises: obtaining tag information in which a compressible module or a compressible node is designated, from the intermediate representation structure, and determining a compression configuration value according to a compressor, and changing at least a part of the intermediate representation structure by using the compressor, based on the tag information and the compression configuration value.

According to an embodiment of the present disclosure, when a compression scheme of the compressor is a pruning scheme, information about another module connected to the compressible module or information about another node connected to the compressible node is extracted from the intermediate representation structure, and at least a part of the intermediate representation structure is changed by the compressor further based on the extracted information.

According to an embodiment of the present disclosure, when the model optimization tool is a graph optimizer, the changing at least a part of the intermediate representation structure comprises: determining a target template corresponding to a combination pattern of modules on the intermediate representation structure, from among pre-stored module combination templates, and changing at least a part of the intermediate representation structure in a unit of a template which represents a combination of modules, by applying the target template to the intermediate representation structure.

According to an embodiment of the present disclosure, the changing at least one module of the intermediate representation structure by using the graph optimizer further comprises determining whether to apply the target template to the intermediate representation structure, by using quantization information stored in the intermediate representation structure.

According to an embodiment of the present disclosure, when the model optimization tool is a graph optimizer, the changing at least a part of the intermediate representation structure comprises: determining a target template corresponding to a combination pattern of modules and a combination pattern of nodes on the intermediate representation structure, from among pre-stored module combination templates, and changing at least a part of the intermediate representation structure in a unit of a template which represents a combination of modules and a combination of nodes, by applying the target template to the intermediate representation structure.

According to an embodiment of the present disclosure, the method further comprises: when a quantization-related operator is included in the received intermediate representation structure, a preprocessing step of removing a quantization-related operator from the intermediate representation structure and adding quantization information corresponding to the quantization-related operator to a tensor within the intermediate representation structure, before the changing at least a part of the intermediate representation structure.

According to an embodiment of the present disclosure, the changing at least a part of the intermediate representation structure comprises generating a quantized intermediate representation structure by changing at least a part of the intermediate representation structure by using a quantizer. The generating the quantized intermediate representation structure comprises: determining a range of a tensor value for the intermediate representation structure, based on target platform information on which the target artificial intelligence model is to be executed, determining a quantization parameter for quantizing the target artificial intelligence model, by using the range of the tensor value, and generating the quantized intermediate representation structure by changing a tensor within the intermediate representation structure based on the quantization parameter.

According to an embodiment of the present disclosure, the target platform information comprises target hardware information on which the target artificial intelligence model is to be executed, target compiler information for connecting the target artificial intelligence model to a target hardware, and runtime information representing an environment of the target hardware on which the target artificial intelligence model is to be executed.

According to an embodiment of the present disclosure, the generating the quantized intermediate representation structure comprises determining a tensor that is an object of quantization within the intermediate representation structure, or determining a tensor that is an object for storing quantization information within the intermediate representation structure, based on module boundary information in the intermediate representation structure.

According to an embodiment of the present disclosure, the intermediate representation structure comprises a combination of nodes corresponding to a minimum unit of atomic operators universally applicable to a plurality of frameworks, when frameworks of artificial intelligence models that perform the same operation are different, different modules are included in their intermediate representation structures, and even if the frameworks of the artificial intelligence models that perform the same operation are different, the same node is included in their intermediate representation structures.

According to an embodiment of the present disclosure, when the intermediate representation structure is cumulatively changed by a plurality of model optimization tools, information on the number of times the model optimization tools have been applied to the intermediate representation structure is stored within the intermediate representation structure, and when the model optimization tool is applied to the intermediate representation structure, a duplicate application of model optimization tools is prevented by using the information on the number of times.

According to an embodiment of the present disclosure, when the intermediate representation structure is changed by a plurality of model optimization tools, a target lightweighting value that defines a lightweighting target is stored in the intermediate representation structure, and a cumulative value for a lightweighting value applied to the intermediate representation structure by each of the model optimization tools is stored in the intermediate representation structure, and when a model optimization tool is applied to the intermediate representation structure, a target lightweighting value corresponding to the model optimization tool for the intermediate representation structure is determined based on a comparison between a current cumulative value and a predefined target lightweighting value.

According to an embodiment of the present disclosure, a non-transitory computer-readable medium storing a computer program is disclosed. The computer program, when executed by a computing device, allows the computing device to perform a method for transforming performance of an artificial intelligence model. The method comprises: receiving an intermediate representation structure that represents a target artificial intelligence model which is an object of performance transformation, with a node corresponding to an atomic operator independent of a framework and a module dependent on a target framework of the target artificial intelligence model, wherein the intermediate representation structure has a hierarchical structure in which one or more nodes constitute the module, changing at least a part of the intermediate representation structure by applying a model optimization tool to the intermediate representation structure, and outputting a target artificial intelligence model to which a performance transformation has been applied, by using the changed intermediate representation structure.

According to an embodiment of the present disclosure, a computing device for transforming performance of an artificial intelligence model is disclosed. The computing device comprises at least one processor. The at least one processor is configured to perform operations comprising: receiving an intermediate representation structure that represents a target artificial intelligence model, which is an object of performance transformation, with a node corresponding to an atomic operator independent of a framework and a module dependent on a target framework of the target artificial intelligence model, wherein the intermediate representation structure has a hierarchical structure in which one or more nodes constitute the module, changing at least a part of the intermediate representation structure by applying a model optimization tool to the intermediate representation structure, and outputting a target artificial intelligence model to which a performance transformation has been applied, by using the changed intermediate representation structure.

According to an embodiment of the present disclosure, a method, performed by a computing device, for generating an expected inference simulation result of an artificial intelligence model is disclosed. The method comprises: receiving an intermediate representation structure that represents a target artificial intelligence model which is an object of a simulation, with a node corresponding to an atomic operator independent of a framework and a module dependent on a target framework of the target artificial intelligence model, wherein the intermediate representation structure has a hierarchical structure in which one or more nodes constitute the module, receiving target platform information for identifying a target platform on which the target artificial intelligence model is to be executed and input data to be used in a simulation process of the target artificial intelligence model, and generating an expected inference simulation result for a case where the target artificial intelligence model with the input data as an input is to be executed on the target platform, without executing the target artificial intelligence model on the target platform, by using the intermediate representation structure, the target platform information, and the input data.

According to an embodiment of the present disclosure, the generating the expected inference simulation result comprises: generating at least one of a target platform node and a target platform module supported on the target platform, by using the received target platform information, changing the intermediate representation structure by using the at least one of the target platform node and the target platform module, and generating the expected inference simulation result for a case where the target artificial intelligence model with the input data as an input is to be executed on the target platform, without executing the target artificial intelligence model on the target platform, by using the changed intermediate representation structure and the input data.

According to an embodiment of the present disclosure, the target platform module comprises a quantization node and a dequantization node, in a structure where an output of the quantization node corresponding to the target platform and an input of the dequantization node corresponding to the target platform are connected to each other.

According to an embodiment of the present disclosure, the generating the expected inference simulation result comprises: changing the intermediate representation structure, by generating a quantization node and a dequantization node corresponding to the target platform by using the received target platform information, and adding the quantization node and the dequantization node to the intermediate representation structure, and generating the expected inference simulation result for a case where the target artificial intelligence model with the input data as an input is to be executed on the target platform, without executing the target artificial intelligence model on the target platform, by using the changed intermediate representation structure and the input data, wherein a position where the quantization node and the dequantization node are to be added on the intermediate representation structure is determined by using the received target platform information.

According to an embodiment of the present disclosure, the generating the expected inference simulation result comprises: generating a simulation intermediate representation structure represented by a connection of nodes, by maintaining nodes and removing modules on the intermediate representation structure, and generating the expected inference simulation result for a case where the target artificial intelligence model with the input data as an input is to be executed on the target platform, without executing the target artificial intelligence model on the target platform, by using the simulation intermediate representation structure and the input data.

According to an embodiment of the present disclosure, the simulation intermediate representation structure is a graph structure composed of a node and an internal edge connecting nodes.

According to an embodiment of the present disclosure, the expected inference simulation result is generated by a scheme of performing inference in a unit of node according to a connection order of nodes within the intermediate representation structure.

According to an embodiment of the present disclosure, the generating the expected inference simulation result comprises: generating a changed intermediate representation structure by adding a quantization node and a dequantization node corresponding to the target platform to the intermediate representation structure by using the received target platform information, generating a simulation intermediate representation structure represented by a connection of nodes, by maintaining nodes and removing modules within the changed intermediate representation structure, and generating the expected inference simulation result for the case where the target artificial intelligence model with the input data as an input is to be executed on the target platform, without executing the target artificial intelligence model on the target platform, by using a simulator with the simulation intermediate representation structure and the input data as an input.

According to an embodiment of the present disclosure, the intermediate representation structure is a graph structure comprising a node, a tensor connecting nodes, a module configured with one or more nodes, and a tensor connecting modules.

According to an embodiment of the present disclosure, the intermediate representation structure further comprises a tensor representing inputs and outputs, a weight, and an activation of modules on the intermediate representation structure, and a module of the intermediate representation structure comprises a combination of nodes corresponding to a minimum unit of atomic operators universally applicable to a plurality of frameworks.

According to an embodiment of the present disclosure, the generating the expected inference simulation result comprises: comparing platform information stored in the intermediate representation structure and the target platform information, when the stored platform information and the target platform information are different as a result of the comparing, changing a node constituting a module within the intermediate representation structure, or the module within the intermediate representation structure, or a tensor within the intermediate representation structure, based on the target platform information, and generating the expected inference simulation result for a case where the target artificial intelligence model with the input data as an input is to be executed on the target platform, without executing the target artificial intelligence model on the target platform, by using the intermediate representation structure to which the change is applied and the input data.

According to an embodiment of the present disclosure, the target platform information comprises target hardware information on which the target artificial intelligence model is to be executed, target compiler information for connecting the target artificial intelligence model to a target hardware, and runtime information representing an environment of the target hardware on which the target artificial intelligence model is to be executed.

According to an embodiment of the present disclosure, the generating the expected inference simulation result comprises: generating a changed intermediate representation structure by adding to the intermediate representation structure at least one of a node supportable on the target platform and a module including the supportable node, or deleting from the intermediate representation structure a node unsupportable on the target platform and a module including the unsupportable node, by using the received target platform information, and generating the expected inference simulation result for a case where the target artificial intelligence model with the input data as an input is to be executed on the target platform, without executing the target artificial intelligence model on the target platform, by using the changed intermediate representation structure and the input data.

According to an embodiment of the present disclosure, the method further comprises generating an optimized intermediate representation structure by modifying a combination of nodes within the intermediate representation structure by using a model optimization tool comprising at least one of a compressor, a graph optimizer, and a quantizer. The generating the expected inference simulation result comprises generating an optimized expected inference simulation result for a case where an optimized target artificial intelligence model with the input data as an input is to be executed on the target platform, without executing the target artificial intelligence model on the target platform, by using the optimized intermediate representation structure and the input data.

According to an embodiment of the present disclosure, the generating the optimized intermediate representation structure comprises: deleting at least one node among nodes included in the intermediate representation structure, compressing at least one node among the nodes included in the intermediate representation structure, or moving at least one node among the nodes included in the intermediate representation structure from a first module to a second module on the intermediate representation structure.

According to an embodiment of the present disclosure, the method further comprises: generating a performance evaluation result for an optimization of the target artificial intelligence model, by comparing the optimized expected inference simulation result generated by using the optimized intermediate representation structure and the expected inference simulation result generated by using the intermediate representation structure.

According to an embodiment of the present disclosure, the method further comprises: converting the intermediate representation structure into the target artificial intelligence model by using a model converter, generating an expected inference simulation result or a benchmark result for a case where the input data and the target artificial intelligence model are to be executed on the target platform and in a target framework of the target artificial intelligence model, by using the converted target artificial intelligence model and the input data, and comparing the expected inference simulation result generated by using the intermediate representation structure and the inference simulation result or the benchmark result.

According to an embodiment of the present disclosure, the method further comprises: determining a range of a tensor value when the input data is input to the intermediate representation structure, based on the target platform information, determining a quantization parameter for quantizing the target artificial intelligence model, by using the range of the tensor value, and generating a quantized intermediate representation structure by changing a tensor within the intermediate representation structure based on the quantization parameter. The generating the expected inference simulation result comprises: generating the expected inference simulation result for a case where a quantized target artificial intelligence model with the input data as an input is to be executed on the target platform, without executing the target artificial intelligence model on the target platform, by using the quantized intermediate representation structure, the target platform information, and the input data.

According to an embodiment of the present disclosure, a non-transitory computer-readable medium storing a computer program is disclosed. The computer program, when executed by a computing device, causes the computing device to perform operations for generating an expected inference simulation result of an artificial intelligence model. The operations comprises: receiving an intermediate representation structure that represents a target artificial intelligence model which is an object of a simulation, with a node corresponding to an atomic operator independent of a framework and a module dependent on a target framework of the target artificial intelligence model, wherein the intermediate representation structure has a hierarchical structure in which one or more nodes constitute the module, receiving target platform information for identifying a target platform on which the target artificial intelligence model is to be executed and input data to be used in a simulation process of the target artificial intelligence model, and generating an expected inference simulation result for a case where the target artificial intelligence model with the input data as an input is to be executed on the target platform, without executing the target artificial intelligence model on the target platform, by using the intermediate representation structure, the target platform information, and the input data.

According to an embodiment of the present disclosure, a computing device for generating an expected inference simulation result of an artificial intelligence model is disclosed. The computing device comprises at least one processor. The processor is configured to perform operations comprising: receiving an intermediate representation structure that represents a target artificial intelligence model which is an object of a simulation, with a node corresponding to an atomic operator independent of a framework and a module dependent on a target framework of the target artificial intelligence model, wherein the intermediate representation structure has a hierarchical structure in which one or more nodes constitute the module, receiving target platform information for identifying a target platform on which the target artificial intelligence model is to be executed and input data to be used in a simulation process of the target artificial intelligence model, and generating an expected inference simulation result for a case where the target artificial intelligence model with the input data as an input is to be executed on the target platform, without executing the target artificial intelligence model on the target platform, by using the intermediate representation structure, the target platform information, and the input data.

According to some embodiments of the present disclosure, performance optimization and/or performance transformation of an artificial intelligence model can be achieved through efficient use of computing resources.

According to some embodiments of the present disclosure, conversion of an artificial intelligence model can be performed in a manner independent of the framework of the artificial intelligence model.

According to some embodiments of the present disclosure, performance transformation and/or performance optimization of an artificial intelligence model can be achieved in a manner independent of the framework of the artificial intelligence model.

According to some embodiments of the present disclosure, performance transformation and/or performance optimization of an artificial intelligence model can be achieved so as to be suitable for the platform on which the artificial intelligence model is to be executed.

According to some embodiments of the present disclosure, without executing the artificial intelligence model on the platform, an expected inference simulation result of the artificial intelligence model on the platform can be generated in an efficient manner.

According to some embodiments of the present disclosure, model optimization tools to be used for optimization and/or transformation of the artificial intelligence model can be efficiently arranged and/or applied.

According to some embodiments of the present disclosure, an artificial intelligence model optimized for a target platform can be generated.

According to some embodiments of the present disclosure, by presenting a novel intermediate representation structure, a technical effect can be derived in that conversion, performance optimization, and/or simulation of the artificial intelligence model across various platforms and/or frameworks can be efficiently achieved.

The effects obtainable from the present disclosure are not limited to the effects mentioned above, and other effects not mentioned will be clearly understood by one of ordinary skill in the art to which the present disclosure pertains from the following description.

### BRIEF DESCRIPTION OF THE DRAWINGS

Various aspects will now be described with reference to the drawings, wherein like reference numerals are used to refer to like elements throughout. In the following description, for purposes of explanation, numerous specific details are set forth in order to provide a thorough understanding of one or more aspects. However, it will be evident that such aspect(s) may be practiced without these specific details. In other instances, well-known structures and devices are shown in block diagram form to facilitate describing one or more aspects.

FIG. 1 is a block diagram of a computing device for performing techniques according to an embodiment of the present disclosure.

FIG. 2 is a schematic diagram illustrating a network function according to an embodiment of the present disclosure.

FIG. 3 is a block diagram illustrating, by way of example, a structure for transforming an artificial intelligence model according to an embodiment of the present disclosure.

FIG. 4 is a flowchart illustrating, by way of example, a method of converting a source artificial intelligence model into a target artificial intelligence model according to an embodiment of the present disclosure.

FIG. 5 illustrates, by way of example, an intermediate representation structure according to an embodiment of the present disclosure.

FIG. 6 illustrates, by way of example, a manner in which a source artificial intelligence model is converted into a target artificial intelligence model using an intermediate representation structure according to an embodiment of the present disclosure.

FIG. 7 illustrates, by way of example, a manner in which a model optimization tool is applied to an intermediate representation structure in the process of converting an artificial intelligence model according to an embodiment of the present disclosure.

FIG. 8 illustrates, by way of example, a conversion process to which a model preprocessing procedure is applied.

FIG. 9 is a block diagram illustrating, by way of example, a structure for transforming an artificial intelligence model according to an embodiment of the present disclosure.

FIG. 10 is a flowchart illustrating, by way of example, a method for outputting a target artificial intelligence model to which performance transformation has been applied.

FIG. 11 illustrates, by way of example, an intermediate representation structure to which channel axis tracking results are applied according to an embodiment of the present disclosure.

FIG. 12 illustrates an example in which a compression technique is applied to an intermediate representation structure according to an embodiment of the present disclosure.

FIG. 13 illustrates an example in which a compression technique is applied to an intermediate representation structure according to an embodiment of the present disclosure.

FIG. 14 illustrates, by way of example, an intermediate representation structure including tensor information according to an embodiment of the present disclosure.

FIG. 15 is a flowchart illustrating, by way of example, a method for generating an expected inference simulation result according to an embodiment of the present disclosure.

FIG. 16 illustrates, by way of example, a process of generating an expected inference simulation result using an intermediate representation structure according to an embodiment of the present disclosure.

FIG. 17 illustrates, by way of example, a process of generating an expected inference simulation result in consideration of platform information according to an embodiment of the present disclosure.

FIG. 18 illustrates, by way of example, a process of generating an expected inference simulation result in consideration of platform information and data type information according to an embodiment of the present disclosure.

FIG. 19 illustrates an example in which a simulator is applied after conversion into a target artificial intelligence model according to an embodiment of the present disclosure.

FIG. 20 is a simplified block diagram illustrating an exemplary computing environment of a computing device in which embodiments of the present disclosure may be implemented.

### DETAILED DESCRIPTION

Various exemplary embodiments will now be described with reference to drawings. In this specification, various descriptions are presented to provide appreciation of the present disclosure. However, it will be apparent that these embodiments may be implemented without the specific descriptions set forth herein.

The term “manager”, “editor” and/or “tool” can be referred to a computer-related component. The component can refer to a computer-related entity, a hardware, a firmware, a software, a combination of the software and the hardware, or the execution of the software. The component may be localized in one computer. For example, the component can be the procedure executed on a processor, a processor, an object, an execution thread, a program and/or a computer, but it is not limited to the above descriptions. One component may be distributed between two or more computers. Further, the components may be executed by various computer-readable media having various data structures, which are stored therein. The components may perform communication through local and/or remote processing according to a signal (for example, data transmitted from another system through a network such as the Internet through data and/or a signal from one component that interacts with other components in a local system and a distribution system) having one or more data packets, for example.

The term “or” is intended to mean not exclusive “or” but inclusive “or”. That is, when not separately specified or not clear in terms of a context, a sentence “X uses A or B” is intended to mean one of the natural inclusive substitutions. That is, the sentence “X uses A or B” may be applied to any of the case where X uses A, the case where X uses B, or the case where X uses both A and B. Further, it should be understood that the term “or” and “and/or” used in this specification designates and includes all available combinations of one or more items among enumerated related items.

Further, it should be appreciated that the term “comprise/include” and/or “comprising/including” means presence of corresponding features and/or components. However, it should be appreciated that the term “comprises/includes” and/or “comprising/including” means that presence or addition of one or more other features, components, and/or a group thereof is not excluded. Further, when not separately specified or it is not clear in terms of the context that a singular form is indicated, it should be construed that the singular form generally means “one or more” in this specification and the claims.

And, the term “at least one of A or B” should be interpreted to mean “a case including only A”, “a case including only B”, and “a case in which A and B are combined”.

In the present disclosure terms represented by N-th such as first, second, or third are used for distinguishing at least one entity. For example, entities expressed as first and second may be the same as each other or different from each other.

In the present disclosure, an artificial intelligence model may refer to a program or a set of functions designed with a mathematical or statistical structure to automatically perform tasks such as prediction, classification, generation, and/or inference for a given input by learning patterns from data. An artificial intelligence model can be constructed by modeling the relationship between an input and an output in the form of a function. A specific example of an artificial intelligence model will be described later with reference to FIG. 2.

In the present disclosure, a “framework” may refer to a collection of libraries and tools for designing, building, training, evaluating, and deploying artificial intelligence models. The framework may denote software that enhances the efficiency and reproducibility of model development. The framework may also refer to a development environment for constructing AI models. The framework may further be used in a broad sense to include the execution environment and/or runtime of AI models. The framework allows the structure and operation of an AI model to be defined and executed. For example, the framework may include TensorFlow, PyTorch, ONNX, TensorFlow Lite, TensorRT, JAX, and MXNet. Such various frameworks may each differ in the structure of operators and the manner in which operators are processed.

In the present disclosure, “transformation,” “conversion” or “converting” of a framework may refer to transforming an AI model of a specific framework into an AI model of another framework. For example, a source AI model executable on a first framework may be converted into a target AI model executable on a second framework. In the present disclosure, the term “transformation” may denote changing a model and may be used in a broad sense to encompass “converting.” Depending on the embodiment, the terms “transformation,” “conversion” and “converting” may be used interchangeably.

In the present disclosure, the intermediate representation structure may refer to a standardized representation format used at an intermediate stage to optimize the computation graph or structure of a model for a specific execution environment or platform. In the present disclosure, the intermediate representation structure may be composed of a graph corresponding to an artificial intelligence model, a module representing a layer (or operator) that is dependently defined for a framework, and nodes representing the minimum unit of operators that constitute the module. In an embodiment, the intermediate representation structure may be configured such that all nodes within the intermediate representation structure (or constituting the artificial intelligence model) are included in any one module. In an embodiment, the intermediate representation structure may be configured such that all nodes within the intermediate representation structure are included in one or more modules. In an embodiment, the intermediate representation structure in the present disclosure may take the form of a graph. For example, the graph related to the intermediate representation structure in the present disclosure may refer to the result of abstracting an artificial intelligence model based on the connection relationship of modules, nodes, and/or tensors. The intermediate representation structure in the present disclosure may refer to an intermediate structure or a temporary structure for changing an artificial intelligence model for execution in various frameworks and/or on various platforms. The intermediate representation structure in the present disclosure may include a graph structure. The intermediate representation structure may be generated such that framework-independent nodes and modules, which are sets of nodes, have a hierarchical structure or a dependency relationship. The intermediate representation structure of the present disclosure may be configured to include nodes corresponding to framework-independent atomic operators, framework-dependent modules, and a tensor that connects the nodes and/or connects the modules. A tensor is a data structure used to represent the input, output, weights, intermediate calculation values, and/or quantization values of an artificial intelligence model. For example, a tensor may have a multi-dimensional array structure. For example, a tensor may have reference information for the transformation or optimization of an artificial intelligence model. For example, a tensor may be stored in an edge connecting nodes, and/or a tensor may be located in an edge connecting modules. For example, a tensor may be located at the input to a module or node, and/or a tensor may be located at the output from a module or node. The intermediate representation structure in the present disclosure may, for example, include a Static Graph of a deep learning framework such as TensorFlow or Onnx, and/or may include a dynamic graph in the form of an Eager execution mode of a deep learning framework such as PyTorch. For example, the intermediate representation structure may be generated by receiving an artificial intelligence model in the form of a static graph, may be generated by receiving an artificial intelligence model in the form of a dynamic graph, and/or may also be generated by receiving an artificial intelligence model to which model optimization tool(s) have been applied. The intermediate representation structure in the present disclosure may refer to a logical structure for expressing the function of an artificial intelligence model. The intermediate representation structure in the present disclosure may include a combination of nodes corresponding to the minimum unit of atomic operators that are universally applicable to a plurality of frameworks. For example, if the frameworks of artificial intelligence models that perform the same operation are different, different modules are included in the intermediate representation structure, and even if the frameworks of artificial intelligence models that perform the same operation are different, the same nodes may be included in the intermediate representation structure.

Within the intermediate representation structure in the present disclosure, a plurality of abstraction levels may be represented. For example, a module within the intermediate representation structure may refer to a component of a first abstraction level (e.g., a high-level abstraction) that represents an artificial intelligence model in units of inference functions, and a node within the intermediate representation structure may refer to a component of a second abstraction level (e.g., a low-level abstraction) that represents the artificial intelligence model in units of operators or operational units that implement the inference function of the artificial intelligence model. For example, a module within the intermediate representation structure is a component abstracted in units of functional blocks defined to be in charge of a specific sub-function of the entire inference process of an artificial intelligence model. For example, a node within the intermediate representation structure is a component abstracted in units of individual operators used to implement a sub-function of an artificial intelligence model.

In an embodiment, the abstraction level corresponding to a module may be higher than the abstraction level corresponding to a node. In an embodiment, the intermediate representation structure may be configured through a combination of components having mutually different abstraction levels. In an embodiment, the computing device 100 may hierarchically abstract an artificial intelligence model using modules and nodes through the intermediate representation structure according to a target transformation scenario. In an embodiment, the computing device 100 may generate an intermediate representation structure by abstracting an artificial intelligence model to a low level. Model optimization tools are executed on the intermediate representation structure to which the low-level abstraction has been applied, and an optimized or transformed (target) artificial intelligence model may be generated by abstracting the intermediate representation structure on which the model optimization tools have been executed to a high level.

The abstraction level in the present disclosure may refer to the degree to which a component constituting an artificial intelligence model is expressed as a higher-level concept structurally or semantically. The abstraction level in the present disclosure may refer to the degree to which a component of an artificial intelligence model is expressed as an operational unit or an operational block. The abstraction level in the present disclosure may refer to the degree or scope of grouping the components of a model into logical units. The abstraction level in the present disclosure may refer to an indicator for defining whether the representation method of an artificial intelligence model is a conceptual method (e.g., source code that is easy for humans to understand) or a concrete method (e.g., machine language that is easy for a machine to understand and execute). For example, the abstraction level may represent an indicator of how concrete (e.g., low-level) or general or conceptual (e.g., high-level) the method of representing or implementing an artificial intelligence model is.

For example, the higher the abstraction level, the greater the degree to which it is expressed as a higher-level concept. For example, a high-level abstraction may refer to conceptualizing or defining the components of an artificial intelligence model in terms of the conceptual or functional aspects of the artificial intelligence model. For example, a low-level abstraction may refer to conceptualizing or defining the components of an artificial intelligence model in terms of the implementation of the artificial intelligence model or in terms of operators. For example, a high-level abstraction may have a larger grouping size in terms of the grouping size of the components of an artificial intelligence model compared to a low-level abstraction. In an embodiment, nodes defined according to a relatively low-level abstraction may constitute or abstract a module or a graph corresponding to a relatively high-level abstraction.

In an additional embodiment, a low abstraction level refers to a form that can be directly executed by hardware, such as machine language, and a high abstraction level may refer to a conceptual representation that is easy for humans to understand, such as a source code or an algorithm design diagram. As an additional example, the abstraction level may be expressed in a plurality of levels, such as a low abstraction level (e.g., binary code and assembly code), an intermediate abstraction level (e.g., source code written in a programming language such as Python, C++, etc.), and a high abstraction level (e.g., a mathematical model, pseudocode of an algorithm, and a block diagram). For example, a compiler can lower the abstraction level of the artificial intelligence model by transforming human-readable source code into low-level machine code, or binary code, which the computer's hardware can execute.

The abstraction level of the present disclosure can be used interchangeably with an expression unit or an abstraction unit according to an abstracted result.

A technique according to an embodiment of the present disclosure can efficiently achieve the transformation and/or optimization of an artificial intelligence model by varying the abstraction level of the artificial intelligence model. A technique according to an embodiment of the present disclosure can efficiently achieve the transformation and/or optimization of an artificial intelligence model by combining both a low-level abstraction and a high-level abstraction for the artificial intelligence model. A technique according to an embodiment of the present disclosure can efficiently achieve the transformation and/or optimization of an artificial intelligence model in a manner of generating an intermediate representation structure of a second abstraction level by applying a low-level abstraction to the artificial intelligence model and generating an artificial intelligence model of a first abstraction level by applying a high-level abstraction to the intermediate representation structure.

In the present disclosure, the performance of an artificial intelligence model may encompass the accuracy, efficiency, resource usage, inference speed, model lightweighting, and/or inference latency of the artificial intelligence model. In an embodiment, performance may encompass the performance of the model itself and/or the performance (e.g., the memory usage, latency, model accuracy and/or fan usage) when the model is executed on a platform. In an embodiment, performance transformation is to change the performance of the artificial intelligence model and performance optimization can be included a scope of the performance transformation. In an embodiment, performance optimization may refer to activities and/or operations for improving or enhancing performance. For example, performance optimization may encompass compression, graph optimization, and/or quantization of an artificial intelligence model. For example, performance optimization may refer to changing or transforming at least a part of a model to improve such performance. For example, performance optimization may refer to changing, modifying or transforming at least one operator of a model to improve such performance. For example, performance optimization may include the optimization of accuracy, which indicates how well the prediction results (e.g., inference results) of the model match the actual correct answers. For example, performance optimization may include transforming the model so that it produces the same or better results using less time or fewer computational resources.

In the present disclosure, compression of a model may refer to a process or algorithm that reduces the storage space occupied by an artificial intelligence model and improves computational efficiency, by reconfiguring or reducing the structure or parameters of the artificial intelligence model or of a group divided from the artificial intelligence model. For example, compression algorithms may include a pruning algorithm that removes unimportant weights or neurons, a quantization algorithm that converts floating-point weights to lower-precision integers, a knowledge distillation algorithm that trains a lightweighted student model to mimic the output of a large-scale teacher model, and the like.

In the present disclosure, graph optimization may refer to a process or algorithm that improves the inference performance of an artificial intelligence model by transforming, changing or modifying the computation graph of the artificial intelligence model. For example, a computation graph can represent the operational flow of a model with nodes (e.g., operations) and edges (e.g., data flow). Graph optimization can modify this computation graph to allow an artificial intelligence model to operate on a specific platform and/or to allow the artificial intelligence model to be executed more efficiently and quickly when executed (on the specific platform).

In the present disclosure, quantization may refer to a process or algorithm that changes or transforms the format of inputs, weights and/or activations of an artificial intelligence model. For example, quantization can convert the format of inputs, weights and/or activations of an artificial intelligence model to a lower bit-count integer or fixed-point format. For example, quantization may refer to an optimization technique that reduces memory usage and improves computation speed during the inference of an artificial intelligence model by changing floating-point (e.g., 32-bit float) values to integers (e.g., 8-bit int).

In the present disclosure, a model optimization tool may refer to a program or software that is applied to or executed on an artificial intelligence model for model optimization and/or model change. For example, a model optimization tool may include a trainer for training a model, a compressor for compressing a model, a graph optimizer for graph optimization of a model, a quantizer for quantizing a model, and/or a simulator for simulating expected execution results for a model without executing the model on a platform. In an embodiment, a model optimization tool may be used interchangeably with modules for transforming at least a part of a model, such as a core module, a model converter, and/or a model optimizer.

In the present disclosure, a platform may include a hardware on which an artificial intelligence model is to be executed and/or a compiler that connects the artificial intelligence model with the hardware. In an embodiment, a platform may be referred to as a deployment target, a system configuration, a runtime environment, an inference platform and/or an execution environment where an artificial intelligence model can be executed.

In the present disclosure, a transformation scenario may refer to a set of one or more model optimization tools. In an embodiment, each of a plurality of transformation scenarios may identify a combination of model optimization tools to be executed on an artificial intelligence model. In an embodiment, a transformation scenario may indicate model optimization tools and their application order or execution order. In an embodiment, a transformation scenario may indicate the execution order, number of executions, functions, and parameters of model optimization tools. In an embodiment, a transformation scenario may indicate a predetermined execution order to allow for the sequential execution of model optimization tools. In an embodiment, within a single transformation scenario, a plurality of model optimization tools may be arranged according to an execution order. In an embodiment, within a single transformation scenario, a plurality of model optimization tools are arranged according to an execution order, and the execution parameters of each of the model optimization tools may be defined. In an embodiment, a transformation scenario may identify a second combination of model optimization tools for a first combination of an artificial intelligence model and a platform. For example, a transformation scenario may identify what the combination of model optimization tools is according to the combination of an artificial intelligence model and a platform. For example, a transformation scenario may identify, for a combination of an artificial intelligence model, a hardware, and a compiler, the order in which the optimization modules are executed on the artificial intelligence model. For example, a transformation scenario may indicate a execution performance prediction value for a combination of the artificial intelligence model, a hardware, and a compiler, when optimization modules are executed on the artificial intelligence model. For example, a transformation scenario may identify, for a combination of an artificial intelligence model, a hardware, and a compiler, identification information of model optimization tools to be applied to the artificial intelligence model and optimization parameters used in at least one of the model optimization tools.

In the present disclosure, a scenario database (DataBase) may refer to a storage or a storage management program for storing, managing, and updating a plurality of transformation scenarios. In an embodiment, a plurality of transformation scenarios are stored in the scenario database (DB). The scenario DB may refer to a database that is searched and used to recommend the execution order of model optimization tools and the parameters of the model optimization tools according to an artificial intelligence model, a platform (e.g., a combination of a hardware and a compiler), and/or user requirements. For example, the scenario DB can manage combinations of model optimization tools for combinations of artificial intelligence models and platforms in a table-like structure.

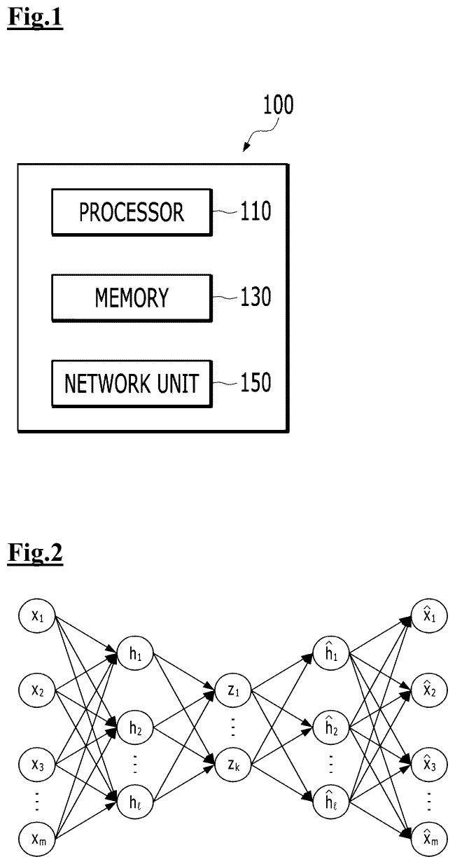

FIG. 1 is a block diagram of a computing device for transforming an artificial intelligence model for performance optimization of the artificial intelligence model according to an embodiment of the present disclosure.

A configuration of the computing device 100 illustrated in FIG. 1 is only an example illustrated through simplification. In an exemplary embodiment of the present disclosure, the computing device 100 may include other components for performing a computing configuration of the computing device 100 and only some of the disclosed components may constitute the computing device 100.

The computing device 100, according to some embodiments of the present disclosure, may be a device for transforming artificial intelligence model. In some embodiments of the present disclosure, the computing device 100 may transform the AI model into an intermediate representation structure and/or perform operations for various performance transformations on the intermediate representation structure. In some embodiments of the present disclosure, the computing device 100 may perform an operation of converting the intermediate representation structure into a target AI model. In some embodiments of the present disclosure, the computing device 100 may perform a simulation operation on the AI model using the intermediate representation structure. In some embodiments of the present disclosure, the computing device 100 may be a device for transforming the AI model for performance optimization of the AI model. The computing device 100 may include any form of server and/or any form of device. The server may include, for example, any type of computer system or computer device such as a microprocessor, a mainframe computer, a digital processor, a portable device, a device controller, a web server, an application server, or a database server.

In one embodiment, the computing device 100 may include a user device. For example, the computing device 100 may correspond to a user device that receives data resources generated by any server and performs additional information processing. The user device may include, for example, a personal computer (PC), a notebook computer, a mobile terminal, a smartphone, or a tablet PC owned by the user.

The computing device 100 may include a processor 110, a memory 130, and a network unit 150.

The processor 110 may be composed of one or more cores and may include a processor for performing operations related to data processing, such as a central processing unit (CPU), a general-purpose graphics processing unit (GPGPU), a digital signal processor (DSP), a tensor processing unit (TPU), or a neural processing unit (NPU). The processor 110 may perform data processing for transforming artificial intelligence model for performance optimization of artificial intelligence model according to an embodiment of the present disclosure, by reading a computer program stored in the memory 130. In other words, a computer program stored in a computer-readable storage medium (e.g., the memory 130) may cause one or more processors (e.g., the processor 110) to perform operations in accordance with an embodiment of the present disclosure. In addition, the processor 110 may implement any component for performing data processing according to an embodiment of the present disclosure.

According to an exemplary embodiment of the present disclosure, the processor 110 may also perform a computation for learning a neural network. For example, the processor 110 may perform calculations for learning the neural network, which include processing of input data for learning in deep learning (DL), extracting a feature in the input data, calculating an error, updating a weight of the neural network using backpropagation, and the like. At least one of the CPU, GPGPU, DSP, TPU, and NPU of the processor 110 may process learning of a network function. For example, both the CPU and the GPGPU may process the learning of the network function and data classification using the network function. Further, in an exemplary embodiment of the present disclosure, processors of the plurality of computing devices may be used together to process the learning of the network function and the data classification using the network function.

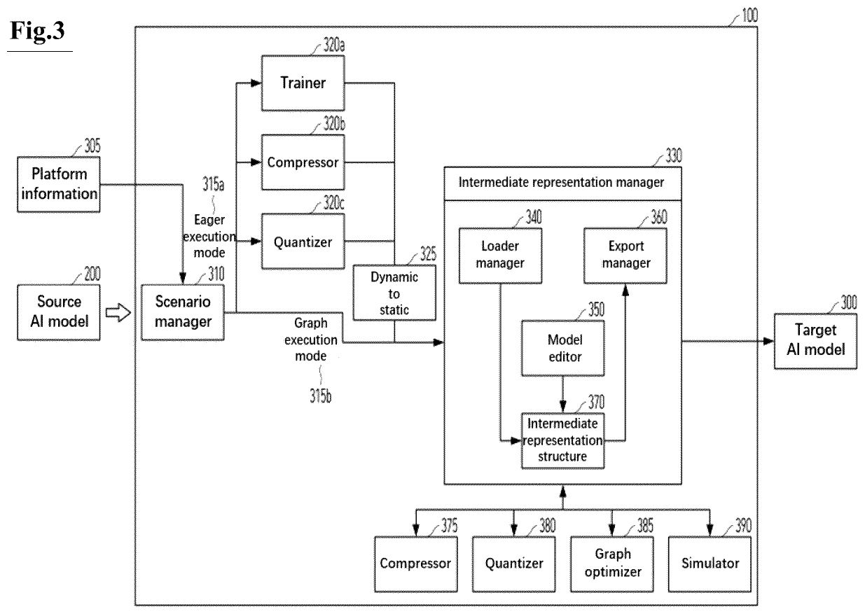

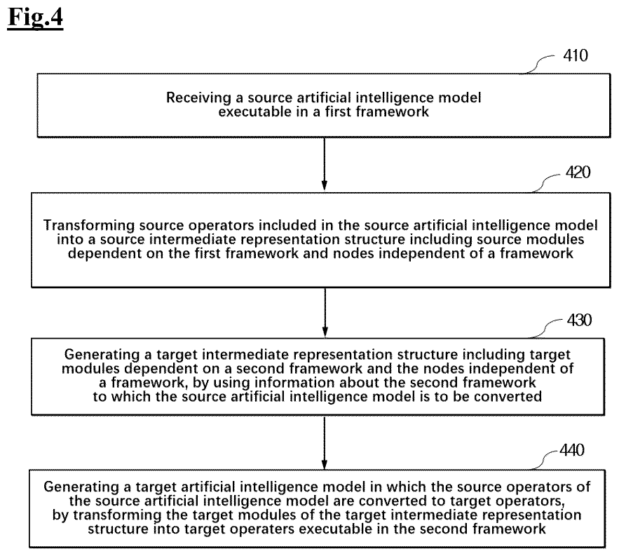

The processor 110 may generally control the overall operation of the computing device 100. For example, the processor 110 may perform the steps included in the flowchart of FIG. 3, which will be described below. By processing signals, data, or information that are input or output through the components included in the computing device 100 or by driving the application program stored in the memory 130, the processor 110 may provide or process appropriate information or functions for the user.

In an embodiment, the computing device 100 may include a System on Chip (SoC). For example, the computing device 100 may include a single chip on which the processor 110, the memory 130, and the network unit 150 shown in FIG. 1 are all mounted. In this case, the SoC may further include any modules for implementing the operations of the computing device 100, such as an I/O interface, a Power Management IC (PMIC), a security module, etc. Meanwhile, it will be apparent to one of ordinary skill in the art that the SoC can be referred to as a processor. Therefore, in such an embodiment, the operations performed by the processor 110 in the present disclosure should be interpreted as being performable by the SoC.

In an embodiment of the present disclosure, the memory 130 may store any type of information generated or determined by the processor 110 and/or any type of information received by the network unit 150. In an embodiment, the memory 130 may store information regarding an artificial intelligence model, information regarding a platform, information regarding an intermediate representation structure, information regarding a simulation, information regarding a benchmark, information regarding a conversion, information regarding a transformation scenario, a scenario DB, and/or information regarding a model optimization tool, and the like. The processor 110 may performs operations in embodiments of the present disclosure using data stored in the memory 130.

In an embodiment of the present disclosure, the memory 130 may mean any type of storage medium, and include, for example, at least one type of storage medium of a flash memory type storage medium, a hard disk type storage medium, a multimedia card micro type storage medium, a card type memory (for example, an SD or XD memory, or the like), a random access memory (RAM), a static random access memory (SRAM), a read-only memory (ROM), an electrically erasable programmable read-only memory (EEPROM), a programmable read-only memory (PROM), a magnetic memory, a magnetic disk, and/or an optical disk. The computing device 100 may operate in connection with a web storage performing a storing function of the memory 130 on the Internet. The memory 130 may include an embedded memory mounted inside the processor 110 and/or a memory mounted outside the processor 110 within the computing device 100. The above description of the memory is just an example and the memory 130 used in the present disclosure is not limited thereto. The memory 130 may be operated by the processor 110.

According to an embodiment of the present disclosure, the network unit 150 may implement any type of wired or wireless communication network capable of transmitting and receiving various types of data and signals. The technologies described in the present specification may be implemented not only through the networks mentioned above, but also through other types of networks.

FIG. 2 illustrates a network function according to an exemplary embodiment of the present disclosure.

Throughout the present disclosure, the artificial intelligence model, the artificial intelligence based model, the operation model, the machine learning model, the deep learning model, the neural network, the network function, and the neural network may be used interchangeably to refer to the same concept.

The neural network may be generally constituted by an aggregate of calculation units which are mutually connected to each other, which may be called “node”. The nodes may also be called neurons. The neural network is configured to include one or more nodes. The nodes (or neurons) constituting the neural networks may be mutually connected to each other by one or more links. The node in FIG. 2 is used to mean a neuron within the artificial intelligence model (i.e., a neural network model), and the node in the intermediate representation structure is used to represent an atomic operator. The node in the intermediate representation structure is used to constitute a module and may have a different meaning from the node corresponding to a neuron in a neural network. A set of nodes in FIG. 2 may represent a layer or an operator, whereas the node in the intermediate representation structure corresponds to an atomic operator that cannot be decomposed.

In the neural network, one or more nodes connected through the link may relatively form a relationship between an input node and an output node. Concepts of the input node and the output node are relative and a predetermined node which has the relationship of the output node with respect to one node may have the relationship of the input node in the relationship with another node and vice versa. As described above, the relationship of the output node to the input node may be generated based on the link. One or more output nodes may be connected to one input node through the link and vice versa.

In the relationship of the input node and the output node connected through one link, a value of data of the output node may be determined based on data input in the input node. Here, a link connecting the input node and the output node to each other may have a weight. The weight may be variable, and the weight may be varied by a user or an algorithm in order for the neural network to perform a desired function. For example, when one or more input nodes are mutually connected to one output node by the respective links, the output node may determine an output node value based on values input in the input nodes connected with the output node and the weights set in the links corresponding to the respective input nodes.

As described above, in the neural network, one or more nodes are connected to each other through one or more links to form the input node and output node relationship in the neural network. A characteristic of the neural network may be determined according to the number of nodes, the number of links, correlations between the nodes and the links, and values of the weights granted to the respective links. For example, when the same number of nodes and links exist and two neural networks in which the weight values of the links are different from each other exist, it may be recognized that two neural networks are different from each other.

The neural network may be constituted by a set of one or more nodes. A subset of the nodes constituting the neural network may constitute a layer. Some of the nodes constituting the neural network may constitute one layer based on the distances from the initial input node. For example, a set of nodes of which distance from the initial input node is n may constitute n layers. The distance from the initial input node may be defined by the minimum number of links which should be passed from the initial input node up to the corresponding node. However, definition of the layer is predetermined for description and the order of the layer in the neural network may be defined by a method different from the aforementioned method. For example, the layers of the nodes may be defined by the distance from a final output node.

In an exemplary embodiment of the present disclosure, the set of the neurons or the nodes may be defined as the expression “layer”.

The initial input node may mean one or more nodes in which data is directly input without passing through the links in the relationships with other nodes among the nodes in the neural network. Alternatively, in the neural network, in the relationship between the nodes based on the link, the initial input node may mean nodes which do not have other input nodes connected through the links. Similarly thereto, the final output node may mean one or more nodes which do not have the output node in the relationship with other nodes among the nodes in the neural network. Further, a hidden node may mean not the initial input node and the final output node but the nodes constituting the neural network.

In the neural network according to an exemplary embodiment of the present disclosure, the number of nodes of the input layer may be the same as the number of nodes of the output layer, and the neural network may be a neural network of a type in which the number of nodes decreases and then, increases again from the input layer to the hidden layer. Further, in the neural network according to another exemplary embodiment of the present disclosure, the number of nodes of the input layer may be smaller than the number of nodes of the output layer, and the neural network may be a neural network of a type in which the number of nodes increases from the input layer to the hidden layer. Further, in the neural network according to yet another exemplary embodiment of the present disclosure, the number of nodes of the input layer may be larger than the number of nodes of the output layer, and the neural network may be a neural network of a type in which the number of nodes decreases from the input layer to the hidden layer. The neural network according to still yet another exemplary embodiment of the present disclosure may be a neural network of a type in which the neural networks are combined.

The deep neural network (DNN) may mean a neural network including a plurality of hidden layers other than the input layer and the output layer. When the deep neural network is used, the latent structures of data may be identified. The deep neural network may include convolutional neural network (CNN), recurrent neural network (RNN), auto encoder, generative adversarial networks (GAN), restricted Boltzmann machine (RBM), deep belief network (DBN), Q network, U network, Siamese network, etc. The description of the deep neural network described above is just an example and the present disclosure is not limited thereto.

The artificial intelligence based model of the present disclosure may be expressed by a network structure of an arbitrary structure described above, including the input layer, the hidden layer, and the output layer.

The neural network which may be used in the artificial intelligence based model of the present disclosure may be learned in at least one scheme of supervised learning, unsupervised learning, semi supervised learning, or reinforcement learning, federated learning for distributed deep learning, and incremental learning. The learning of the neural network may be a process in which the neural network applies knowledge for performing a specific operation to the neural network.

The neural network may be learned in a direction to minimize errors of an output. The learning of the neural network is a process of repeatedly inputting learning data into the neural network and calculating the output of the neural network for the learning data and the error of a target and back-propagating the errors of the neural network from the output layer of the neural network toward the input layer in a direction to reduce the errors to update the weight of each node of the neural network. In the case of the supervised learning, the learning data labeled with a correct answer is used for each learning data (i.e., the labeled learning data) and in the case of the unsupervised learning, the correct answer may not be labeled in each learning data. That is, for example, the learning data in the case of the supervised learning related to the data classification may be data in which category is labeled in each learning data. The labeled learning data is input to the neural network, and the error may be calculated by comparing the output (category) of the neural network with the label of the learning data.

As another example, in the case of the unsupervised learning related to the data classification, the learning data as the input is compared with the output of the neural network to calculate the error. The calculated error is back-propagated in a reverse direction (i.e., a direction from the output layer toward the input layer) in the neural network and connection weights of respective nodes of each layer of the neural network may be updated according to the back propagation. A variation amount of the updated connection weight of each node may be determined according to a learning rate. Calculation of the neural network for the input data and the back-propagation of the error may constitute a learning cycle (epoch). The learning rate may be applied differently according to the number of repetition times of the learning cycle of the neural network. For example, in an initial stage of the learning of the neural network, the neural network ensures a certain level of performance quickly by using a high learning rate, thereby increasing efficiency and uses a low learning rate in a latter stage of the learning, thereby increasing accuracy.

In learning of the neural network, the learning data may be generally a subset of actual data (i.e., data to be processed using the learned neural network), and as a result, there may be a learning cycle in which errors for the learning data decrease, but the errors for the actual data increase. Overfitting is a phenomenon in which the errors for the actual data increase due to excessive learning of the learning data. For example, a phenomenon in which the neural network that learns a cat by showing a yellow cat sees a cat other than the yellow cat and does not recognize the corresponding cat as the cat may be a kind of overfitting. The overfitting may act as a cause which increases the error of the machine learning algorithm. Various optimization methods may be used in order to prevent the overfitting. In order to prevent the overfitting, a method such as increasing the learning data, regularization, dropout of omitting a part of the node of the network in the process of learning, utilization of a batch normalization layer, etc., may be applied.

According to an embodiment of the present disclosure, a computer-readable medium storing a data structure is disclosed. The above-described data structure may be stored in the memory 130 of the present disclosure, executed by the processor 110, and transmitted or received by the network unit 150.

The data structure may refer to the organization, management, and storage of data that enables efficient access to and modification of data. The data structure may refer to the organization of data for solving a specific problem (e.g., data search, data storage, data modification in the shortest time). The data structures may be defined as physical or logical relationships between data elements, designed to support specific data processing functions. The logical relationship between data elements may include a connection relationship between data elements that the user defines. The physical relationship between data elements may include an actual relationship between data elements physically stored on a computer-readable storage medium (e.g., persistent storage device). The data structure may specifically include a set of data, a relationship between the data, a function which may be applied to the data, or instructions. Through an effectively designed data structure, a computing device may perform operations while using the resources of the computing device to a minimum. Specifically, the computing device may increase the efficiency of operation, read, insert, delete, compare, exchange, and search through the effectively designed data structure.

The data structure may be divided into a linear data structure and a non-linear data structure according to the type of data structure. The linear data structure may be a structure in which only one data is connected after one data. The linear data structure may include a list, a stack, a queue, and a deque. The list may mean a series of data sets in which an order exists internally. The list may include a linked list. The linked list may be a data structure in which data is connected in a scheme in which each data is linked in a row with a pointer. In the linked list, the pointer may include link information with next or previous data. The linked list may be represented as a single linked list, a double linked list, or a circular linked list depending on the type. The stack may be a data listing structure with limited access to data. The stack may be a linear data structure that may process (e.g., insert or delete) data at only one end of the data structure. The data stored in the stack may be a data structure (LIFO-Last in First Out) in which the data is input last and output first. The queue is a data listing structure that may access data limitedly and unlike a stack, the queue may be a data structure (FIFO-First in First Out) in which late stored data is output late. The deque may be a data structure capable of processing data at both ends of the data structure.

The non-linear data structure may be a structure in which a plurality of data are connected after one data. The non-linear data structure may include a graph data structure. The graph data structure may be defined as a vertex and an edge, and the edge may include a line connecting two different vertices. The graph data structure may include a tree data structure. The tree data structure may be a data structure in which there is one path connecting two different vertices among a plurality of vertices included in the tree. That is, the tree data structure may be a data structure that does not form a loop in the graph data structure.

The data structure may include the neural network. In addition, the data structures, including the neural network, may be stored in a computer readable medium. The data structure including the neural network may also include data preprocessed for processing by the neural network, data input to the neural network, weights of the neural network, hyper parameters of the neural network, data obtained from the neural network, an active function associated with each node or layer of the neural network, and a loss function for learning the neural network. The data structure including the neural network may include predetermined components of the components disclosed above. In other words, the data structure including the neural network may include all of data preprocessed for processing by the neural network, data input to the neural network, weights of the neural network, hyper parameters of the neural network, data obtained from the neural network, an active function associated with each node or layer of the neural network, and a loss function for learning the neural network or a combination thereof. In addition to the above-described configurations, the data structure including the neural network may include predetermined other information that determines the characteristics of the neural network. In addition, the data structure may include all types of data used or generated in the calculation process of the neural network, and is not limited to the above. The computer readable medium may include a computer readable recording medium and/or a computer readable transmission medium. The neural network may be generally constituted by an aggregate of calculation units which are mutually connected to each other, which may be called “node”. The nodes may also be called neurons. The neural network is configured to include one or more nodes.

The data structure may include data input into the neural network. The data structure including the data input into the neural network may be stored in the computer readable medium. The data input to the neural network may include learning data input in a neural network learning process and/or input data input to a neural network in which learning is completed. The data input to the neural network may include preprocessed data and/or data to be preprocessed. The preprocessing may include a data processing process for inputting data into the neural network. Therefore, the data structure may include data to be preprocessed and data generated by preprocessing. The data structure is just an example and the present disclosure is not limited thereto.

The data structure may include the weight of the neural network (in the present disclosure, the weight and the parameter may be used as the same meaning). In addition, the data structures, including the weight of the neural network, may be stored in the computer readable medium. The neural network may include a plurality of weights. The weight may be variable and the weight may be varied by a user or an algorithm in order for the neural network to perform a desired function. For example, when one or more input nodes are mutually connected to one output node by the respective links, the output node may determine a data value output from an output node based on values input in the input nodes connected with the output node and the weights set in the links corresponding to the respective input nodes. The data structure is just an example and the present disclosure is not limited thereto.

As a non-limiting example, the weight may include a weight which varies in the neural network learning process and/or a weight in which neural network learning is completed. The weight which varies in the neural network learning process may include a weight at a time when a learning cycle starts and/or a weight that varies during the learning cycle. The weight in which the neural network learning is completed may include a weight in which the learning cycle is completed. Accordingly, the data structure including the weight of the neural network may include a data structure including the weight which varies in the neural network learning process and/or the weight in which neural network learning is completed. Accordingly, the above-described weight and/or a combination of each weight are included in a data structure including a weight of a neural network. The data structure is just an example and the present disclosure is not limited thereto.

The data structure including the weight of the neural network may be stored in the computer-readable storage medium (e.g., memory, hard disk) after a serialization process. Serialization may be a process of storing data structures on the same or different computing devices and later reconfiguring the data structure and converting the data structure to a form that may be used. The computing device may serialize the data structure to send and receive data over the network. The data structure including the weight of the serialized neural network may be reconfigured in the same computing device or another computing device through deserialization. The data structure including the weight of the neural network is not limited to the serialization. Furthermore, the data structure including the weight of the neural network may include a data structure (for example, B-Tree, R-Tree, Trie, m-way search tree, AVL tree, and Red-Black Tree in a nonlinear data structure) to increase the efficiency of operation while using resources of the computing device to a minimum. The above-described matter is just an example and the present disclosure is not limited thereto.

The data structure may include hyper-parameters of the neural network. In addition, the data structures, including the hyper-parameters of the neural network, may be stored in the computer readable medium. The hyper-parameter may be a variable which may be varied by the user. The hyper-parameter may include, for example, a learning rate, a cost function, the number of learning cycle iterations, weight initialization (for example, setting a range of weight values to be subjected to weight initialization), and Hidden Unit number (e.g., the number of hidden layers and the number of nodes in the hidden layer). The data structure is just an example, and the present disclosure is not limited thereto.

An artificial intelligence-based model according to an embodiment of the present disclosure may include a Large Language Model (LLM). In the present disclosure, a Large Language Model may refer to an artificial intelligence-based model trained using a vast amount of training data to perform Natural Language Processing. A Large Language Model may include a transformer, an encoder-type model of a transformer, and/or a decoder-type model of a transformer. An encoder-type model of a transformer may correspond to an artificial intelligence model that uses the encoder structure of a transformer. A decoder-type model of a transformer may correspond to an artificial intelligence model that uses the decoder structure of a transformer. As an example, the artificial intelligence-based model of the present disclosure may include a GPT-family Large Language Model, a Bidirectional Encoder Representations from Transformers (BERT)-family Large Language Model, and the like.

In an embodiment, a transformer may be composed of an encoder that encodes input data and a decoder that decodes the encoded data. A transformer may have a structure that takes a series of input data as input and outputs a series of output data through encoding and decoding steps. In an embodiment, the series of input data may be processed into a form that a transformer can compute. The process of processing the series of input data into a computable form for the transformer may include a tokenizing process and an embedding process. The tokenizing process may refer to a process of dividing a series of input data into tokens of a certain unit. For example, the certain unit may include a word unit. The embedding process may refer to a process of converting at least one token, tokenized from the series of input data, into an embedding vector.

In an embodiment, a transformer can obtain an embedding vector to be input into an encoder by summing a token embedding vector, which embeds at least one token corresponding to a series of input data, a segment embedding vector that distinguishes the sentence containing the token for each token, and a position embedding vector that reflects the position of the token. Encoder-type models and decoder-type models of a transformer may also perform the same method to obtain an embedding vector.

In an embodiment, for a transformer to encode and decode a series of input data, the encoder and decoder within the transformer may utilize an attention algorithm. The attention algorithm may refer to an algorithm that, for a given Query, calculates a similarity by applying a softmax function to an attention score obtained by matrix-multiplying the Query with a Key, and then calculates an attention value for the Query by matrix-multiplying the calculated similarity with a Value.

In an embodiment, a self-attention algorithm may refer to an attention algorithm that uses a Query, Key, and Value generated by respectively multiplying the same embedding vector by a query weight, a key weight, and a value weight. A cross-attention algorithm may refer to an attention algorithm that uses a Query generated by multiplying a first embedding vector by a query weight, and a Key and a Value generated by respectively multiplying a second embedding vector by a key weight and a value weight. The query weight, key weight, and value weight may be trainable parameters that are updated through the learning process of the Large Language Model.

In an embodiment, the encoder of a transformer may include an embedding layer, a self-attention layer that applies a self-attention algorithm to an embedding vector, a normalization layer, and a Feed Forward Neural Network (FFN). Furthermore, the encoder may have a form in which N unit structures, each comprising a self-attention layer, a normalization layer, and a feed-forward neural network, are connected. The decoder of a transformer may include an embedding layer, a masked self-attention layer, a normalization layer, a cross-attention layer that applies a cross-attention algorithm, and a feed-forward neural network. Furthermore, the decoder may have a form in which N unit structures, each comprising a masked self-attention layer, a normalization layer, a cross-attention layer, and a feed-forward neural network, are connected. The masked self-attention layer may correspond to a layer that calculates an attention value for each of the sequences in which words are sequentially included, for a plurality of words included in a series of input data.

A transformer may include not only an encoder and a decoder but also additional components such as a linear layer, a softmax layer, etc. Encoder-family models and decoder-family models of a transformer may also respectively include not only an encoder and a decoder but also the aforementioned additional components. A method for constructing a transformer using an attention algorithm may include the method disclosed in Vaswani et al., “Attention Is All You Need,” 2017 NIPS, which is incorporated herein by reference.

In an embodiment, an attention layer such as a self-attention layer, a masked self-attention layer, or a cross-attention layer may correspond to a multi-head attention layer that includes a plurality of attention layers in parallel. The multi-head attention layer can concatenate the attention values output from each of the plurality of attention layers, and matrix-multiply the concatenated matrix with an output weight to output an output attention value. The output attention value output from the multi-head attention layer may have the same size as the attention value output from a single attention layer.

In an embodiment, a transformer may be trained through a Masked Language Model (MLM) process, a Next Sentence Prediction (NSP) process, and the like. The MLM process may refer to a learning process that predicts a masked word through a series of training data in which some words are masked. The NSP process may refer to a learning process that determines whether two sentences are connected in a series of training data that includes two arbitrary sentences.

In an embodiment, a Large Language Model can process not only natural language text but also various data formats such as image data, audio data, and video data. A Large Language Model can embed data to convert data with various formats into a series of computable data. A Large Language Model can process additional data that represents the relative positional relationship or topological relationship between a series of input data. Alternatively, a series of input data can be embedded by additionally reflecting vectors that represent the relative positional relationship or topological relationship between the input data. As an example, the relative positional relationship between a series of input data may include, but is not limited to, the word order within a natural language sentence, the relative positional relationship of each divided image, the time sequence of a divided audio waveform, etc. The process of adding information that represents the relative positional or topological relationship between a series of input data may be referred to as positional encoding.

An example of a Large Language Model that processes image data (Vision Transformer, ViT) is disclosed in Dosovitskiy, et al., “AN IMAGE IS WORTH 16×16 WORDS: TRANSFORMERS FOR IMAGE RECOGNITION AT SCALE,” and this document is incorporated herein by reference.

An artificial intelligence model according to an embodiment of the present disclosure may include a multi-modal Large Language Model. A multi-modal Large Language Model may refer to a Large Language Model that can understand and process the relationship between mutually different data formats, such as natural language text data, image data, audio data, and video data. A multi-modal language model may include a plurality of encoders that encode input data corresponding to each data format. The multi-modal language model can be trained, through training data that includes data of mutually different formats, to calculate the similarity between embedding vectors encoded from the encoder of each data format, such that the similarity for the same pairs is calculated to be higher, and the similarity for different pairs is calculated to be lower.

An example of a multi-modal Large Language Model that understands and processes the relationship between image data and natural language text data (Contrastive Language-Image Pre-training, CLIP) is disclosed in Alec Radford, et al., “LEARNING TRANSFERABLE VISUAL MODELS FROM NATURAL LANGUAGE SUPERVISION,” and this document is incorporated herein by reference.

FIG. 3 is a block diagram illustrating, by way of example, a structure for transforming an artificial intelligence model according to an embodiment of the present disclosure.

Entities illustrated in FIG. 3 are illustrated as being included in computing device 100. According to an implementation aspect, some of the entities of FIG. 3 may be operated by interacting with the computing device 100 from outside the computing device 100. According to an implementation aspect, a method in which an additional entity other than the entities of FIG. 3 is included in the computing device 100 and operated may also be implemented.

In an embodiment, the computing device 100 may receive a source artificial intelligence model 200. For example, the source artificial intelligence model 200 may refer to an artificial intelligence model that is an object of transformation. For example, the source artificial intelligence model 200 may refer to an artificial intelligence model to be transformed or converted. For example, the source artificial intelligence model 200 may refer to a model executable on a source framework. For example, the source artificial intelligence model 200 may be an object of transformation to a target artificial intelligence model 300 executable on a target framework. For example, the source artificial intelligence model 200 may refer to an artificial intelligence model received and/or input from a user terminal. For example, the source artificial intelligence model 200 may refer to a model configured with one or more operators or layers executable on the source framework. In the present disclosure, an operator and a layer may be used interchangeably according to an implementation aspect. For example, the source artificial intelligence model 200 may include framework information on which the source artificial intelligence model 200 is executable. For example, the source artificial intelligence model 200 may include identification information of the artificial intelligence model, executable file information of the artificial intelligence model, training dataset information of the artificial intelligence model, execution environment information of the artificial intelligence model, and/or framework information of the artificial intelligence model. For example, the computing device 100 may receive information for identifying the source artificial intelligence model 200 or a file of the source artificial intelligence model 200, and may extract the training dataset information of the artificial intelligence model, the execution environment information of the artificial intelligence model, and/or the framework information of the artificial intelligence model, by using the received information or file. In an embodiment, the computing device 100 may receive, from a user terminal, information on the source artificial intelligence model 200 and a target framework (a framework different from the source framework) on which the source artificial intelligence model 200 is intended to be executed. The computing device 100 may transform the source artificial intelligence model 200 into a target artificial intelligence model 300 executable on the target framework. The computing device 100 may transform the source artificial intelligence model 200 into the target artificial intelligence model 300 executable on the target framework by considering constraint(s) included in platform information 305. For example, the computing device 100 may receive the source artificial intelligence model 200 together with a target framework (e.g., PyTorch, ONNX, and TFlite, etc.) to which the corresponding model is to be transformed, and the target framework herein may represent a framework different from a source framework on which the source artificial intelligence model 200 is executable.

In an additional embodiment, the computing device 100 may, in response to receiving the source artificial intelligence model 200 and/or the target framework, automatically generate recommendation information for candidate platforms that support the target framework. In response to a user selection input on this recommendation information, a target platform that becomes an object of transformation may be determined from among the candidate platforms. In this embodiment, the platform information 305 may be determined in response to the user selection input on the recommendation information. In this embodiment, the platform information 305 may also be automatically determined by the computing device 100 in response to receiving the target framework.

In an embodiment, the computing device 100 may receive platform information 305. The platform information 305 may include information for identifying a hardware and/or information for identifying a compiler. The platform information 305 may define an environment in which the transformed target artificial intelligence model 300 is to be executed. The platform information 305 may identify a hardware and/or a compiler that is a target of execution of the source artificial intelligence model 200. The platform information 305 may be received and/or input from a user terminal. In an embodiment, the platform information 305 may include at least one of a hardware on which an artificial intelligence model is to be executed, a compiler for connecting the artificial intelligence model to the hardware, and a runtime representing an environment of the hardware on which the artificial intelligence model is to be executed. The computing device 100 may extract or generate information regarding the hardware and/or information regarding the compiler on which the source artificial intelligence model 200 is intended to be executed, from the platform information 305. For example, the information regarding the hardware included in the platform information 305 may include, for example, information regarding a CPU, GPU, NPU, and FPGA, etc. The information regarding the hardware may refer to any form of information for identifying the hardware on which the artificial intelligence model can be executed (e.g., on which the source artificial intelligence model 200 is intended to be executed). For example, the information regarding the hardware may include information related to the physical components of a system and their characteristics, structure, performance, compatibility, and the like. For example, the information regarding the hardware may include at least one of identification information of the hardware, information on a supportable framework, information on a supportable data type, information on a supportable operator, or information on a supportable granularity. As another example, the information regarding the hardware may include a hardware constraint. The hardware constraint may include at least one of whether each of the data types of an operator is supported, whether hardware operational acceleration for an operator is supported, or whether a speed is improved for each of the data types of an operator. For example, a data type may be the type of values that can be used when storing and processing data in a hardware or programming language, and the method of their representation. A data type may be a type of data classified according to the method of data storage and operation. For example, a data type may include an integer type, a real number type, a character type, and the like. A hardware supports operations for a specific data type, and each data type may have a different memory size and representation range. For example, information regarding the compiler included in the platform information 305 may refer to any form of information for identifying an entity that connects the artificial intelligence model and the hardware. For example, a platform may be identified and/or managed in units of a combination of a hardware and a compiler. For example, a platform may be identified and/or managed in units of a combination of a hardware and a compiler within the computing device 100. As the platform information 305 is received, information regarding a related platform may be extracted or generated by the computing device 100.

In an embodiment, the computing device 100 may determine a transformation scenario of the source artificial intelligence model 200 by using the source artificial intelligence model 200 and the platform information 305. In an embodiment, a scenario manager 310 of the computing device 100 may determine a transformation scenario by using the source artificial intelligence model 200 and the platform information 305. In an embodiment, the scenario manager 310 may generate a target transformation scenario to be applied to the source artificial intelligence model 200 from among a plurality of transformation scenarios, by using the source artificial intelligence model 200 and the platform information 305 (and/or target performance information). In an embodiment, the scenario manager 310 may generate a plurality of transformation scenarios to construct a scenario database. The scenario manager 310 may refer to a component (e.g., a software component) that performs a specific function in the computing device 100.

In an embodiment, the scenario manager 310 of the computing device 100 may access a scenario database that stores a plurality of transformation scenarios, and may determine a target transformation scenario to be applied to the source artificial intelligence model 20 from among the plurality of transformation scenarios by using the source artificial intelligence model 200 and the platform information 305.

In an embodiment, each of the plurality of transformation scenarios stored in the scenario database may identify a combination of model optimization tools to be executed on an artificial intelligence model. Each of the plurality of transformation scenarios stored in the scenario DB may identify a second combination of model optimization tools 320a, 320b, 320c, 375, 380, 385 and/or 390 for a first combination of an artificial intelligence model and a platform. For example, a combination of an artificial intelligence model named A, a platform named B, and model optimization tools arranged in the order of C, D, E, and F may be included in a single transformation scenario. The scenario DB can manage the combination of model optimization tools 320a, 320b, 320c, 375, 380, 385 and/or 390 for the combination of an artificial intelligence model and a platform, for example, in a table-like structure. For example, each of the plurality of transformation scenarios may identify, for a first combination of an artificial intelligence model and a platform, an order in which the model optimization tools 320a, 320b, 320c, 375, 380, 385 and/or 390 are applied to the artificial intelligence model.

In an embodiment, the computing device 100 may access the scenario DB and input a combination of the source artificial intelligence model 200 and the platform information 305 into the scenario DB. The computing device 100 may receive, obtain, or determine a target transformation scenario that matches the combination of the source artificial intelligence model 200 and the platform information 305 among the plurality of transformation scenarios. As the computing device 100 obtains the target transformation scenario that matches the combination of the source artificial intelligence model 200 and the platform information 305, it may receive, obtain, and/or determine identification information of model optimization tools and/or the execution order of the model optimization tools stored in the target transformation scenario. As a non-limiting example, the order in which the model optimization tools identified in each of the plurality of transformation scenarios are applied to an artificial intelligence model may be determined based on a performance change prediction value by each of the model optimization tools and a constraint according to the platform.

In an embodiment, the scenario DB may include identification information of an artificial intelligence model or identification information of a block of an artificial intelligence model, identification information of a model optimization tool or identification information of an optimization scheme, and performance information related to the artificial intelligence model to which the model optimization tool or the optimization scheme has been applied. The scenario DB may represent the aforementioned information in a table structure.

In an embodiment, the scenario DB may store and manage a plurality of transformation scenarios. Each of the plurality of transformation scenarios may indicate a performance prediction value for a first combination of an artificial intelligence model and a platform, when the model optimization tools are applied to the artificial intelligence model. For example, the performance prediction value may refer to the expected execution performance of the artificial intelligence model when the artificial intelligence model to which the model optimization tools have been applied is executed on the platform. For example, the performance prediction value may include at least one of an accuracy of the artificial intelligence model, an inference speed of the artificial intelligence model, and a degree of lightweighting of the artificial intelligence model. For example, the scenario DB may manage a plurality of transformation scenarios and the expected execution performance according to the scenarios in the form of a table structure.

In an embodiment, the computing device 100 may calculate a model similarity between the source artificial intelligence model 200 and a plurality of candidate artificial intelligence models stored in the scenario DB. For example, the model similarity may be determined by using identification information of operators (or layers) included in the model and/or connection information of the operators. For example, the model similarity may be calculated for each of the source artificial intelligence model 200 and the candidate artificial intelligence models stored in the scenario DB in units of groups of operators (e.g., blocks) included in the model. In an embodiment, the model similarity may be determined by transforming a model into an intermediate representation structure and calculating a similarity between the intermediate representation structures of models. For example, the computing device 100 may transform the source artificial intelligence model 200 into a graph structure and quantitatively measure the model similarity between artificial intelligence models by using, as factors, patterns of nodes, identification information of nodes, the number of nodes, identification information of modules, the number of modules, and/or patterns of modules within the graph structure. For example, the computing device 100 may calculate the similarity between entire models by a method of measuring a sub-similarity between a plurality of artificial intelligence models in units of operators or blocks constituting the artificial intelligence models and combining the measured sub-similarities. For example, the computing device 100 may measure the similarity between artificial intelligence models, even if they include the same blocks or the same operators, by using a cosine similarity on the output values for the same input, because the lightweighting performance may differ if the weights are different, and this similarity may be utilized in the model similarity measurement. In an embodiment, the computing device 100 may preemptively use the model similarity to determine the artificial intelligence model most similar to the source artificial intelligence model 200 within the scenario DB, and may search on the scenario DB for a scenario that maps to the hardware, compiler, user environment, and target performance for the determined model. In an embodiment, in a situation where the model similarity is lower than a similarity threshold, the computing device 100 may determine that it cannot find a model similar to the source artificial intelligence model 200 in the scenario DB and may perform a transformation scenario preparation process for storing the source artificial intelligence model 200 as a new model in the scenario DB. In such an embodiment, the computing device 100 may determine whether to change to the transformation scenario preparation process or maintain the transformation scenario execution process, based on a result of the comparison of the model similarity between the source artificial intelligence model 200 and the models on the scenario DB.

In an embodiment, the computing device 100 may determine the target transformation scenario to be applied to the source artificial intelligence model 200 from among the plurality of transformation scenarios stored in the scenario DB, by using the model similarity, the platform information 305, and/or a target performance value specified by the user as conditions. The computing device 100 may perform a search within the scenario DB by using the aforementioned condition(s) as a filtering criterion. For example, the computing device 100 may perform a search on the scenario DB by using a combination of the model similarity, the platform information 305, and the target performance value as a filtering criterion. Through such a search according to the filtering criterion, a target transformation scenario corresponding to the user's intent can be efficiently obtained.

In an embodiment, the computing device 100 may determine a reference artificial intelligence model corresponding to the source artificial intelligence model 200 among the candidate models stored in the scenario DB, based on the calculation result of the model similarity for the source artificial intelligence model 200 and each of the candidate artificial intelligence models stored in the scenario DB. The computing device 100 may determine a scenario that is mapped to the platform information 305 and/or the target performance value specified by the user as the target transformation scenario, based on the reference artificial intelligence model. For example, the computing device 100 may determine a reference artificial intelligence model with the highest similarity to the source artificial intelligence model 200 from among the candidate artificial intelligence models, and may filter a plurality of transformation scenarios including the reference artificial intelligence model within the scenario DB by utilizing the determined reference artificial intelligence model as a search criterion. The computing device 100 may determine the target transformation scenario, which is the optimal transformation scenario that meets the user's intent, from among the filtered transformation scenarios, by using the platform information 305 and/or user requirements (e.g., target performance value, etc.) as an additional filtering condition.

In an embodiment, the computing device 100 may additionally receive a target performance value. This target performance value may define a performance value that serves as a criterion for the transformation of the source artificial intelligence model 200. The computing device 100 may compare the target performance value with the performance prediction value of each of the transformation scenarios (or each of the model optimization tools) in the scenario DB and may determine the target transformation scenario to be applied to the source artificial intelligence model 200 based on the result of the comparison. For example, the computing device 100 may search for and/or determine the target transformation scenario on the scenario DB, which is a relational DB with a table structure, in a resource-efficient manner, by using the identification information of the source artificial intelligence model 200, the platform information 305, and the target performance value as search conditions. For example, the computing device 100 may compare the target performance value with each of the performance prediction values (of each of the transformation scenarios) stored in the scenario DB, and may perform a search according to the combination of the source artificial intelligence model 200 and the platform information 305 on the transformation scenarios that have passed a criterion based on the comparison. In this manner, the optimization method for the user's artificial intelligence model according to the conditions intended by the user can be automatically determined with efficient use of computing resources.

In an embodiment, the computing device 100 may measure the model similarity between a plurality of artificial intelligence models registered in the scenario DB and the source artificial intelligence model 200. The model similarity may represent the similarity between combinations of components (e.g., operators (layers)) included in the model. A target scenario that is the most similar to the criteria may be determined from among the plurality of transformation scenarios stored on the scenario DB, based on the model similarity, hardware information and compiler information included in the platform information 305, the user environment, and/or the target performance. For example, if the user environment is incapable of training or if no data exists, it may be determined that a trainer 320a cannot be used, and transformation scenarios in which a trainer 320a exists may be filtered-out from among the transformation scenarios. For example, if the user environment is incapable of training or if no data exists, even if the execution mode of the source artificial intelligence model 200 is determined to be the eager execution mode 315a, a transformation scenario that does not include an advanced compressor 320b and/or an advanced quantizer 320c may be determined as the target transformation scenario.

In an embodiment, the computing device 100 may vary the method of determining the target transformation scenario according to the execution scheme or execution mode of the source artificial intelligence model 200. For example, a correlation between the execution scheme, execution mode, or execution type of the source artificial intelligence model 200 and the determination method of the target transformation scenario may be automatically determined by the computing device 100. For example, the computing device 100 may determine the execution mode of the source artificial intelligence model 200 as one of an eager execution mode 315a and a graph execution mode 315b. For example, the eager execution mode 315a may refer to a scheme of executing operations in the artificial intelligence model without converting to a graph. For example, the graph execution mode 315b may refer to a scheme of converting operations to a graph before the execution of the artificial intelligence model. Each of the artificial intelligence models has an execution mode defined for its execution. The computing device 100 may determine what the execution mode of the source artificial intelligence model 200 is by using the identification information of the source artificial intelligence model 200 and/or by parsing a file of the source artificial intelligence model 200 (e.g., analysis of identification information and connection structure of operators). For example, the computing device 100 may determine whether the source artificial intelligence model 200 is in an eager execution mode 315a or a graph execution mode 315b by executing the source artificial intelligence model 200 on a specific platform. For example, if it is confirmed that the source artificial intelligence model 200 immediately executes an operator during its execution process, the computing device 100 may classify the source artificial intelligence model as being in an eager execution mode 315a. For example, if it is confirmed or checked that the source artificial intelligence model adds an operator to a computation graph during its execution process and executes the computation graph all at once, the computing device 100 may classify the source artificial intelligence model 200 as being in a graph execution mode 315a. In an additional example, the computing device 100 may classify the source artificial intelligence model 200 as being in an eager execution mode 315a if a framework (e.g., a source framework) of the source artificial intelligence model 200 is analyzed and the analyzed source framework belongs to a first group of frameworks, and as being in a graph execution mode 315b if it belongs to a second group of frameworks.

In an embodiment, the computing device 100 may receive a model and/or an intermediate representation corresponding to various frameworks such as, for example, PyTorch, ONNX, and TFLite as an input, determine a scenario for sequentially executing model optimization tools by using the scenario manager 310, and execute the model optimization tools accordingly (e.g., according to the scenario). As a non-limiting example, the model optimization tools may include a trainer 320a, a compressor 320b, and a quantizer 320d that are executed in an eager execution mode (e.g., Pytorch). As a non-limiting example, the model optimization tools may include an intermediate representation manager 330, a compressor 375, a quantizer 380, a graph optimizer 385, and a simulator 390 that are executed in a graph execution mode. The graph execution mode is a mode that is represented and executed as a graph without operating in an eager execution mode such as, for example, the PyTorch framework. If a graph has a dynamic graph, it can be converted to a static graph through dynamic to static 325. For example, frameworks such as ONNX, TFLite, etc., can be represented as a static graph.

In an embodiment, the computing device 100 may determine filtered candidate transformation scenarios that include the determined execution mode from among the plurality of transformation scenarios stored in the scenario DB by using the determined execution mode of the source artificial intelligence model 200 as a filtering criterion. The computing device 100 may determine the target transformation scenario to be applied to the source artificial intelligence model 200 from among the filtered candidate transformation scenarios. Since this method can reduce the search space of the scenario DB in the process of determining the target transformation scenario, a technical effect can be achieved in that the technique according to an embodiment of the present disclosure can determine the execution order of model optimization tools suitable for user requirements while efficiently using computing resources.

In an embodiment, the computing device 100 may determine to use a different model optimization tool or a different set of model optimization tools, according to the execution mode of the source artificial intelligence model 200. A correlation may be set between the execution mode of the source artificial intelligence model 200 and a combination of model optimization tools to be executed on the source artificial intelligence model 200.

For example, when the source artificial intelligence model 200 is determined to be in the eager execution mode 315a, the computing device 100 may determine the model optimization tool(s) to be executed on or applied to the source artificial intelligence model 200 within a set of model optimization tools including a trainer 320a, a compressor 320b, and a quantizer 320c for the source artificial intelligence model 200. For example, a set of model optimization tools including a trainer 320a, a compressor 320b, and a quantizer 320c may be used when the execution mode of the source artificial intelligence model 200 is determined to be the eager execution mode 315a. For example, the trainer 320a may operate to train the source artificial intelligence model 200. For example, the compressor 320b may refer to an advanced compressor. For example, the quantizer 320c may refer to an advanced quantizer. For example, the trainer 320a, the compressor 320b, and/or the quantizer 320c may perform training, compression, and/or quantization of an artificial intelligence model through a runtime operation, not an intermediate representation structure. For example, the trainer 320a, the compressor 320b, and/or the quantizer 320c may perform training, compression, and/or quantization of an artificial intelligence model through a runtime operation, not a graph structure.

In an embodiment, the computing device 100 may transfer a corresponding model to an intermediate representation manager 330 by performing a dynamic to static transformation on an output from the trainer 320a, the compressor 320b, and/or the quantizer 320c. For example, the dynamic to static transformation may refer to transforming a model written or developed in an Eager execution mode (e.g., a dynamic execution mode) into a graph execution mode (e.g., a static graph execution mode). For example, the computing device 100 may trace an execution path of code on the Eager execution mode and may generate a computation graph structure corresponding to the graph execution mode by using a trace result for the execution path.

In an embodiment, the intermediate representation structure may, for example, include a static graph of a deep learning framework such as TensorFlow or Onnx, and/or may include a dynamic graph in the form of an Eager execution mode of a deep learning framework such as PyTorch. For example, the computing device 100 may receive an artificial intelligence model in the form of a static graph and may transform it into an intermediate representation structure 370. For example, the computing device 100 may receive an artificial intelligence model in the form of a dynamic graph and may transform it into an intermediate representation structure 370. The computing device 100 may receive an artificial intelligence model to which model optimization tool(s) 320a, 320b, and 320c have been applied and may generate it as an intermediate representation structure 370.

In an additional embodiment, when the source artificial intelligence model 200 is determined to be in the eager execution mode 315a, the computing device 100 may also change the source artificial intelligence model 200 to a graph execution mode without applying the trainer 320a, the compressor 320b, and/or the quantizer 320c, by applying a dynamic to static transformation to the source artificial intelligence model 200.

For example, when the source artificial intelligence model 200 is determined to be in the graph execution mode 315a, the computing device 100 may determine the model optimization tool(s) to be executed on or applied to the source artificial intelligence model 200 within a set of model optimization tools including a compressor 375, a quantizer 380, and/or a graph optimizer 385 for the source artificial intelligence model 200. For example, when the source artificial intelligence model 200 is determined to be in the graph execution mode 315a, the computing device 100 may determine the model optimization tool(s) to be executed on or applied to the source artificial intelligence model 200 within a set of model optimization tools including a compressor 375, a quantizer 380, a graph optimizer 385, and/or a simulator 390 for the source artificial intelligence model 200. For example, when the source artificial intelligence model 200 is determined to be in the graph execution mode 315a, the computing device 100 may, by using an intermediate representation manager 330, transform the source artificial intelligence model into an intermediate representation structure and allow model optimization tools (e.g., 375, 380, 385, and/or 390) to be executed on the intermediate representation structure.

In an embodiment, the intermediate representation manager 330 may be configured to generate a target artificial intelligence model 330 by transforming an artificial intelligence model into an intermediate representation structure 370 and applying an optimization and/or converting to the intermediate representation structure 370. For example, the intermediate representation manager 330 may be operated as a component within the computing device 100. For example, the intermediate representation manager 330 may refer to software that defines and/or performs the aforementioned functions within the computing device 100.

In an embodiment, the intermediate representation manager 330 may include a loader manager 340, a model editor 350, and/or an export manager 360.

In an embodiment, the loader manager 340 may be configured to transform an artificial intelligence model into an intermediate representation structure 370. The loader manager 340 is operable as a component within the computing device 100 and may refer to software that performs a function for transforming into the intermediate representation structure 370. The loader manager 340 may transform an artificial intelligence model into a hierarchical structure composed of a node corresponding to an atomic operator and a module which is a set of nodes. The loader manager 340 may transform an artificial intelligence model into a graph structure composed of a node, a module, and a tensor. The loader manager 340 may generate an intermediate representation structure 370 that represents a dependency relationship or a hierarchical relationship between a node independent of a framework and a module dependent on a framework. For example, a method in which the loader manager 340 generates a loader corresponding to an artificial intelligence model and an intermediate representation structure 370 for the artificial intelligence model is generated through the loader may also be possible according to an implementation aspect. The loader manager 340 may be operated to take an artificial intelligence model (e.g., a source artificial intelligence model) as an input and an intermediate representation structure 370 as an output. For example, the loader manager 340 may store and manage a plurality of loaders. For example, the loader manager 340 may manage loaders prepared for each framework of an artificial intelligence model, such as a TensorFlow loader, a TensorFlow Lite loader, an ONNX loader, and/or a PyTorch loader. The loader manager 340 may determine a loader suitable for an artificial intelligence model to generate an intermediate representation structure 370 based on a parsing result of the artificial intelligence model, and may call the determined loader to allow an intermediate representation structure 370 corresponding to the artificial intelligence model to be generated. In an embodiment, a loader or the loader manager 340 may wrap an input of an artificial intelligence model with a proxy and may transform operators dependent on the framework of the artificial intelligence model into modules to generate a graph-type intermediate representation structure.

In an embodiment, the model editor 350 may be configured to modify or transform the generated intermediate representation structure 370. The model editor 350 may, in conjunction with model optimization tools, generate an intermediate representation structure 370 in which an optimization of the model optimization tools is reflected. The model editor 350 may be configured to modify the intermediate representation structure 370 according to a result of a channel axis transformation and/or a dimension transformation. The model editor 350 is operable as a component within the computing device 100 and may refer to software that performs a function for changing or editing the intermediate representation structure 370.

In an embodiment, the export manager 360 may be configured to transform the intermediate representation structure 370 to correspond to a target framework of a target artificial intelligence model 300. The export manager 360 may be operated to take the intermediate representation structure 370 as an input and a target artificial intelligence model 300 as an output. The export manager 360 may be configured to transform (e.g., convert) nodes of the intermediate representation structure 370 by combining them into module(s) dependent on a target framework. For example, the export manager 360 may generate a converter that converts a model (e.g., a framework of the model) to a corresponding framework (e.g., a target framework), and model converting to a target framework may be performed by using the generated converter. For example, the export manager 360 may store and manage a plurality of converters. For example, the export manager 360 may manage a corresponding converter in units of a combination of a source framework and a target framework. For example, the export manager 360 may manage a corresponding converter in units of a framework. For example, the export manager 360 may manage converters prepared for each framework of an artificial intelligence model, such as a TensorFlow converter, a TensorFlow Lite converter, an ONNX converter, and/or a PyTorch converter. The export manager 360 may determine a converter suitable for a target artificial intelligence model 300 to convert an intermediate representation structure 370 based on a target framework of the target artificial intelligence model 300, and may call the determined converter to transform the intermediate representation structure 370 into the target artificial intelligence model 300.

In an embodiment, the export manager 360 may include one or more converters that transform an intermediate representation structure in the present disclosure into another form of intermediate representation structure (e.g., ONNX, PyTorch Fx, and TFlite, etc.). The converters may perform an abstraction that represents a hierarchical graph of a node and a module as a module-unit graph. The converters may lower (e.g., decrease) an abstraction level by a method of representing a module-unit graph with a hierarchical relationship composed of a node and a module. The converters may raise (e.g., increase) an abstraction level by a method of representing a hierarchical relationship composed of a node and a module as a module-unit graph. The export manager 360 may include one or more compilers that perform a lowering or a low-level transformation that transforms an intermediate representation structure in the present disclosure into a low-level representation intermediate representation structure such as XLA HLO, LLVM, etc.

An abstraction level in the present disclosure may include an abstraction level related to a model hierarchy structure and/or an abstraction level related to an execution of a model.

In an embodiment, the abstraction level related to the model hierarchy structure may represent an abstraction level within the model hierarchy structure, such as when a layer of a source artificial intelligence model is specified and represented as nodes in one more step in a process of transforming from the source artificial intelligence model or another intermediate representation structure to the intermediate representation structure in the present disclosure. For example, from the perspective of a converter, an abstraction related to the model hierarchy structure or a transformation of the abstraction level related to the model hierarchy structure may be used. As an example of the abstraction related to the model hierarchy structure, when a module corresponding to a layer of a model is converted into a structure including one or more nodes, it may be expressed that the abstraction level has been lowered or decreased.

In an embodiment, the abstraction level related to the execution of a model may represent an abstraction level used in a situation where a relatively high-level source code is compiled (e.g., transformed) into a relatively low-level form close to machine language (or in a reverse-transformed situation). For example, the higher the abstraction level (high-level), the closer it is to a conceptual representation that is easy for humans to understand, and the lower the abstraction level (low-level), the closer it may be to a concrete representation that is easy for a machine to understand and execute. For example, from the perspective of a compiler, an abstraction related to the execution of a model or a transformation of the abstraction level related to the execution of a model may be used. As an example of the abstraction related to the execution of a model, when a representation written in the form of a source code is compiled into a representation written in machine language, it may be expressed that the abstraction level has been lowered or decreased.

In an embodiment, the model optimization tools may include a trainer 320a, a compressor 320b and 375, a graph optimizer 385, a quantizer 320c and 380, and/or a simulator 390. The model optimization tools may include various types of trainers, various types of compressors, various types of graph optimizers, various types of quantizers, and/or various types of simulators. In an embodiment, a different set of model optimization tools may be used according to an execution mode of the source artificial intelligence model 200. The trainer 320a, the compressor 320c, and the quantizer 320c are model optimization tools that can be operated on an eager execution mode. The graph optimizer 385, the compressor 375, the quantizer 380, and/or the simulator 390 are model optimization tools that can be operated on a graph execution mode.

In an embodiment, an interconnection relationship between the model optimization tools may be managed as a transformation scenario.

In an embodiment, the trainer 320a may generate a training result of an artificial intelligence model.

In an embodiment, the compressors 320b and 375 can lightweight an artificial intelligence model, such as by filter decomposition and/or pruning. The compressor can measure or identify a location where a lightweighting technique is applicable and perform compression based on platform information using the measured (or identified) location. For example, an advanced compressor 320b can perform compression of a model through a compression technique that operates in an eager execution mode 315a. For example, the compressor 375 can perform compression of a model through a compression technique that operates in a graph execution mode 315b.

In an embodiment, the quantizers 320c and 380 can perform quantization of an artificial intelligence model based on a data type supported by a hardware and/or a compiler. For example, an advanced quantizer 320c can perform quantization of a model through a quantization technique that operates in an eager execution mode 315a. For example, the quantizer 380 can perform quantization of a model through a quantization technique that operates in a graph execution mode 315b.

In an embodiment, the graph optimizer 385 can remove an operator which is not required by a hardware and/or a compiler from a model, change an unsupportable operator to a supportable operator, change an unsupportable operator to a combination of supportable operators, and/or change a supportable operator to an operator for a more efficient operation.

In an embodiment, the simulator 390 can generate an expected execution result for when an artificial intelligence model is executed on a platform. The simulator 390 can generate an expected execution result of an artificial intelligence model by simulating a runtime that operates on a hardware. The simulator 390 can generate an expected execution result of an artificial intelligence model by simulating a runtime that operates on a hardware on an intermediate representation structure 370 without executing the actual model on the actual hardware.

In an embodiment, the model optimization tools 375, 380, 385, and 390 may be executed or applied on an intermediate representation structure. Accordingly, optimization and transformation of a model, and simulation of the model (or the optimized model) may be possible without directly executing the actual model on an actual platform (e.g., a hardware).

In an embodiment, the target artificial intelligence model 300 may refer to an artificial intelligence model that is an object of a framework transformation. For example, the target artificial intelligence model 300 may refer to an artificial intelligence model to which an optimization and/or a transformation has been applied. For example, a performance according to an expected simulation result of the target artificial intelligence model 300 may be performed on the intermediate representation structure 370 by the simulator 390. For example, the target artificial intelligence model 300 may be generated, as the intermediate representation structure 370 is converted by a converter or the export manager 360.

In an embodiment, the target artificial intelligence model 300 may include a static model and a dynamic model. For example, the target artificial intelligence model 300 may take the form of a static graph of a deep learning framework such as TensorFlow or Onnx. For example, the target artificial intelligence model 300 may take the form of a dynamic graph in the form of an eager execution mode of a deep learning framework such as PyTorch. As a non-limiting example, when it is determined that the target artificial intelligence model 300 is to take the form of a dynamic graph (e.g., according to a user input or a pre-determined rule), a static to dynamic transformation may also be applied when the computing device 100 generates or outputs the target artificial intelligence model 300.

FIG. 4 is a flowchart illustrating, by way of example, a method of converting a source artificial intelligence model into a target artificial intelligence model according to an embodiment of the present disclosure.

The exemplary flowchart in FIG. 4 may be performed by a computing device 100. According to an implementation aspect, some steps in the example of FIG. 4 may be deleted and/or additional steps may be added to the example of FIG. 4.

In an embodiment, the computing device 100 may receive a source artificial intelligence model executable in a first framework (410).

In an embodiment, the source artificial intelligence model represents an artificial intelligence model input to the computing device 100. The source artificial intelligence model represents an artificial intelligence model that is an object of transformation. The source artificial intelligence model may be received from a user terminal. The source artificial intelligence model may include a model file, framework information, training dataset information and/or identification information of the artificial intelligence model. The source artificial intelligence model may be an object to be transformed to a target artificial intelligence model. The source artificial intelligence model may refer to a model executable in a first framework (e.g., a source framework). The source artificial intelligence model may be an object to be transformed to a target artificial intelligence model operable in a second framework.

In an embodiment, the source artificial intelligence model may refer to a model abstracted to a first abstraction level corresponding to a relatively high level. Such a source artificial intelligence model may be composed of components in units of inference functions of the model.

In an embodiment, the computing device 100 may transform source operators included in the source artificial intelligence model into a source intermediate representation structure including source modules dependent on the first framework and nodes independent of a framework (420).

In an embodiment, the computing device 100 may transform the source artificial intelligence model into a source intermediate representation structure. For example, the computing device 100 may transform the source artificial intelligence model into an intermediate representation for converting to an artificial intelligence model operable in a different framework. For example, the computing device 100 may transform the source artificial intelligence model into an intermediate representation for executing various model optimization tools. For example, the computing device 100 may transform the source artificial intelligence model into an intermediate representation for simulating an optimization or transformation result of the source artificial intelligence model. For example, the computing device 100 may generate a source intermediate representation structure that represents an internal structure of the source artificial intelligence model as a graph structure. For example, the source intermediate representation structure may be generated by a loader manager of the computing device 100. For example, the source intermediate representation structure may be generated by a loader corresponding to the source artificial intelligence model among a plurality of loaders.

In an embodiment, an intermediate representation structure corresponding to the source artificial intelligence model is referred to as a source intermediate representation structure. The source intermediate representation structure may be composed of source modules dependent on the first framework and nodes within the source modules. Each of the nodes herein may correspond to an atomic operator independent of a framework. The expression “dependent on a framework” in the present disclosure indicates that it varies according to a specific framework. Since each of the modules within the intermediate representation structure is dependent on a framework, a form of a module and information of nodes within the module may be configured differently according to a specific framework. For example, the source intermediate representation structure may be composed of source modules suitable for a first framework on which the source artificial intelligence model is executable. The source modules may be determined based on the first framework. Each of the nodes within the source modules is independent of a framework, and an atomic operator that is no longer decomposed may correspond to a node. For example, the computing device 100 may determine source modules corresponding to each of source operators (e.g., source layers) constituting the source artificial intelligence model and may determine atomic operators within the source artificial intelligence model. The source modules may be respectively generated by combining the atomic operators to be suitable for the first framework (i.e., the source artificial intelligence model). The computing device 100 may generate a source intermediate representation structure that represents the source artificial intelligence model with a source module and a node, by transforming each of the source operators (e.g., source layers) constituting the source artificial intelligence model into the source module configured with the nodes independent of a framework. The source modules may correspond to the source operators (e.g., layers included in the source artificial intelligence model) dependent on the first framework.

In an embodiment, the source intermediate representation structure may include a node, a tensor connecting nodes, a source module that represents information dependent on the first framework and is configured with one or more nodes, and a tensor connecting source modules. The source intermediate representation structure may further include an argument representing information (or a value) necessary for a specific operator of the source artificial intelligence model to be executed. The argument may include information for an execution of a module and/or a node within the source representation structure. Additionally, a tensor in the source intermediate representation structure may also be used as the argument. For example, each of the modules and nodes of the intermediate representation structure may include an argument for an execution of each of them. Platform information and/or quantization information may be stored in a tensor within the intermediate representation structure.

In an embodiment, the source module in the source intermediate representation structure may include an input tensor, an output tensor, a source operator dependent on the first framework, nodes existing within the source module, an original module at a time of generation of the source intermediate representation structure, and original nodes at the time of generation of the source intermediate representation structure. The original module herein may refer to a module transformed from an operator or a set of operators (or a layer) of the source artificial intelligence model when generating the source intermediate representation structure. For example, the original module may be changed to an optimized or transformed form as model optimization tool(s) are executed. A node on the source intermediate representation structure may include an input tensor, an output tensor, an atomic operator corresponding to the node, and original nodes at the time of generation of the source intermediate representation structure. The original node herein may refer to a node transformed from an atomic operator of the source artificial intelligence model when generating the source intermediate representation structure. For example, the original node may be changed to an optimized or transformed form as model optimization tool(s) are executed.

In an embodiment, the computing device 100 may generate a target intermediate representation structure including target modules dependent on a second framework and the nodes independent of a framework, by using information about the second framework to which the source artificial intelligence model is to be converted (430).

In an embodiment, the computing device 100 may change source modules to target modules dependent on the second framework. The target modules may be dependently determined on the second framework on which a target artificial intelligence model is executable. Like the source module, the target module may be varied according to a framework. For an intermediate representation structure to be changed to be suitable for a first framework, module(s) on the intermediate representation structure may be changed to first target module(s) corresponding to the first framework. For an intermediate representation structure generated to be suitable for a first framework to be changed to be suitable for a second framework, source module(s) corresponding to the first framework on the intermediate representation structure may be changed to second target module(s) corresponding to the second framework. The number and type of nodes included in a target module may also be varied according to a framework. In an embodiment, since the nodes included in the source intermediate representation structure are independent of a framework, they can be maintained in the process of being transformed into a target intermediate representation structure. However, a node may be changed, as model optimization tool(s) are executed on the intermediate representation structure.

In an embodiment, the source intermediate representation structure may be generated by applying an abstraction of a second abstraction level corresponding to a relatively low level to the source artificial intelligence model. The source intermediate representation structure may be represented by a module of a first abstraction level and a node of a second abstraction level. The source intermediate representation structure can be generated by applying a low-level abstraction of the source artificial intelligence model. The source intermediate representation structure may refer to a structure to which an abstraction of the second abstraction level is applied.

In an embodiment, the target intermediate representation structure may also be represented by a module of a first abstraction level and a node of a second abstraction level, corresponding to the source intermediate representation structure. The target intermediate representation structure may refer to a structure to which an abstraction of the second abstraction level (e.g., an abstraction specified down to a node unit) is applied.

In an embodiment, the target intermediate representation structure may include a node corresponding to an atomic operator independent of a framework, and a target module that represents information dependent on the second framework and is configured with one or more nodes. The target intermediate representation structure may further include a tensor connecting the target modules and/or the nodes. The target intermediate representation structure may further include an argument representing a value used for an operator to operate. According to an implementation aspect, this argument may be included within the scope of a tensor.

In an embodiment, the computing device 100 may transform the source intermediate representation structure into a universal intermediate representation structure for a transformation to a target framework different from the source framework. For example, the universal intermediate representation structure may refer to an intermediate representation structure that serves as a reference for transformation into various forms of frameworks. For example, a source intermediate representation structure corresponding to a source framework and a target intermediate representation structure suitable for a target framework may have a structure dependent on a specific framework. For example, a source intermediate representation structure corresponding to a source framework and a target intermediate representation structure suitable for a target framework may have a module structure dependent on a framework (e.g., source module(s) and/or target module(s)). For example, the universal intermediate representation structure may refer to an intermediate representation structure that is not dependent on a framework. For example, the universal intermediate representation structure may refer to an intermediate representation structure that is independent on a framework. For example, the universal intermediate representation structure may refer to a structure in which modules on the source intermediate representation structure are removed. For example, the computing device 100 may generate the universal intermediate representation structure by changing the source intermediate representation structure into a form in which a single node is included in a single module. For example, the universal intermediate representation structure may be generated by removing framework-dependent module(s) from the generated intermediate representation structure. For example, the universal intermediate representation structure may be generated, as the intermediate representation structure is changed so that a module and a node have a one-to-one inclusion relationship. In an embodiment, the computing device 100 may generate the universal intermediate representation structure by removing the source modules dependent on the first framework and maintaining the nodes independent of a framework, on the source intermediate representation structure. In an embodiment, the computing device 100 may generate the universal intermediate representation structure by modifying the source intermediate representation structure such that a single node is included in a single source module on the source intermediate representation structure. For example, the universal intermediate representation structure may be composed of nodes of a second abstraction level corresponding to a relatively low level. For example, as components of a first abstraction level are removed from the source intermediate representation structure, a universal intermediate representation structure composed of components of a second abstraction level may be generated. For example, the universal intermediate representation structure may be generated as a high-level abstraction removal is applied to the source intermediate representation structure.

In an embodiment, in order to perform a transformation between frameworks of an artificial intelligence model, a source intermediate representation structure to be transformed may be transformed into a universal intermediate representation structure, and a target intermediate representation structure, which is a result of the transformation, may be generated by using the universal intermediate representation structure. Since the technique according to an embodiment of the present disclosure uses an intermediate representation structure that can be universally applied to frameworks for transformation between frameworks, a technical effect can be achieved in that a transformation between various frameworks can be achieved resource-efficiently on the intermediate representation.

In an embodiment, the computing device 100 may transform the universal intermediate representation structure into a target intermediate representation structure including target modules dependent on the second framework and the nodes independent of a framework, by using information about the second framework to which the source artificial intelligence model is to be converted. In an embodiment, the universal intermediate representation structure used in the process of transforming to the target intermediate representation structure may refer to an intermediate representation independent of a framework. The universal intermediate representation structure may include a combination of nodes corresponding to a minimum unit of atomic operators universally applicable to a plurality of frameworks. The universal intermediate representation structure may refer to an intermediate representation composed only of nodes as modules are removed. The universal intermediate representation structure may have a form in which a module includes node(s) so as not to be dependent on a framework.

In an embodiment, the computing device 100 may transform the universal intermediate representation structure into a target intermediate representation structure including target modules dependent on the second framework and the nodes independent of a framework. For example, the computing device 100 may group the nodes included in the universal (or source) intermediate representation structure by using the information about the second framework to which the source artificial intelligence model is to be converted as a grouping condition. For example, the nodes on the universal (or source) intermediate representation structure may be grouped by using a table in which information about the second framework and information about a combination of nodes are mapped. As the nodes are grouped, target modules may be generated. For example, a single target module may include one or more nodes. According to a result of this grouping, target modules dependent on the second framework may be generated. The target modules may correspond to target operators within an artificial intelligence model corresponding to the second framework.

In an additional embodiment, the computing device 100 may also use a method of directly transforming the source intermediate representation structure into the target intermediate representation structure without utilizing the universal intermediate representation structure. For example, by using a target framework, the target intermediate representation structure may be generated as source module(s) on the source intermediate representation structure are changed to target module(s). For example, the target intermediate representation structure may be generated, as source module(s) are changed to target module(s) by using a target framework and a mapping table that defines a correlation between a module and an operator (or a layer).

In an embodiment, a mapping table may be utilized in the process of generating a source intermediate representation structure, generating an intermediate representation structure, and/or generating a target intermediate representation structure. A technique according to an embodiment of the present disclosure can generate, construct, change, manage, and/or utilize a mapping table for a mutual transformation between various deep learning frameworks of an artificial intelligence model and intermediate representation structures defined in the present disclosure. The mapping table can define a mapping relationship between an operator for each framework and an atomic operator (e.g., a node) of the intermediate representation structure of the present disclosure. For example, this mapping table may be included or stored in the intermediate representation manager 230. For example, the mapping table may be utilized in the process of generating and transforming an intermediate representation structure by components such as a loader manager and/or an export manager.

In an embodiment, the target module in the target intermediate representation structure may include: an input tensor, an output tensor, a target operator dependent on the second framework, nodes existing within the target module, an original module at a time of generation of the target intermediate representation structure, and original nodes at the time of generation of the source intermediate representation structure. A node in the target intermediate representation structure may include an input tensor, an output tensor, an atomic operator corresponding to the node, and original nodes at the time of generation of the source intermediate representation structure.

In an embodiment, the computing device 100 may define a correlation between operators and nodes (or modules) within the intermediate representation structure by using a mapping table. This mapping table may be used interchangeably with a lookup table according to an implementation aspect.

For example, the computing device 100 may use a lookup table when generating a source intermediate representation structure from a source artificial intelligence model. For example, the computing device 100 may transform source operators into a combination of nodes within the source intermediate representation structure. For example, the computing device 100 may transform the source operators included in the source artificial intelligence model into a combination of the nodes, by using a lookup table that represents a transformation relationship between the source operators of the first framework and the nodes. For example, a source intermediate representation structure may be generated by combining nodes that are in a mapping relationship with each of the source operators of the first framework. For example, as a first lookup table corresponding to the first framework is used, a source intermediate representation structure including nodes determined based on information stored in the first lookup table may be generated.

In an embodiment, the computing device 100 may, when generating the source intermediate representation structure, use a lookup table including a transformation relationship between the source operators of the first framework and nodes and an argument used for an operator to operate in the first framework. For example, the computing device 100 may transform each of the source operators included in the source artificial intelligence model into a source module which is a combination of nodes, and transform an argument of the source operators into an argument of a node included in the source module, by using a lookup table including the transformation relationship and the argument.

In an embodiment, the lookup table may be used to identify a combination of nodes that matches an operator of a specific framework. In an embodiment, the lookup table may be configured to match a combination of a framework and an operator with a node. In an embodiment, the lookup table may be configured to match a combination of a framework and an operator with a combination of nodes. For example, the computing device 100 may identify a combination of nodes that matches a combination of the source operator of the source artificial intelligence model and the first framework, by using a lookup table that identifies a combination of nodes that matches a combination of a type of framework and a type of operator. The computing device 100 may transform each of the source operators constituting the source artificial intelligence model into a source module, by configuring a single module with the identified combination of nodes. A specific example of the transformation into a source module will be described later in the following drawings.

In an embodiment, the computing device 100 may use a lookup table when generating a target intermediate representation structure. The lookup table may represent a transformation relationship between target operators of the second framework and nodes corresponding to an atomic operator. The computing device 100 may determine a recombination scheme of the nodes for compatibility of the second framework by using the lookup table. In an additional embodiment, the computing device 100 may select a lookup table related to the second framework among a plurality of types of lookup tables and may determine a recombination scheme of the nodes for compatibility of the second framework by using the selected lookup table. In an embodiment, the computing device 100 may generate target modules dependent on the second framework by grouping the nodes by using the determined recombination scheme. The recombination of nodes in the present disclosure may refer to rearranging nodes within the source (or universal) intermediate representation structure to correspond to the target intermediate representation structure. The recombination of nodes in the present disclosure may refer to adaptively rearranging nodes within the source (or universal) intermediate representation structure according to the target intermediate representation structure. The recombination of nodes in the present disclosure may refer to adjusting an arrangement position, a precedence relationship, and/or an arrangement relationship of nodes within the intermediate representation structure.

In an embodiment, the lookup table may have a data structure including a key and a value. In an embodiment, the computing device 100 may, when transforming source operators of a source artificial intelligence model into a source intermediate representation structure, use a lookup table that uses an operator for each framework as a key and a node corresponding to an atomic operator as a value. The source operators included in the source artificial intelligence model can be transformed into a combination of nodes by using the lookup table. In an additional embodiment, the computing device 100 may, when generating a target intermediate representation structure from a source intermediate representation structure or a universal intermediate representation structure, use a lookup table that uses an operator for each framework as a key and a node corresponding to an atomic operator as a value. A combination of nodes of the source intermediate representation structure or the universal intermediate representation structure can be transformed into a combination of nodes of the target intermediate representation structure by using the lookup table.

In an embodiment, the computing device 100 may generate a mapping table (or a lookup table) by mapping each of model operators and each of modules within an intermediate representation structure. For example, the computing device 100 may generate the mapping table by using an execution-based analysis method based on an execution of a test artificial intelligence model and/or an embedding-based analysis method based on an embedding transformation between a model operator and an atomic operator independent of a framework. For example, the computing device 100 may determine a module corresponding to a model operator by using the execution-based analysis method and/or the embedding-based analysis method and may generate the mapping table by mapping the determined module and the model operator. For example, the mapping table may include version information of a framework, identification information of a model operator in the mapping table, input/output information of the model operator, identification information of one or more nodes included in a module mapped to the model operator, input/output information of the one or more nodes, and/or an execution order of each node. For example, the mapping table can define a mapping relationship between an operator (or a layer) of an artificial intelligence model and a node or a set of nodes of an intermediate representation structure. The computing device 100 may transform a source artificial intelligence model into a source intermediate representation structure by using the mapping table. The computing device 100 may transform a target intermediate representation structure into a target artificial intelligence model by using the mapping table.

In an embodiment, the computing device 100 may generate a reverse mapping table that defines a mapping relationship between an atomic operator and a model operator, by using a mapping relationship in a forward mapping table that defines a mapping relationship between a model operator and an atomic operator. For example, the forward mapping table may be used to generate a source intermediate representation structure from a source artificial intelligence model. For example, the reverse mapping table may be used to generate a target artificial intelligence model from a target intermediate representation structure.

In an embodiment, the computing device 100 may determine a module corresponding to a model operator based on a type of a framework. In an embodiment, the computing device 100 may determine a module corresponding to a model operator in a different manner according to a type of a framework. In an embodiment, the computing device 100 may dependently vary a method of determining a module corresponding to a model operator on a type of a framework.

In an embodiment, when a type of a framework is a framework that supports a function of transforming to an intermediate representation structure (e.g., a Torch-based framework), the computing device 100 may determine a module corresponding to a model operator based on a first execution-based analysis method that traces atomic operators called in an execution process of a test artificial intelligence model. For example, the computing device 100 may generate a first test artificial intelligence model including model operators and may transform the model operators included in the first test artificial intelligence model into a first intermediate representation structure represented in units of atomic operators by executing the first test artificial intelligence model. Then, the computing device 100 may identify a combination and an execution order of atomic operators (e.g., nodes) corresponding to each of the model operators within the first intermediate representation structure, based on the model operator information. The computing device 100 may determine the module corresponding to each of the model operators, based on the identified combination and execution order of the atomic operators. In this manner, a mapping table where a module corresponding to a model operator is mapped can be generated. For example, a combination of atomic operators (e.g., nodes) corresponding to a model operator may be determined as a module.

In an embodiment, when a type of a framework is a framework that does not support a function of transforming to an intermediate representation structure (e.g., a Non-Torch-based framework), the computing device 100 may determine a module corresponding to a model operator based on a second execution-based analysis method that compares execution results of a test artificial intelligence model or an embedding-based analysis method. For example, the second execution-based analysis method may include determining a module mapped to model operator(s) of a specific artificial intelligence model, by comparing an execution result of the specific artificial intelligence model (e.g., a second test artificial intelligence model) for a specific input data and an execution result of candidate modules for the specific input data.

In an embodiment, when a type of a framework is a framework that does not support a function of transforming to an intermediate representation structure, the computing device 100 may perform determining a module corresponding to a model operator after generating a mapping table based on a first execution-based analysis method that traces atomic operators called in an execution process of a test artificial intelligence model. For example, when a type of a framework is a framework that does not support a function of transforming to an intermediate representation structure, the computing device 100 may generate a candidate mapping table corresponding to the framework, based on a second execution-based analysis method using a threshold error or an embedding-based analysis method using a threshold embedding similarity. The candidate mapping table may correspond to a table in which one or more candidate modules are mapped to one target model operator. The candidate mapping table may be generated by using pre-determined modules for a framework of a type that supports a function of transforming to an intermediate representation structure. The computing device 100 may determine a module corresponding to each of model operators, by comparing an execution result of each of the model operators and an execution result of each of one or more candidate modules mapped in the candidate mapping table.

In an embodiment, the second execution-based analysis method may be implemented by the following operations. For example, the computing device 100 may generate a second test artificial intelligence model including model operators that are objects of mapping. The computing device 100 may determine a module corresponding to each of the model operators included in the second test artificial intelligence model, based on an execution result of the second test artificial intelligence model for a first input data and an execution result of a plurality of pre-stored candidate modules for the first input data. A mapping relationship between the model operators and the determined module may be set. For example, the plurality of pre-stored candidate modules may correspond to pre-determined modules based on the first execution-based analysis method.

In an embodiment, when the second test artificial intelligence model is composed of a single first model operator, the computing device 100 may, when determining a module corresponding to the first model operator included in the second test artificial intelligence model, calculate an error between an execution result of the first model operator for a first input data and an execution result of the plurality of pre-stored candidate modules for the first input data and may determine a module corresponding to the first model operator by using the calculated error. For example, the computing device 100 may identify one or more candidate modules in which the error is less than or equal to a threshold error from among the plurality of pre-stored candidate modules, and may determine a module corresponding to the first model operator from among the identified one or more candidate modules by comparing an execution result of the first model operator for a second input data and an execution result of the identified one or more candidate modules for the second input data.

In an embodiment, when the second test artificial intelligence model is composed of a plurality of model operators, the computing device 100 may calculate an error between an execution result of the second test artificial intelligence model for the first input data and an execution result of candidate module combinations composed of the plurality of pre-stored candidate modules for the first input data, and may determine a module corresponding to each of the model operators by using the calculated error. For example, the computing device 100 may identify one or more candidate module combinations in which the error is less than or equal to a threshold error from among the candidate module combinations, and may determine a module corresponding to each of the model operators within the identified one or more candidate module combinations by comparing an execution result of each of the model operators included in the second test artificial intelligence model for a third input data and an execution result of each of the candidate modules included in the identified one or more candidate module combinations for the third input data.

In an embodiment, the computing device 100 may, in setting a mapping relationship between a model operator and a module in an artificial intelligence model, compare an intermediate execution result for each model operator for an input data (e.g., an intermediate input/output value) and an execution result of each of candidate modules for the input data. Based on this comparison, a candidate module with an error less than or equal to a threshold error may be identified. A mapping relationship between the identified candidate module and the model operator may be set.

In an embodiment, the computing device 100 may use an embedding analysis method when determining a module corresponding to a model operator. This embedding analysis method may be implemented by generating a model operator embedding vector corresponding to a model operator and generating an atomic operator embedding vector corresponding to an atomic operator. A module corresponding to a model operator can be determined as a vector similarity between the model operator embedding vector and the atomic operator embedding vector is calculated. For example, based on the vector similarity, a combination of atomic operators (e.g., nodes) corresponding to a model operator is determined, and the combination of atomic operators may be set to constitute a module. For example, the model operator embedding vector may be generated by performing a filtering process of deleting a token corresponding to a pre-defined stopword or selecting a token corresponding to a pre-defined keyword, on a plurality of model operator tokens in which model operator information corresponding to each of the model operators is tokenized. The model operator information may include identification information, description information, input/output information, and an implementation code of each of the model operators. The description information may represent information in which a description of each of the model operators is described in a natural language text. The input/output information may include a data type, a shape, and order information of an input value and an output value of each of the model operators. For example, the atomic operator embedding vector may be generated by performing a filtering process of deleting a token corresponding to a pre-defined stopword or selecting a token corresponding to a pre-defined keyword, on a plurality of atomic operator tokens in which information about atomic operators is tokenized.

In an embodiment, the computing device 100 may generate a target artificial intelligence model in which the source operators of the source artificial intelligence model are converted to target operators, by transforming the target modules of the target intermediate representation structure into the target operators executable in the second framework (440).

In an embodiment, the target artificial intelligence model may refer to a result of a transformation (or converting) of the source artificial intelligence model. In an embodiment, the target artificial intelligence model may be generated as a result of converting a target intermediate representation structure. In an embodiment, the target artificial intelligence model may be converted in a manner that modules of the target intermediate representation structure are transformed into target operators. In an embodiment, the target artificial intelligence model may refer to an artificial intelligence model executable on the second framework. In an embodiment, a mapping table (e.g., a lookup table) representing a correlation between target operators and nodes may be used in the process of converting into the target artificial intelligence model. As the mapping table is used, target modules on the target intermediate representation structure can be transformed into target operators. As this mapping table is used, a node or a combination of nodes on the target intermediate representation structure can be transformed into target operators. The target artificial intelligence model converted from the target intermediate representation structure may be provided to a user terminal. As the target artificial intelligence model is executed, an inference of the artificial intelligence model whose framework has been transformed from the first framework to the second framework may be performed.

In an embodiment, the computing device 100 may determine a converter corresponding to a target artificial intelligence model from among a plurality of converters and may convert an intermediate representation structure into the target artificial intelligence model including target operators by using the determined converter. In an embodiment, the computing device 100 may determine a converter corresponding to the second framework from among a plurality of converters and may convert an intermediate representation structure into the target artificial intelligence model including target operators by using the determined converter.

In an embodiment, the computing device 100 may convert a target intermediate representation structure into a target artificial intelligence model including target operators by using a lookup table including various information. For example, the computing device 100 may perform a converting between a combination of nodes and a target operator by using a mapping relationship stored in a lookup table. For example, the computing device 100 may convert an argument stored in a lookup table into an argument of a target operator. For example, the computing device 100 may generate a target artificial intelligence model by using information stored in a tensor of a lookup table.

In an embodiment, the computing device 100 may convert a target intermediate representation structure into a target artificial intelligence model by using a lookup table that defines a mapping relationship between the second framework and a combination of nodes. In an embodiment, the computing device 100 may generate a target artificial intelligence model corresponding to the second framework by transforming arguments within an intermediate representation structure into arguments of target operators by using a lookup table. In an embodiment, the computing device 100 may transform arguments of nodes included in target modules into arguments of target operators of the second framework, by using a lookup table representing a transformation relationship between the second framework and nodes and an argument used for an operator to operate in the second framework. By this transformation, a target artificial intelligence model compatible with the second framework can be generated.

In an embodiment, the computing device 100 may convert a target intermediate representation structure into a target artificial intelligence model by using information included in a tensor within the target intermediate representation structure. In an embodiment, the computing device 100 may generate a quantization operator and a dequantization operator corresponding to the second framework, by using quantization information of a tensor included in the target intermediate representation structure. The quantization operator and the dequantization operator may be added to the target operators when transforming the target modules of the target intermediate representation structure into the target operators executable in the second framework. The quantization operator and the dequantization operator may be respectively arranged before and after the target operator, or the dequantization operator and the quantization operator may be respectively arranged before and after the target operator.

In an embodiment, the computing device 100 may identify an execution mode of a source artificial intelligence model and may vary a method of transforming to a source intermediate representation structure according to the identified execution mode. For example, when a received source artificial intelligence model is identified as a first mode in which the model is executed after representing operations as a graph, the computing device 100 may transform the received source artificial intelligence model into a source intermediate representation structure. For example, when a received source artificial intelligence model is identified as a second mode in which the model is executed in an operation unit without representing operations as a graph, a model optimization tool may be applied on the source artificial intelligence model and a transformation from the source artificial intelligence model to which the model optimization tool is applied to a source intermediate representation structure may be performed.

In an embodiment, after model optimization tools are applied to or executed on a target intermediate representation structure, a converting operation into a target artificial intelligence model may be performed. For example, the computing device 100 may change target modules included in a target intermediate representation structure by using a model optimization tool comprising at least one of a compressor, a graph optimizer, and a quantizer. For example, the computing device 100 may change a configuration of the target modules included in the target intermediate representation structure by using a model optimization tool comprising at least one of a compressor, a graph optimizer, and a quantizer. Then, the computing device 100 may generate the target artificial intelligence model executable in the second framework, by converting the target modules with the changed configuration in the target intermediate representation structure into the target operators executable in the second framework.

In an embodiment, the computing device 100 may use platform information in the process of converting to a target artificial intelligence model. For example, the computing device 100 may use or consider hardware information and/or compiler information in the process of converting into a target artificial intelligence model. A method of converting and/or a result of converting may be varied according to platform information.

In an embodiment, when information of a target hardware on which a target artificial intelligence model is to be deployed is received, the information of the target hardware may be stored in a target module and a tensor in a target intermediate representation structure. The computing device 100 may perform a converting into the target artificial intelligence model by a method of selecting an operator supportable on the target hardware by using the information of the target hardware. The computing device 100 may perform a converting into the target artificial intelligence model by a method of removing an operator unsupportable on the target hardware by using the information of the target hardware. For example, the computing device 100 can generate the target artificial intelligence model by removing a target module or a node corresponding to an operator unsupportable on the target hardware from the target intermediate representation structure, by using the information of the target hardware. For example, the information of the target hardware may be determined on the target intermediate representation structure or may be received from a user terminal.

In an embodiment, the computing device 100 may perform a converting to a target artificial intelligence model by using or considering information of a target hardware and a target compiler together. In an embodiment, when information of a target hardware and a target compiler on which a target artificial intelligence model is to be deployed is received, a node supportable on the target hardware and the target compiler and a module including the supportable node may be added to the target intermediate representation structure. In an embodiment, when information of a target hardware and a target compiler on which a target artificial intelligence model is to be deployed is received, a target operator supportable on the target hardware and the target compiler may be generated in the process of converting into the target artificial intelligence model. In an embodiment, when information of a target hardware and a target compiler on which a target artificial intelligence model is to be deployed is received, an unsupportable node on the target hardware and the target compiler and a module including the unsupportable node may be deleted from the target intermediate representation structure. In an embodiment, when information of a target hardware and/or a target compiler on which a target artificial intelligence model is to be deployed is received, an unsupportable node on the target hardware and/or the target compiler and a module including the unsupportable node on the target intermediate representation structure may be changed to a node and a module supportable on the target hardware and/or the target compiler. In an embodiment, when information of a target hardware and/or a target compiler on which a target artificial intelligence model is to be deployed is received, a converting into the target artificial intelligence model may be performed in a manner that an unsupportable node on the target hardware and/or the target compiler and a module including the unsupportable node on the target intermediate representation structure are changed to a target operator supportable on the target hardware and/or the target compiler.

In an embodiment, the computing device 100 may perform an optimization operation or a performance transformation operation on a target intermediate representation structure by using platform information. For example, the computing device 100 may determine a graph optimization method for a target intermediate representation structure according to platform information. There can be a correlation between platform information and a graph optimization method. For example, when the computing device 100 receives platform information (e.g., information of a target hardware) on which a target artificial intelligence model is to be deployed, it may delete a node or a module on the target intermediate representation structure by using the platform information. For example, when the computing device 100 receives platform information (e.g., information of a target hardware) on which a target artificial intelligence model is to be deployed, it may delete at least one node among nodes included in the target intermediate representation structure by using the platform information. For example, when the computing device 100 receives platform information (e.g., information of a target hardware) on which a target artificial intelligence model is to be deployed, it may move at least one node among the nodes included in the target intermediate representation structure from a first target module to a second target module on the target intermediate representation structure by using the platform information.

In an embodiment, the computing device 100 may generate a target artificial intelligence model by abstracting a target intermediate representation structure to a high level. The target artificial intelligence model can be generated through a method of raising an abstraction level of the target intermediate representation structure represented at a second abstraction level. For example, the target artificial intelligence model may be generated as components corresponding to the second abstraction level are removed from the target intermediate representation structure. For example, the target artificial intelligence model may be represented at a first abstraction level. For example, the target artificial intelligence model may be generated by a high-level abstraction of the target intermediate representation structure, and the target artificial intelligence model may be represented at the first abstraction level by this abstraction.

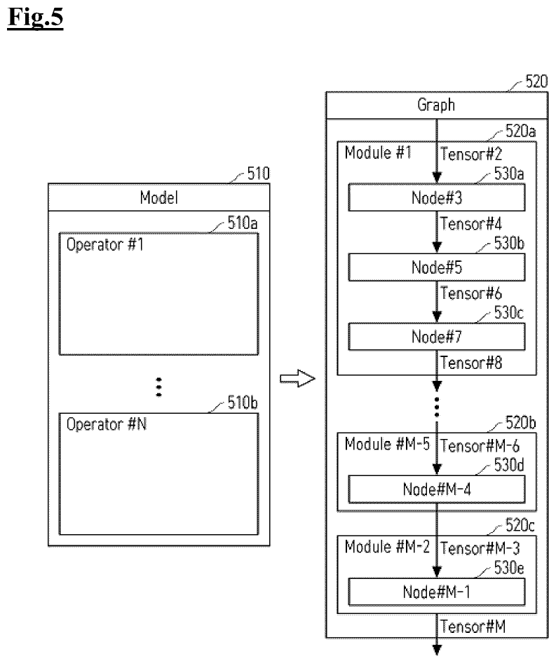

FIG. 5 illustrates, by way of example, an intermediate representation structure according to an embodiment of the present disclosure.

In an embodiment, the artificial intelligence model 510 may include operators 510a and 510b. The operators 510a and 510b may refer to a unit that performs a specific function within the artificial intelligence model. The operators 510a and 510b of the artificial intelligence model 510 may be used interchangeably with layers.

In an embodiment, the artificial intelligence model 510 may correspond to a source artificial intelligence model on which a converting into a target artificial intelligence model is to be performed by using the intermediate representation structure 520. In an embodiment, the artificial intelligence model 510 may correspond to an artificial intelligence model on which model optimization tools are to be executed or applied on the intermediate representation structure 520. In an embodiment, the artificial intelligence model 510 may correspond to an artificial intelligence model on which a simulation is to be performed on the intermediate representation structure 520.

In an embodiment, the intermediate representation structure 520 may include a source intermediate representation structure corresponding to a source artificial intelligence model, a target intermediate representation structure corresponding to a target artificial intelligence model, and/or a universal intermediate representation structure.

In an embodiment, the intermediate representation structure 520 may have a graph structure as illustrated in FIG. 5. Nodes 530a, 530b, 530c, 530d, and 530e and an edge connecting the nodes 530a, 530b, 530c, 530d, and 530e, and modules 520a, 520b, and 520c and an edge connecting the modules 520a, 520b, and 520c may form a graph structure. The intermediate representation structure 520 may include nodes 530a, 530b, 530c, 530d, and 530e corresponding to an atomic operator. A module 520a, 520b, and 520c may be configured, as one or more nodes are combined. The intermediate representation structure 520 may include a tensor (Tensor #2, Tensor #4, Tensor #6, Tensor #8, Tensor #M-6, Tensor #M-3, and Tensor #M). For example, a tensor may represent a connection between nodes and/or a connection between modules, and may represent an input/output of nodes and an input/output of modules.

In an embodiment, a first operator 510a in the artificial intelligence model 510 may be transformed into a first module 520a on the intermediate representation structure 520. In this transformation process, a set of nodes 530a, 530b, and 530c corresponding to the first operator 510a may be determined. This set of nodes 530a, 530b, and 530c may be determined by using, for example, a mapping table (or a lookup table). One or more atomic operators representing the first operator 510a are determined, and these atomic operators may be represented as a set of nodes 530a, 530b, and 530c. When the first module 520a is configured, tensors (Tensor #2, Tensor #4, Tensor #6, Tensor #8) related to the first module 520a may be included. By using the same method, a second operator 510b in the artificial intelligence model 510 may be transformed into another module (e.g., Module #M-2 (520c)) on the intermediate representation structure 520.

In an embodiment, a node in the intermediate representation structure 520 may include: identification information (ID and/or name) of the node, information for identifying an input tensor of the node, information for identifying an output tensor of the node, identification information of an atomic operator independent of a framework, information necessary for implementing the atomic operator (e.g., an argument), information regarding a tensor, information regarding an argument, and/or node information at the time of initial generation of the source intermediate representation structure.

In an embodiment, a module in the intermediate representation structure 520 may include: identification information (ID and/or name) of the module, information about nodes existing within the module, information about an executable operator dependent on a framework, information necessary for executing the operator, information regarding a tensor, information regarding an argument, an input tensor of the module, an output tensor of the module, information about an original module, and information about an original node in the module. For example, when the intermediate representation structure 520 is a source intermediate representation structure, the original module may include module information at the time of initial generation of the source intermediate representation structure. For example, when the intermediate representation structure 520 is a target intermediate representation structure, the original module may include module information at the time of initial generation of the target intermediate representation structure. For example, the information about an original node may include node information at the time of initial generation of the source intermediate representation structure. This information about an original node is not changed even after the source representation structure is transformed into a target intermediate representation structure.

In an embodiment, a tensor in the intermediate representation structure 520 may include: identification information (ID and/or name) of the tensor, identification information of a node that outputs the tensor, identification information of a node in which the tensor is used as an input, a value of the tensor (e.g., a pre-defined value such as a weight), information indicating whether a parameter is in a trainable form, external storage location information, shape information of the tensor, size information of the tensor, information about whether quantization has proceeded, and/or information about a quantization-related parameter. For example, an activation value may be defined as None in the value of the tensor.

Although there are various deep learning frameworks that support the efficient development, training, and/or deployment of an artificial intelligence model, each of these frameworks has its own advantages and disadvantages according to its purpose. A specific framework has a relatively very low entry barrier in the development of an artificial intelligence model and is loved by many researchers, but it has a disadvantage from an optimization perspective, so its performance and efficiency for execution on various devices may be poor. In order to compensate for the advantages and disadvantages of each of these frameworks or to use a runtime optimized for a specific device, a transformation between deep learning frameworks is an essential situation. For example, in the case of ONNX, it supports a fixed graph, and a transformation to another framework is not free. Through the novel intermediate representation structure according to an embodiment of the present disclosure, a technical effect can be derived that a converting that efficiently uses computing resources between various frameworks can be achieved. By using the intermediate representation structure 520 of the present disclosure, a user can efficiently derive an artificial intelligence model optimized for various frameworks and platforms for the same model.

According to an embodiment of the present disclosure, when generating a graph structure (intermediate representation structure 520) for an artificial intelligence model, for a framework that allows a dynamic control flow, a technical effect can be derived that it is possible to respond to the dynamic control flow and an eager execution mode by generating a proxy for input data. In addition, according to an embodiment of the present disclosure, a technical effect can be achieved that an interoperability becomes possible even for an artificial intelligence model in a framework that does not allow a dynamic control flow, by fragmenting the model.

Through the intermediate representation structure 520 in the present disclosure, a technical effect can be achieved that both a static model and a dynamic model can be received as an input. Through the intermediate representation structure 520 in the present disclosure, a technical effect can be achieved that optimized models that have passed through model optimization tools can also be received as an input. Since quantization-related information can be stored in a tensor-form data structure including an activation and/or a weight within the intermediate representation structure 520, a technical effect can be achieved that quantization information of a model can be stored regardless of a framework.

The intermediate representation structure 520 according to an embodiment of the present disclosure can allow artificial intelligence models of various frameworks that are optimized to be framework-dependent to be efficiently transformed into an artificial intelligence model of a specific framework. Since the intermediate representation structure 520 according to an embodiment of the present disclosure is configured to include a minimum unit of an operator called a node that is independent of a framework, it can maintain a compatibility for various frameworks regardless of operators (layers) that are defined differently between frameworks. Since the nodes in the intermediate representation structure 520 are grouped in a module unit to correspond to a model operator of various frameworks, an efficient transformation to an operator (layer) of a specific framework can be allowed. Through this, a converting and/or a compiling from a graph-type intermediate representation structure 520 composed of nodes to a specific framework can be performed regardless of an input or an output framework. In an embodiment, the computing device 100 may obtain an artificial intelligence model 510 (e.g., a source artificial intelligence model) on which a first level of abstraction has been performed. In an embodiment, the computing device 100 may abstract the artificial intelligence model 510 to a first level. Through the first level of abstraction, the artificial intelligence model 510 may be configured to include components 510a and 510b in units of inference functions. For example, the artificial intelligence model 510 may be represented by one or more modules 510a and 510b through a first level (e.g., a high level) of abstraction.

In an embodiment, the computing device 100 may abstract the artificial intelligence model 510 of the first abstraction level to a second abstraction level. For example, the computing device 100 may generate an intermediate representation structure 520 (e.g., a source intermediate representation structure) by configuring the artificial intelligence model 510 of the first abstraction level through a lower abstraction unit. The computing device 100 may generate the intermediate representation structure 520 by abstracting the artificial intelligence model by using a lower-level abstraction unit. The computing device 100 may generate the intermediate representation structure 520 by abstracting the artificial intelligence model 510 to a second abstraction level. The intermediate representation structure 520 may be generated to include modules 520a, 520b, and 520c corresponding to the first abstraction level and nodes 530a, 530b, 530c, 530d, and 530e corresponding to the second abstraction level. The computing device 100 may generate the intermediate representation structure 520 from the artificial intelligence model 510 by a method of lowering an abstraction level. The computing device 100 may generate the intermediate representation structure 520 through a hierarchical abstraction of a first abstraction level and a second abstraction level.

In an embodiment, the computing device 100 may generate an intermediate representation structure (e.g., a universal intermediate representation structure) composed of nodes of a second abstraction level by performing an abstraction in a manner of removing modules from the intermediate representation structure 520. The computing device 100 may generate an intermediate representation structure composed only of a second abstraction level, from an intermediate representation structure in which both a first abstraction level and a second abstraction level are reflected.

In an embodiment, the computing device 100 may, when generating a target artificial intelligence model, generate the target artificial intelligence model from the intermediate representation structure 520 by a method of raising (or increasing) an abstraction level. For example, an intermediate representation structure 520 to which an abstraction of a first abstraction level and a second abstraction level is applied may be transformed into a target artificial intelligence model abstracted only with the first abstraction level. For example, according to an implementation aspect, an intermediate representation structure 520 to which an abstraction of a first abstraction level is applied may be transformed into a target artificial intelligence model to which an abstraction of the first abstraction level and the second abstraction level are applied together. A technique according to an embodiment of the present disclosure may perform a transformation or an optimization of an artificial intelligence model by constructing a transformation flow to a first-level source artificial intelligence model, a second-level source intermediate representation structure, a second-level target intermediate representation structure, and a first-level target artificial intelligence model. In an embodiment, a bidirectional abstraction level transformation between a high level and a low level may be performed in the process of optimizing or transforming an artificial intelligence model.

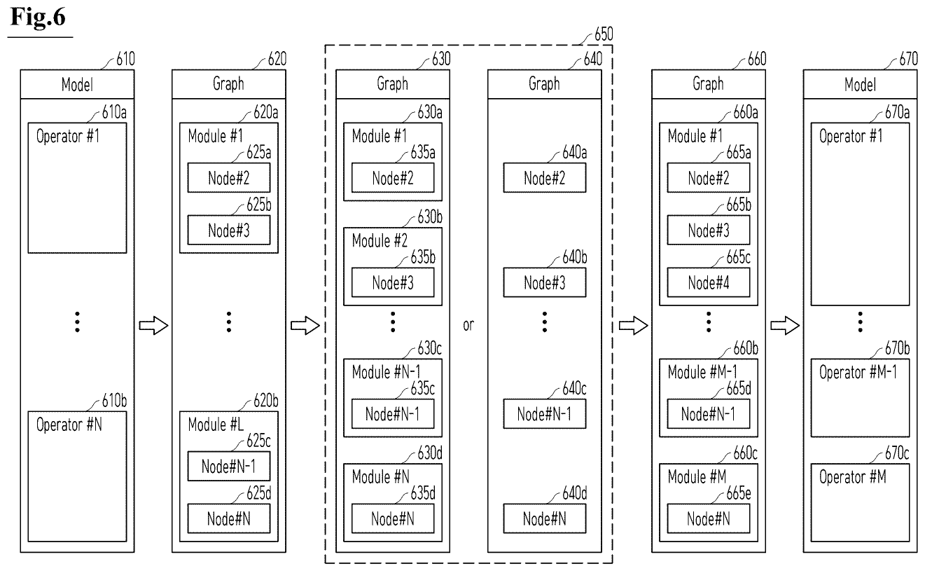

FIG. 6 illustratively shows a method in which a source artificial intelligence model 610 is converted into a target artificial intelligence model 670 by using an intermediate representation structure 620, 650, 660 according to an embodiment of the present disclosure.

In an embodiment, the computing device 100 may receive a source artificial intelligence model 610 that is an object of converting. The source artificial intelligence model 610 may include a plurality of operators (or layers) 610a and 610b. The computing device 100 may receive a source artificial intelligence model 610 that is an object of optimization from a user terminal. The computing device 100 may receive a source artificial intelligence model 610 that is an object of converting from a user terminal. For example, as the source artificial intelligence model 610 is parsed by the computing device 100, the operators 610a and 610b of the source artificial intelligence model 610 may be identified. As another example, the operators 610a and 610b of the source artificial intelligence model 610 may be identified by using a database or a lookup table that manages identification information of the source artificial intelligence model 610 and identification information of operators included in the corresponding model.

In an embodiment, as the operators 610a and 610b in the source artificial intelligence model 610 are transformed into modules 620a and 620b including nodes, a source intermediate representation structure 620 corresponding to the source artificial intelligence model 610 may be generated. The source intermediate representation structure 620 may represent a result of transforming source operators 610a and 610b in the source artificial intelligence model 610 into modules 620a and 620b including nodes 625a, 625b, 625c, and 625d. As described above, each of the nodes 625a, 625b, 625c, and 625d may correspond to a minimum unit of an atomic operator that is no longer decomposed. In the example of FIG. 6, the source intermediate representation structure 620 may include a first module 620a representing a first operator 610a of the source artificial intelligence model 610 and a second module 620b representing a second operator 610b. The nodes 625a and 625b in the source intermediate representation structure 620 represent a set of atomic operators representing the first operator 610a of the source artificial intelligence model 610 and may be determined independently of a framework (i.e., a framework of the source artificial intelligence model 610). The first module 620a in the source intermediate representation structure 620 may represent the first operator 610a of the source artificial intelligence model 610. The first module 620a in the source intermediate representation structure 620 may be configured to be dependent on the framework of the source artificial intelligence model 610. In order to preserve a connection relationship of the source artificial intelligence model 610, source modules 620a and 620b corresponding to each of the source operators 610a and 610b may be generated in the source intermediate representation structure 620. In addition, nodes 625a, 625b, 625c, and 625d that are not dependent on a framework may be generated for the operators (or layers 610a and 610b) of the source artificial intelligence model 610. The computing device 100 may generate the source intermediate representation structure 620 by configuring framework-dependent information for the source artificial intelligence model 610 as modules 620a and 620b and configuring atomic operators corresponding to each of the source operators 610a and 610b of the source artificial intelligence model 610 in a mapping table as nodes 625a, 625b, 625c, and 625d. As described above, a mapping table that defines which nodes a layer or an operator of a specific framework can be transformed into may be used to generate the source intermediate representation structure 620. In addition, since additional information related to a node may also be changed according to the type of a layer or an operator, information about these arguments may also be stored in the mapping table.

In an embodiment, the computing device 100 may transform the source intermediate representation structure 620 into a universal intermediate representation structure 650 (630 and/or 640). For example, the universal intermediate representation structure 650 may play a role of an intermediate step for transforming the source intermediate representation structure 620 into a target intermediate representation structure 660. For example, the universal intermediate representation structure 650 may be generated by a method of removing framework-dependent information from the source intermediate representation structure 620. For example, the universal intermediate representation structure 650 may be generated by a transformation method of removing framework-dependent information and maintaining framework-independent information on the source intermediate representation structure 620. For example, the universal intermediate representation structure 650 (630 and/or 640) may also have a graph structure. For example, the universal intermediate representation structure 650 (630 and/or 640) may refer to an intermediate representation structure in which the source intermediate representation structure 620 is transformed into a graph structure for universal use. For example, the universal intermediate representation structure 650 (630 and/or 640) may refer to an intermediate representation structure in which the source intermediate representation structure 620 is transformed into a framework-independent structure.

In an embodiment, the universal intermediate representation structure 630 may be generated by a method of setting a one-to-one correspondence relationship between a module and a node. In an embodiment, each of the modules 630a and 630b of the universal intermediate representation structure 630 may be configured to include a single node. For example, a transformation from the source intermediate representation structure 620 to the universal intermediate representation structure 630 may be performed by generating a single module that covers each of the nodes 625a, 625b, 625c, and 625d existing on the source intermediate representation structure 620. For example, a transformation from the source intermediate representation structure 620 to the universal intermediate representation structure 630 may be performed by forming a single module for each of the nodes 625a, 625b, 625c, and 625d existing on the source intermediate representation structure 620. As illustrated in FIG. 6, each of the nodes 625a, 625b, 625c, and 625d of the source intermediate representation structure 620 may correspond to each of the nodes 635a, 635b, 635c, and 635d of the universal intermediate representation structure 630. In the process in which the source intermediate representation structure 620 is transformed into the universal intermediate representation structure 630, the modules 620a and 620b of the source intermediate representation structure 620 are removed, and modules 630a, 630b, 630c, and 630d corresponding to each of the nodes 635a, 635b, 635c, and 635d of the universal intermediate representation structure 630 may be respectively generated.

In an embodiment, the universal intermediate representation structure 640 may refer to an intermediate representation structure configured to include only nodes corresponding to an atomic operator. For example, the universal intermediate representation structure 640 may have a form in which the modules 620a and 620b are removed from the source intermediate representation structure 620. The computing device 100 may generate the universal intermediate representation structure 640 by removing the framework-dependent modules 620 and 620b and maintaining the framework-independent nodes 625a, 625b, 625c, and 625d from the source intermediate representation structure 620. As illustrated in FIG. 6, the universal intermediate representation structure 640 may be configured to include framework-independent nodes 640a, 640b, 640c, and 640d. Each of the nodes 640a, 640b, 640c, and 640d of the universal intermediate representation structure 640 may correspond to each of the nodes 625a, 625b, 625c, and 625d of the source intermediate representation structure 620.

In an embodiment, the computing device 100 may receive a target framework to be compiled and/or converted from a user. In an embodiment, the computing device 100 may transform the universal intermediate representation structure 650 into a target intermediate representation structure 660. The target intermediate representation structure 660 may refer to an intermediate representation structure transformed to be compatible with a framework corresponding to a target artificial intelligence model 670 which is an object of transformation. The computing device 100 may receive target framework information from a user and may transform the universal intermediate representation structure 650 into the target intermediate representation structure 660 by using the received target framework information. The target intermediate representation structure 660 may be generated by generating target modules 660a, 660b, and 660c corresponding to each of target operators included in the target framework information. For example, the computing device 100 may identify the modules 660a, 660b, and 660c dependent on the target framework and may identify one or more nodes to be included in each of the modules 660a, 660b, and 660c dependent on the target framework. For example, a mapping table may be used in this identification process. For example, node(s) to be included in the target modules 660, 660b, and 660c may be determined by using a mapping relationship between the target modules 660, 660b, and 660c stored in the mapping table and a combination of nodes, and accordingly, the target intermediate representation structure 660 may be generated. For example, three modules on the universal intermediate representation structure 630 may be transformed into a single module 660a on the target intermediate representation structure 660, and the target intermediate representation structure 660 may be configured such that Node #2, Node #3, and Node #4 on the universal intermediate representation structure 630 are included in the single module 660a. For example, the node 635a in the universal intermediate representation structure 630 corresponds to the node 665a of the target intermediate representation structure 660, the node 635b in the universal intermediate representation structure 630 corresponds to the node 665b of the target intermediate representation structure 660, the node (Node #4 (not shown)) in the universal intermediate representation structure 630 corresponds to the node 665c of the target intermediate representation structure 660, the node 635c in the universal intermediate representation structure 630 corresponds to the node 665d of the target intermediate representation structure 660, and the node 635d in the universal intermediate representation structure 630 may correspond to the node 665e of the target intermediate representation structure 660. For example, the target intermediate representation structure 660 may be configured such that three nodes on the universal intermediate representation structure 640 are included in a single module 660a on the target intermediate representation structure 660. For example, the target intermediate representation structure 660 may be configured such that one node on the universal intermediate representation structure 640 is included in a single module 660b on the target intermediate representation structure 660. For example, the target intermediate representation structure 660 may be configured such that one node on the universal intermediate representation structure 640 is included in a single module 660c on the target intermediate representation structure 660. For example, the node 640a in the universal intermediate representation structure 640 corresponds to the node 665a of the target intermediate representation structure 660, the node 640b in the universal intermediate representation structure 640 corresponds to the node 665b of the target intermediate representation structure 660, the node (Node #4 (not shown)) in the universal intermediate representation structure 640 corresponds to the node 665c of the target intermediate representation structure 660, the node 640c in the universal intermediate representation structure 640 corresponds to the node 665d of the target intermediate representation structure 660, and the node 640d in the universal intermediate representation structure 640 may correspond to the node 665e of the target intermediate representation structure 660.

In an embodiment, when transforming from the universal intermediate representation structure 650 to the target intermediate representation structure 660, the nodes in the universal intermediate representation structure 650 are not removed, and a combination of nodes into a module may be changed.

In an embodiment, the nodes may be grouped in a target module unit by a method of assigning the nodes 640a, 640b, 640c, and 640d constituting the universal intermediate representation structure 650 to each of the target modules 660a, 660b, and 660c. The target modules 660a, 660b, and 660c may be generated and the target intermediate representation structure 660 may be generated by this grouping.

In an embodiment, the computing device 100 may perform a direct transformation from the source intermediate representation structure 620 to the target intermediate representation structure 660. In this embodiment, a direct transformation between the source intermediate representation structure 620 and the target intermediate representation structure 660 may be performed without using the universal intermediate representation structure 650. For example, the computing device 100 may determine which nodes each of the modules 660a and 660b constituting the target intermediate representation structure 660 will include, by using information about a target framework of the target artificial intelligence model 670. This determination may be determined by using, for example, a mapping relationship stored in a mapping table. The computing device 100 may perform a transformation from the source modules 620a and 620b to the target modules 660a and 660b dependent on the target framework, by using a correlation between a target operator and a combination of nodes stored in a mapping table.

In an embodiment, the computing device 100 may receive a target framework to be compiled and/or converted from a user. In an embodiment, the computing device 100 may receive platform information on which an artificial intelligence model after compiling and/or converting is to be deployed, from a user. Although operators (e.g., layers) of various frameworks are defined with the same name, there are cases where the same dynamics do not proceed. For example, in the case of a specific framework, there may be a case where a Bias is included in a Conv operator, and in the case of another framework, there is a case where a Bias is not included in a Conv operator. For example, according to a target framework to be targeted, two nodes of Conv and bias may be combined into a single Conv of an output framework or may be divided into a Conv module and an Add module, respectively. Information related to an operator for each framework and/or information related to a configuration method of an intermediate representation structure for each framework may be provided in the aforementioned mapping table.

In an embodiment, the computing device 100 may perform a generation and a transformation of an intermediate representation structure by using platform information received from a user. For example, the computing device 100 may remove or avoid operators that are not supported on a specific platform in the process of transforming to a module. For example, if an operator that is not supported on a specific platform needs to be implemented in a different form, the computing device 100 may transform the corresponding operator into a corresponding operator or a compatible (replaceable) operator in a mapping table. If there is no replaceable operator, a module may be configured by using node(s) representing a minimum unit of an operator.

In an embodiment, each of the modules in the intermediate representation structure can be transformed not only into an operator (or a layer) of a framework to be output, but also into operators that are compatible with (or executable on) a corresponding platform when inferring a converted or compiled model on an actual platform. Accordingly, a technical effect can be derived that a platform optimization or a hardware optimization of an artificial intelligence model can be achieved in an efficient manner by using the intermediate representation structure. As such, a technique according to an embodiment of the present disclosure can have a technical effect of enabling an optimization not only from a framework perspective but also from a hardware and a runtime perspective.

In an embodiment, the computing device 100 may convert the target intermediate representation structure 660 into a target artificial intelligence model 670. In the process of converting to the target artificial intelligence model 670, a module 660a may be transformed into an operator 670a, a module 660b may be transformed into an operator 670b, and a module 660c may be transformed into an operator 670c. This transformation between a module and an operator may be performed by using, for example, a mapping relationship defined in a mapping table. This transformation between a module and an operator may correspond to the reverse of the method in which the source artificial intelligence model 610 is transformed into the source intermediate representation structure 620.

A technique according to an embodiment of the present disclosure can generate an intermediate representation structure regardless of operators (layers) and modules that are arranged differently between frameworks, by using a minimum unit of an operator called a node that is independent of a framework. A technique according to an embodiment of the present disclosure can allow an efficient transformation to an operator (or layer) of various frameworks by grouping or combining these nodes into a module to correspond to an operator of various frameworks. Through this, a converting and a compiling from a graph structure composed of nodes to various frameworks can be possible regardless of an input or an output framework.

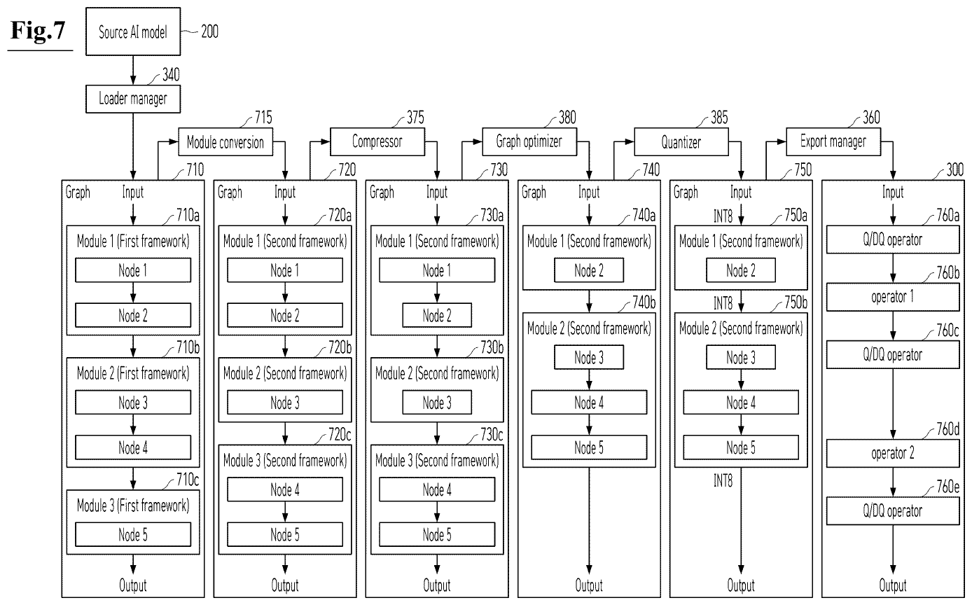

FIG. 7 illustratively shows a method in which model optimization tools 375, 380, and 385 are applied to an intermediate representation structure in a process of converting an artificial intelligence model, according to an embodiment of the present disclosure.

In an embodiment, the computing device 100 may perform a performance optimization of a converted target artificial intelligence model 300 by executing model optimization tools 375, 380, and 385 in a process of converting a source artificial intelligence model 200 to a target artificial intelligence model 300. Through the performance optimization, an execution performance of the target artificial intelligence model 300 on a specific platform and/or in a specific framework may be improved.

In an embodiment, the model optimization tools 375, 380, and 385 may be applied or executed on a novel intermediate representation structure according to an embodiment of the present disclosure.

In an embodiment, the computing device 100 may transform the source artificial intelligence model 300 into a source intermediate representation structure 710 by using a loader manager 340. In an embodiment, the computing device 100 may determine a loader corresponding to the source artificial intelligence model 200 from among a plurality of loaders for generating an intermediate representation structure by using the loader manager 340, and may transform the source artificial intelligence model 300 into the source intermediate representation structure 710 by using the determined loader.

In an embodiment, the source intermediate representation structure 710 may include modules 710a, 710b, and 710c corresponding to each of source operators executable on a first framework related to the source artificial intelligence model 200. In addition, nodes to be included in each of the modules 710a, 710b, and 710c may be determined by using a mapping table that represents a mapping relationship between atomic operators and model operators of the first framework that supports the source artificial intelligence model 200. A source intermediate representation structure 710 corresponding to the source artificial intelligence model 200 may be generated by using these nodes (Node 1, Node 2, Node 3, Node 4, and Node 5) and modules 710a, 710b, and 710c. The modules 710a, 710b, and 710c of the source intermediate representation structure 710 may be dependently determined on the first framework. Nodes included in each of the modules 710a, 710b, and 710c of the source intermediate representation structure 710 may be dependently determined on source operators of the source artificial intelligence model 200 corresponding to the first framework.

In an embodiment, the computing device 100 may perform a transformation 715 from the source intermediate representation structure 710 to a target intermediate representation structure 720 corresponding to a second framework that supports a target artificial intelligence model 300 to be converted. For example, the target intermediate representation structure 720 may be generated by a model editor 350, an export manager 360, and/or a separate module converter (not shown). Additionally, a universal intermediate representation structure, which is an intermediate representation independent of a framework, may be used in the process of transforming the source intermediate representation structure 710 to the target intermediate representation structure 720. This universal intermediate representation structure may, for example, include a combination of nodes corresponding to a minimum unit of atomic operators universally applicable to a plurality of frameworks.

In an embodiment, the target intermediate representation structure 720 may include the same nodes as the nodes (Node 1, Node 2, Node 3, Node 4, and Node 5) included in the source intermediate representation structure 710. The modules 720a, 720b, and 720c of the target intermediate representation structure 720 may be determined based on the second framework. The modules 720a, 720b, and 720c of the target intermediate representation structure 720 may be dependently determined on the second framework. A set of nodes to be included in each of the modules 720a, 720b, and 720c of the target intermediate representation structure 720 may be dependently determined on target operators of the target artificial intelligence model 300 corresponding to the second framework. A set of nodes to be included in the modules 720a, 720b, and 720c may be determined within a range of the nodes (Node 1, Node 2, Node 3, Node 4, and Node 5) included in the source intermediate representation structure 710. Based on the second framework, a set of nodes to be included in the modules 720a, 720b, and 720c may be determined from within the range of the nodes (Node 1, Node 2, Node 3, Node 4, and Node 5) included in the source intermediate representation structure 710. In this converting process, the target intermediate representation structure 720 may be configured such that Node 4, which was included in the module 710b of the source intermediate representation structure 710, is included in the module 720c of the target intermediate representation structure 720. A module transformation 715 may change the grouping of modules to be suitable for a target framework that can support a target artificial intelligence model 300 to be targeted.

In an embodiment, various model optimization tools 375, 380, and 385 operate based on an intermediate representation structure, and the intermediate representation structure may be modified according to these operations, and accordingly, a lightweighted and/or optimized intermediate representation structure may be generated. Finally, a lightweighted and/or optimized target artificial intelligence model 300 may be generated.

In an embodiment, various model optimization tools 375, 380, and 385 may be executed or applied on the target intermediate representation structure 720. In the example of FIG. 7, it is illustrated that the model optimization tools are applied in the order of a compressor 375, a graph optimizer 380, and a quantizer 385, but according to an implementation aspect, the model optimization tools may be applied in a different order, and only one or two of them may also be used. In addition, other model optimization tools for a performance transformation of an artificial intelligence model other than the compressor 375, the graph optimizer 380, and the quantizer 385 may also be applied on the intermediate representation structure. In addition, although it is illustrated in the example of FIG. 7 that the model optimization tools are executed on the target intermediate representation structure 720, it is also possible for the model optimization tools to be executed on the source intermediate representation structure 720 according to an implementation aspect.

In an embodiment, an intermediate representation manager 330 of the computing device 100 may modify a graph of an intermediate representation structure and/or modify information stored in the intermediate representation structure in conjunction with model optimization tools. For example, a model editor 350 of the intermediate representation manager 330 may modify an intermediate representation structure by using transformation, lightweighting, and/or optimization related information delivered from model optimization tools.

In an embodiment, it is also implementable for model optimization tools to perform a direct modification of an intermediate representation structure.

In an embodiment, an intermediate representation structure is composed of a module, a node, and a tensor as a graph structure, and each component may include information necessary for model optimization tools in addition to information related to the graph structure. Since the novel intermediate representation structure according to an embodiment of the present disclosure has a hierarchical structure or a dependent structure of a module dependent on a framework and a node independent of a framework, a method for processing a module must be defined in the operation process of model optimization tools. This method of processing a module is stored in the intermediate representation structure (e.g., a module, a node, and/or a tensor), and a lightweighting and/or an optimization operation of model optimization tools may be performed by utilizing the stored information.

In an embodiment, since the intermediate representation structure stores optimization reference information, the stored optimization reference information can be utilized when a model optimization tool operates. For example, based on a type of a model optimization tool, optimization reference information to be used by the model optimization tool among the optimization reference information stored in the intermediate representation structure may be different. That is, there is a correlation between a model optimization tool and optimization reference information stored and used in an intermediate representation structure.

In an embodiment, as in the example of FIG. 7, when a plurality of model optimization tools are applied to an intermediate representation structure, an input and an output of the model optimization tools may be sequentially connected. For example, an intermediate representation structure to which a first change by one model optimization tool is applied may be input to another model optimization tool, and a second change may be applied to the intermediate representation structure to which the first change is applied by the other model optimization tool.

In an embodiment, when an intermediate representation structure is changed as model optimization tools are applied on the intermediate representation structure, a hierarchical structure of the intermediate representation structure can be maintained. For example, when at least a part of the intermediate representation structure is changed, information of a module can be used as optimization reference information used by a model optimization tool. Accordingly, the hierarchical structure of the intermediate representation structure can be maintained before and after a change of the intermediate representation structure by the model optimization tool. In an embodiment, when an intermediate representation structure is changed as model optimization tools are applied on the intermediate representation structure, a dependency relationship to a framework (e.g., a second framework) of the intermediate representation structure can be maintained. For example, the computing device 100 can apply a model optimization tool to an intermediate representation structure by using information of a target framework (e.g., a second framework) included in the intermediate representation structure. Accordingly, a dependency relationship of a module to the target framework (e.g., the second framework) can be maintained before and after the change of the intermediate representation structure.

In an embodiment, an intermediate representation structure to which model optimization tools are applied may have a graph structure comprising: a node, a module configured with one or more nodes, and a tensor that represents an input of a module, an output of a module, a weight input to the module, and an activation input to the module, on the intermediate representation structure. Optimization reference information to be used for an operation of a model optimization tool is stored in the intermediate representation structure and can be utilized at the time of the operation of the model optimization tool. The optimization reference information may include channel axis tracking information, information indicating whether compression is possible, target hardware information, target framework information, and/or quantization information. A different type of optimization reference information may be used according to a type of a model optimization tool. As a non-limiting example, when the model optimization tool is a compressor 375, a first optimization reference information representing a compressible operator among operators of an artificial intelligence model within the intermediate representation structure may be used in the compressor 375. As a non-limiting example, when the model optimization tool is a graph optimizer 380, a second optimization reference information comprising quantization information for determining whether to change a module of the intermediate representation structure within the intermediate representation structure may be used in the graph optimizer. As a non-limiting example, when the model optimization tool is a quantizer 385, a third optimization reference information comprising target platform information on which an artificial intelligence model is to be executed within the intermediate representation structure may be used in the quantizer 385.

In an embodiment, the computing device 100 may change the target intermediate representation structure 720 by using a compressor 375. For example, the compressor 375 may receive the intermediate representation structure 720 which is an object of lightweighting and may generate or output a lightweighted intermediate representation structure 730. For example, the compressor 375 may change the target intermediate representation structure 720 for a lightweighting of a target artificial intelligence model. A lightweighted target intermediate representation structure 730 may be generated by the compressor 375. For example, the computing device 100 may modify a module and/or a node on an intermediate representation structure by using the compressor 375. Channel axis information may be utilized in the modification process of the module and/or the node. For example, the compressor 375 can reduce the size of an operator. For example, the compressor 375 can reduce the size of a node on an intermediate representation structure. In FIG. 7, it is illustrated that Node 2 in a module 730a is compressed and Node 3 in a module 730b is compressed as the compressor 375 is executed on the intermediate representation structure. For example, the compressor 375 can remove an unnecessary node in a module. For example, the compressor 375 can reduce the size of a node by removing an unnecessary part in the node.

In an embodiment, the compressor 375 may support a model lightweighting method including a pruning and a filter decomposition. The computing device 100 may add a value about whether a pruning is possible and/or whether a filter decomposition is possible to a module corresponding to an operator (layer) on which a pruning or a filter decomposition is possible on an intermediate representation structure. For example, the computing device 100 may extract tag information in which a compressible module or a compressible node is designated from an intermediate representation structure and may determine a compression configuration value according to the compressor 375. Then, the computing device 100 may change at least a part of the intermediate representation structure by using the compressor 375, based on the tag information and the compression configuration value. For example, the computing device 100 may extract information about another module connected to a compressible module or information about another node connected to the compressible node from an intermediate representation structure, and may change at least a part of the intermediate representation structure by using the compressor 375 based on the extracted information. For example, when the compressor 375 performs a pruning operation, a tensor (information stored in the tensor) on an intermediate representation structure may be changed by the pruning operation. For example, when the compressor 375 performs a filter decomposition operation, a node and/or a module on an intermediate representation structure may be changed by the filter decomposition operation.

In an embodiment, the compressor 375 may perform a compression considering a platform by using platform information (e.g., hardware information). For example, the compressor 375 may perform a lightweighting optimized for a corresponding hardware by using a phenomenon that, when an output channel number (Cout) of a neural network is increased in a specific hardware, an inference latency does not increase linearly, but is maintained constant in a specific section and then rapidly increases at a specific point.

In an embodiment, the graph optimizer 380 may change at least a part of an intermediate representation structure in order to increase the execution efficiency of a target artificial intelligence model 300. The graph optimizer 380 may generate an optimized target intermediate representation structure 740 including transformed target modules 740a and 740b by modifying a combination of nodes (Node 1, Node 2, Node 3, Node 4, and Node 5) included in an intermediate representation structure 730. A graph-optimized intermediate representation structure 740 may be generated by the graph optimizer 380. In the example of FIG. 7, a graph optimization operation is shown in which Node 1 in a module 730a of the intermediate representation structure 730 input to the graph optimizer 380 is removed. As a result of removing Node 1 in the module 730a, a module 740a of the graph-optimized intermediate representation structure 740 may be changed to include only Node 2. In the example of FIG. 7, a result is shown in which a module 730b and a module 730c of the intermediate representation structure 730 input to the graph optimizer 380 are integrated into a single module 740b. As an optimization operation of the graph optimizer 380 is applied to the intermediate representation structure, a module 740b having a connection relationship of Node 3, Node 4, and Node 5 is generated, and the existing modules 730b and 730c may be removed from the intermediate representation structure.

In an embodiment, the graph optimizer 380 may delete at least one node among nodes included in an intermediate representation structure, or may move at least one node among the nodes included in the intermediate representation structure from a first target module to a second target module on the intermediate representation structure, or may delete at least one module among modules included in the intermediate representation structure and move a node included in the deleted module to another module. In an embodiment, the graph optimizer 380 may determine a target template corresponding to a combination pattern of modules on an intermediate representation structure from among pre-stored module combination templates, and may change at least a part of the intermediate representation structure in the unit of a template representing a combination of modules, by applying the target template to the intermediate representation structure. Quantization information stored in a tensor of the intermediate representation structure may be used to determine whether to apply the target template to the intermediate representation structure.

In an embodiment, the graph optimizer 380 may replace a module included in an intermediate representation structure with another module. The graph optimizer 380 may change a combination of nodes of an intermediate representation structure to a combination of other nodes. For example, a matrix multiplication operator representing a matrix product may be replaced with a combination of basic operators (e.g., nodes) to which a low-level abstraction is applied in a graph optimization process. For example, a matrix multiplication operator may be replaced with a combination of Reshape, Convolution, Split, and Concatenation, etc. In this example, a module corresponding to a matrix multiplication operator and its node in an intermediate representation structure may be deleted and new modules and nodes may be generated.

In an embodiment, the quantizer 385 may be applied on an intermediate representation structure to reduce at least one of a size and an amount of computation of an artificial intelligence model. The quantizer 385 may receive an intermediate representation structure 740 as an input and may generate a quantized intermediate representation structure 750. A module 750a and a module 750b of the quantized intermediate representation structure 750 correspond to a module 740a and a module 740b of the input intermediate representation structure 740, respectively. Through the quantization 385, a quantization parameter (or a quantization format) called INT 8 in the example of FIG. 7 may be added to the quantized intermediate representation structure 750. For example, INT 8 represents a quantization parameter that represents an operation and a parameter of an artificial intelligence model as an 8-bit integer. Accordingly, for example, since an artificial intelligence model can be represented by scaling a value of a 32-bit floating point (float 32) to an 8-bit integer value, a size of the model can be reduced and a computation speed can be improved. In the example of FIG. 7, it is shown that a quantization parameter of float 32 is transformed to INT 8 by the quantizer 385. For example, information about a quantization parameter or a quantization format such as INT 8 may be stored in a tensor of an intermediate representation structure. In the example of FIG. 7, in the quantized intermediate representation structure 750, information about INT8 may be stored in a tensor representing an input of the module 750a, information about INT8 may be stored in a tensor(s) representing an output of the module 750a and an input of the module 750b, and information about INT8 may be stored in a tensor representing an output of the module 750b. For reference, quantization information (e.g., information about Float 32) in other intermediate representation structures 710, 720, 730, and 740 may also be stored in their tensors.

In an embodiment, the quantizer 385 may determine a range of a tensor value for an intermediate representation structure, based on target platform information on which an artificial intelligence model is to be executed. The quantizer 385 may determine a quantization parameter (e.g., a quantization scale, a zero-point, etc.) for quantizing an artificial intelligence model by using the range of the tensor value. The quantizer 385 may generate a quantized intermediate representation structure 750 by changing a tensor within an intermediate representation structure based on the quantization parameter. A tensor that is an object of quantization may be determined or a tensor that is to store quantization information may be determined, based on module boundary information on an intermediate representation structure.

In an embodiment, the export manager 360 may generate a target artificial intelligence model 360 by using an intermediate representation structure 750 to which model optimization tools have been applied. The export manager 360 may transform an intermediate representation structure into a target artificial intelligence model by using a mapping table representing a correlation between target operators corresponding to a framework of the target artificial intelligence model 360 (e.g., a second framework) and nodes. In the example of FIG. 7, a module 750a may be transformed into an operator 760b and a module 750b may be transformed into an operator 760d.

In an embodiment, the computing device 100 (e.g., the export manager 360) may generate Quantization/DeQuantization operators 760a, 760c, and 760e in a converting process by using quantization information stored in a tensor of a quantized intermediate representation structure 750. These quantization-related operators may be added to be connected with an input and an output of operators corresponding to modules. These quantization-related operators may be added to a boundary of each of the modules. In this manner, quantization-related information stored in a tensor on an intermediate representation structure can be transformed into quantization-related operators arranged before and after operators of an artificial intelligence model. As non-limiting embodiment, an input portion of a module and an output portion of a module can be related to a boundary of a module.

A technique according to an embodiment of the present disclosure can efficiently perform an optimization or a lightweighting operation on an intermediate representation structure through an interworking between optimization reference information stored in the intermediate representation structure and model optimization tool(s). In the present disclosure, optimization and lightweighting may be used interchangeably.

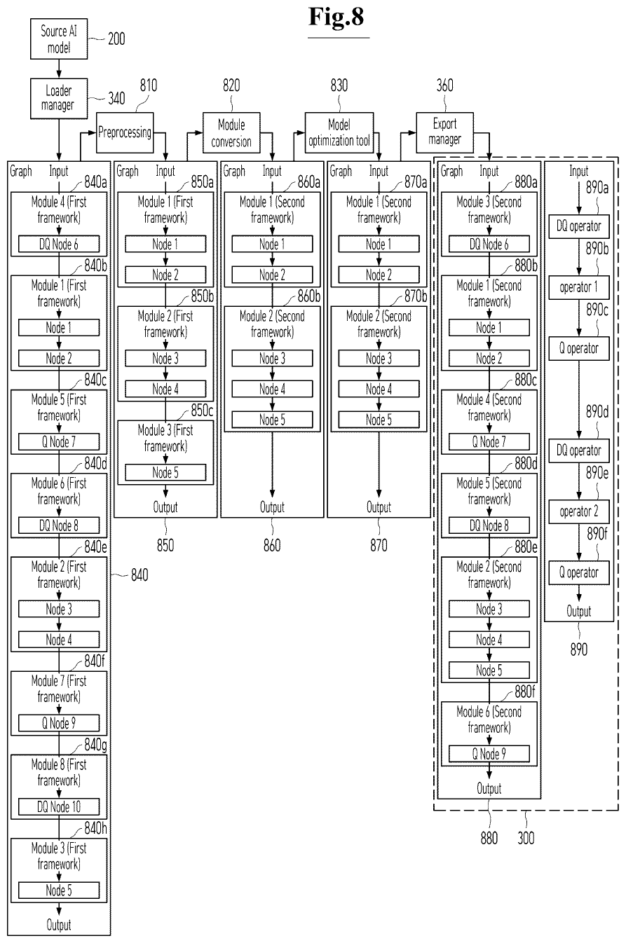

FIG. 8 illustratively shows a converting process to which a model preprocessing procedure is applied.

For features among the technical features in FIG. 8 that are redundant with the technical features described above, the description thereof will be omitted and replaced with the technical features described above.

In an embodiment, the computing device 100 may transform the source artificial intelligence model 200 into an intermediate representation structure 840 by using a loader manager 340. For example, the loader manager 340 of the computing device 100 may identify a first framework corresponding to the source artificial intelligence model 200 and determine a loader corresponding to the first framework, thereby allowing the generation of the intermediate representation structure 840 by the corresponding loader. The intermediate representation structure 840 may include modules 840b, 840e, and 840h corresponding to each of the source operators of the source artificial intelligence model 200. Quantization-related information of the source artificial intelligence model 200 may be represented by Q nodes 840c and 840f and DQ nodes 840a, 840d, and 840g on the intermediate representation structure 840.

In an embodiment, the computing device 100 may perform a preprocessing 810 on the intermediate representation structure 840, thereby removing quantization-related nodes 840a, 840c, 840d, 840f, and 840g and including quantization-related information in a tensor. This preprocessing 810 may be performed by, for example, the loader manager 340 and/or a model editor 350.

In an embodiment, as the preprocessing 810 is performed, a source intermediate representation structure 850 corresponding to the source artificial intelligence model 200 may be generated. The source intermediate representation structure 850 may include modules 850a, 850b, and 850c that are dependently determined on a first framework that can support the source artificial intelligence model 200. Through the preprocessing 810, information (e.g., DQ Node 6) related to a module 840a of the intermediate representation structure 840 before preprocessing may be stored in a tensor of an input portion of a module 850a of the source intermediate representation structure 850. A tensor of an output portion of the module 850a of the source intermediate representation structure 850 and a tensor of an input portion of a module 850b of the source intermediate representation structure 850 may be the same tensor. Q Node 7 information related to a module 840c of the intermediate representation structure 840 and DQ Node 8 related to a module 840d may be the same. Accordingly, information related to Q Node 7 and DQ Node 8 can be removed at once, and the corresponding information can be stored in the tensor(s) of the output portion and the input portion. According to an implementation aspect, a Q Node and a DQ Node may not be configured as a pair, and a node configuration in the form of Q Node, Q Node, and DQ Node may exist on the intermediate representation structure 840, and it may also be possible that in the preprocessing process, a Q Node is not deleted but left because it has a role of Re-quantization. Information (e.g., Q Node 9) related to a module 840f of the intermediate representation structure 840 may be stored in a tensor of an output portion of the module 850b of the source intermediate representation structure 850. Information (e.g., DQ Node 10) related to a module 840g of the intermediate representation structure 840 may be stored in a tensor of an input portion of a module 850c of the source intermediate representation structure 850. As described above, the preprocessing 810 may include storing a quantization node and a dequantization node on the intermediate representation structure in a tensor on the intermediate representation structure. The preprocessing 810 may include removing a quantization node and a dequantization node on the intermediate representation structure from the intermediate representation structure. The preprocessing 810 may include removing a module related to a quantization node and a dequantization node on the intermediate representation structure from the intermediate representation structure.

In an embodiment, a target intermediate representation structure 860 including modules 860a and 860b dependent on a second framework corresponding to the target artificial intelligence model 300 may be generated through a module transformation 820 of the preprocessed intermediate representation structure 850. The target intermediate representation structure 860 may be configured to include the module 860a and the module 860b to correspond to target operators of the second framework. Through the module transformation 820, the modules 850a, 850b, and 850c of the intermediate representation structure 850 may be transformed into the modules 860a and 860b of the target intermediate representation structure 860. Even if the module transformation 820 to the target intermediate representation structure 860 is performed, nodes (Node 1, Node 2, Node 3, Node 4, and Node 5) of the intermediate representation structure 850 may be maintained without being removed. A combination method of these nodes may be changed according to a framework. The computing device 100 may generate target modules 860a and 860b dependent on the second framework by grouping the nodes included in the source intermediate representation structure or the universal intermediate representation structure by using information about the second framework to which the source artificial intelligence model 200 is to be converted as a grouping condition. These target modules 860a and 860b may correspond to target operators in the target artificial intelligence model.

In an embodiment, a model optimization tool 830 may be used based on the target intermediate representation structure 860. As the model optimization tool 830 is applied to the target intermediate representation structure 860, an optimized or lightweighted intermediate representation structure 870 may be generated. The optimized or lightweighted intermediate representation structure 870 may be generated, as at least a part of a node and/or a module on the target intermediate representation structure 860 is changed. The optimized or lightweighted intermediate representation structure 870 may be generated, as information stored in a tensor on the target intermediate representation structure 860 is changed. The optimized or lightweighted intermediate representation structure 870 may be optimized or lightweighted to include modules 870a and 870b.

In an embodiment, an export manager 360 may convert the intermediate representation structure 870 into a structure corresponding to the target artificial intelligence model 300. For example, the export manager 360 of the computing device 100 may identify a second framework corresponding to the target artificial intelligence model 300 and determine a converter corresponding to the second framework, thereby allowing the generation of the target artificial intelligence model by the corresponding converter.

In an embodiment, the computing device 100 may extract quantization-related information stored in a tensor on the intermediate representation structure 870, and may add a quantization-related node and/or a quantization-related module on the intermediate representation structure by using the extracted quantization-related information. The computing device 100 (e.g., the export manager 360 and/or a model editor 350) may reconstruct the intermediate representation structure by a method of adding Q/DQ modules 880a, 880c, 880d, and 880f based on the quantization information stored in the tensor of the intermediate representation structure 870. The reconstructed intermediate representation structure 880 may be composed of a module 880a including DQ Node 5, a module 880b corresponding to the module 870a, a module 880c including Q Node 7, a module 880d including DQ Node 8, a module 880e corresponding to the module 870b, and a module 880f including Q Node 9. The computing device 100 may transform the reconstructed intermediate representation structure 880 into the target artificial intelligence model 300 by using a converter corresponding to the second framework (e.g., a converter for a transformation to the second framework or a converter for a transformation from the first framework to the second framework). The target artificial intelligence model 300 may be configured to include target operators 890a, 890b, 890c, 890d, 890e, and 890f as in reference numeral 890. The module 880a of the reconstructed intermediate representation structure 880 may correspond to a DQ operator 890a in the target artificial intelligence model structure 890. The module 880b of the reconstructed intermediate representation structure 880 may correspond to an operator 1 890b in the target artificial intelligence model structure 890. The module 880c of the reconstructed intermediate representation structure 880 may correspond to a Q operator 890c in the target artificial intelligence model structure 890. The module 880d of the reconstructed intermediate representation structure 880 may correspond to a DQ operator 890d in the target artificial intelligence model structure 890. The module 880e of the reconstructed intermediate representation structure 880 may correspond to an operator 2 890e in the target artificial intelligence model structure 890. And the module 880f of the reconstructed intermediate representation structure 880 may correspond to a Q operator 890f in the target artificial intelligence model structure 890. The computing device 100 may generate the target artificial intelligence model 890 executable in the second framework, by converting the target modules with the changed configuration in the intermediate representation structure into the target operators 890a, 890b, 890c, 890d, 890e, and 890f executable in the second framework. According to an implementation aspect, reference numerals 890b and 890e may be defined as target operators, and reference numerals 890a, 890c, 890d, and 890f may also be defined as quantization operators.

In an embodiment, when information of a target platform on which a target artificial intelligence model is to be deployed is received, the information of the target platform may be stored in a module and a tensor in an intermediate representation structure. The computing device 100 may generate the target artificial intelligence model 300 by a method of removing a target module corresponding to an unsupportable operator on the target platform, by using the information of the target platform in the intermediate representation structure.

A technique according to an embodiment of the present disclosure can universally achieve a transformation between deep learning frameworks by using a novel intermediate representation structure, in order to compensate for the advantages and disadvantages of each of various deep learning frameworks or to use a runtime optimized for a specific device. Through a new intermediate representation technique for a transformation to various frameworks, a user can derive an artificial intelligence model optimized for various frameworks and various platforms for the same model. Furthermore, a technique according to an embodiment of the present disclosure can efficiently achieve an optimization or a lightweighting of a model along with a transformation between deep learning frameworks by using a novel intermediate representation structure.

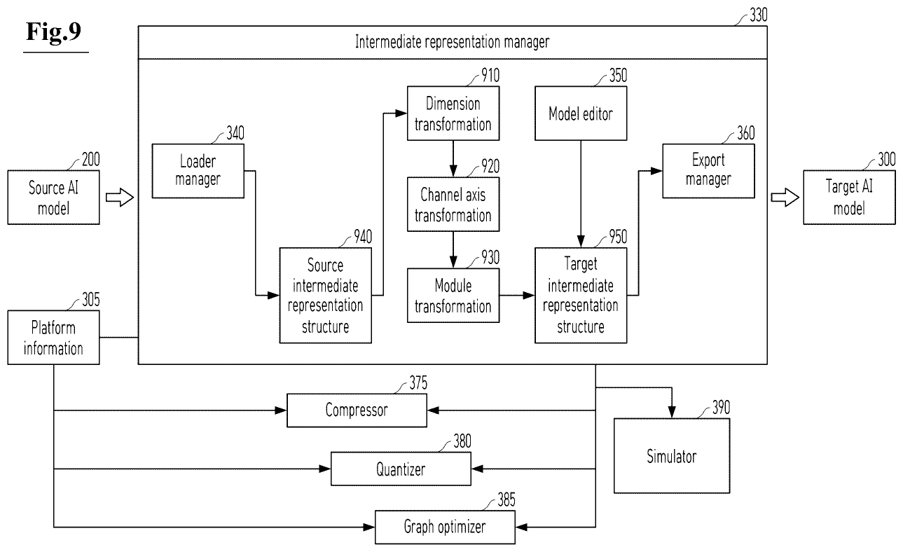

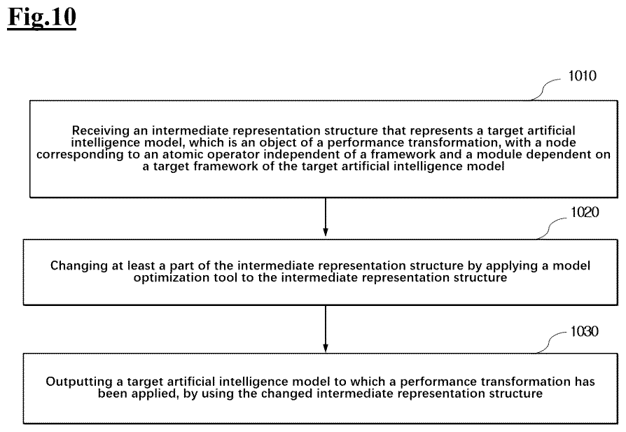

FIG. 9 illustratively shows a block diagram for transforming an artificial intelligence model according to an embodiment of the present disclosure.

For descriptions in FIG. 9 that are redundant with the descriptions provided above, the descriptions will be replaced with the above-provided descriptions for the sake of brevity.

In an embodiment, the computing device 100 may receive a source artificial intelligence model 200 and platform information 305. For example, an intermediate representation manager 330 of the computing device 100 may receive the source artificial intelligence model 200 and the platform information 305, and may generate an intermediate representation structure, perform an optimization of the intermediate representation structure, and/or perform a framework transformation from the source artificial intelligence model 200 to a target artificial intelligence model 300, by using the received source artificial intelligence model 200 and/or the platform information 305.

In an embodiment, the source artificial intelligence model 200 may be transformed into a source intermediate representation structure 940 through a loader manager 340. The loader manager 340 may determine a loader dedicated to a source framework of the source artificial intelligence model 200. The determined loader may transform the source artificial intelligence model 200 into the source intermediate representation structure 940.

In an embodiment, a dimension transformation 910, a channel axis transformation 920, and/or a model transformation 930 may be performed on the source intermediate representation structure 940. As a result of this performance, a target intermediate representation structure 950 corresponding to a target framework may be generated. The target intermediate representation structure 950 is an intermediate representation structure in which at least a part of the source intermediate representation structure 940 is changed, and a change on the intermediate representation structure may be performed by a model editor 350. For example, the dimension transformation 910, the channel axis transformation 920, and/or the model transformation 930 may be performed by components within the intermediate representation manager 330. As another example, the dimension transformation 910, the channel axis transformation 920, and/or the model transformation 930 may be performed by components existing outside the intermediate representation manager 330, and a transformation result may be reflected on the intermediate representation structure by communicating with the intermediate representation manager 330. In an embodiment, at least some of the dimension transformation 910, the channel axis transformation 920, and/or the model transformation 930 may also be executed in parallel with each other. In an embodiment, the dimension transformation 910, the channel axis transformation 920, and/or the model transformation 930 may also be performed in an execution order different from the execution order in FIG. 9. For example, according to an implementation aspect, at least some of the operations 910, 920, and 930 may also be omitted. For example, according to an implementation aspect, at least some of the operations 910, 920, and 930 may also be included in at least one operation among 375, 380, 385, and 390 of FIG. 3.

In an embodiment, the computing device 100 (e.g., the intermediate representation manager 330) may infer a dimension that represents a channel axis among the dimensions of tensors in the intermediate representation structure 940 by using a channel tracking algorithm, and may store the inferred dimension in the intermediate representation structure 940. The inferred dimension (e.g., channel axis tracking information) may be stored in a tensor of the intermediate representation structure 940.

In an embodiment, the dimension transformation 910 may be performed by utilizing the channel axis tracking information. The dimension transformation 910 may include fixing or changing a specific dimension of each of the tensors of the intermediate representation structure 940 by using the channel axis tracking information. The dimension transformation 910 may include, for example, fixing or changing all tensors that are configured differently with 2, 3, 4, 5, and/or 6 dimensions to 4 dimensions. A dimension value of tensors is changed by the dimension transformation 910, and the changed dimension value may be stored in the intermediate representation structure 940 (e.g., the tensors).

In an embodiment, the channel axis transformation 920 may be performed by utilizing the channel axis tracking information. The channel axis transformation 920 may refer to changing an axis that constitutes a channel according to a specific criterion (e.g., a set value of the intermediate representation structure). The channel axis transformation 920 may refer to changing an axis that constitutes a channel according to a specific criterion (e.g., a set value of the intermediate representation structure) by using the channel axis tracking information. For example, when an input in an intermediate representation structure is configured in a channel-first form of B, C, H, and W, and an output in the intermediate representation structure is configured in a channel-last form of B, H, W and C, a change in the position of the channel axis is required. Therefore, the channel axis transformation 920 may be performed to unify the position of the channel axis between the input and the output within the intermediate representation structure. The position of the channel axis changed according to the channel axis transformation 920 may be stored in the intermediate representation structure 940. The position of the channel axis changed according to the channel axis transformation 920 may be stored in the tensor(s) in the intermediate representation structure 940.

In an embodiment, the computing device 100 may determine a combination of nodes in the intermediate representation structure 940 to be suitable for target operators corresponding to a target framework of a target artificial intelligence model 300, and may generate target modules by combining the determined nodes through a model transformation 930. The target intermediate representation structure 950 may be generated by generating the target modules. The transformation and modification work to the target intermediate representation structure 950 may be performed by the model editor 350 that modifies the intermediate representation structure.

In an embodiment, the computing device 100 may perform an optimization or a lightweighting on the target intermediate representation structure 950 by using a compressor 375, a quantizer 380, and a graph optimizer 385. The computing device 100 may perform an optimization or a lightweighting work on the target intermediate representation structure 950 based on the platform information 305. The platform information 305 may be used in the operation process of the compressor 375, the quantizer 380, and/or the graph optimizer 385. For example, a hardware constraint and/or a compiler constraint in the platform information 305 may be used in an optimization or a lightweighting operation of the compressor 375, the quantizer 380, and/or the graph optimizer 385.

In an embodiment, the intermediate representation structures 940 and 950 may be used to generate an expected inference simulation result for when the target artificial intelligence model 300 is executed on a platform before a transformation to the target artificial intelligence model 300. The simulator 390 may generate an inference simulation result without an execution of the actual artificial intelligence model on the platform, by using the intermediate representation structures 940 and 950 and the platform information 305.

In an embodiment, the computing device 100 may execute a model optimization tool on the target intermediate representation structure 950 by using an execution order and parameters of model optimization tools on a target transformation scenario determined by the scenario manager 310.

In an embodiment, the computing device 100 may sequentially execute the model optimization tools on the target intermediate representation structure 950 according to the execution order of the model optimization tools on the target transformation scenario. According to an implementation aspect, it may also be possible for the computing device 100 to execute the model optimization tools in parallel on the target intermediate representation structure 950 for model optimization tools designated as capable of parallel execution on the target transformation scenario.

In an embodiment, the computing device 100 may generate an expected simulation result for when a target transformation scenario is applied to a target artificial intelligence model by using a simulator 390. In this manner, the utility of the determined target transformation scenario, the utility of the framework-transformed model, and/or the utility of the model optimization tool can be verified in a resource-efficient way through an expected simulation result, without performing the execution of the actual platform and model. As framework-dependent module(s) of the intermediate representation structure are modified according to the target platform, a simulation for the target artificial intelligence model on the target platform can be performed. In this manner, the expected execution performance according to the combination of the target artificial intelligence model and the target platform when model optimization tools are applied to the target artificial intelligence model can be verified. Accordingly, the utility of the model optimization tools can be verified.

In an embodiment, the computing device 100 may apply and/or execute the target model optimization tools included in the target transformation scenario on the target artificial intelligence model through a simulator 390 according to the order specified in the target transformation scenario, without executing the transformed target artificial intelligence model on the target platform. This execution through a simulator 390 may include that the target model optimization tools are applied or executed on the intermediate representation structure corresponding to the combination of the target artificial intelligence model and the target platform. The computing device 100 may generate a performance verification result including an expected inference simulation result for a case where the transformed target artificial intelligence model is executed on the target platform. The performance verification result may be utilized in the verification process of the target transformation scenario.

In an embodiment, the computing device 100 may compare the performance verification result of the transformed target artificial intelligence model with a performance prediction value mapped to the target transformation scenario. For example, the computing device 100 may compare the result simulated through the simulator with the performance prediction value stored in the scenario DB to verify if there is a difference between the actual performance of the target transformation scenario and the prediction value. The computing device 100 may determine whether to modify the target transformation scenario based on the result of the comparison. For example, if the difference value between the performance prediction value and the performance verification result obtained through the simulator exceeds a predetermined threshold difference (or if the performance is not better than the performance prediction value), the computing device 100 may determine to modify the target transformation scenario. In this case, the computing device 100 may change a parameter of at least one of the target model optimization tools included in the target transformation scenario. For example, changing the parameter may refer to changing the value of an optimization-related parameter mapped to the model optimization tools (e.g., compression rate, compression ratio, compression method, quantization method, etc.). The computing device 100 may perform a second transformation of the target artificial intelligence model by applying the target model optimization tools including the changed parameter to the target artificial intelligence model before transformation. Accordingly, a technical effect can be achieved in that the computing device 100 can achieve more efficient and more accurate optimization of an artificial intelligence model by modifying a transformation result that has not reached the performance prediction value on the scenario DB. For example, the second transformation is a transformation that follows a first transformation (i.e., an application of first model optimization tool(s)) that was simulated through a simulator, and may be applied to the target artificial intelligence model before the first transformation was made. For example, the result according to the second transformation may also be simulated by a simulator in the aforementioned manner. If the simulation result for the second transformation satisfies a predetermined threshold criterion, the computing device 100 may update the scenario DB with the parameter value included in the second transformation. If the simulation result for the second transformation satisfies a predetermined threshold criterion (e.g., if it falls within the range of the expected performance value, or if it is not degraded compared to the expected performance value), the computing device 100 may update the parameter value of the target transformation scenario on the scenario DB with the parameter value included in the second transformation.

In an embodiment, assume that according to the parameters (e.g., compression ratio 10%) of the compressor and the parameters (e.g., Int8:Int16=1:9) of the quantizer included in the determined target transformation scenario, the performance verification result according to the first transformation was output as an accuracy decrease of 0.5% and an inference speed decrease of 3%. If the performance prediction value mapped to the target transformation scenario on the scenario DB is recorded as an accuracy decrease of 0.3% and an inference speed decrease of 3%, the computing device 100 may determine that the performance verification result according to the first transformation did not satisfy the threshold criterion, change at least one of the parameters of the compressor and/or the quantizer included in the target transformation scenario, and perform a second transformation of the target artificial intelligence model according to the target transformation scenario to which the changed parameter is applied. If the computing device 100 performs a simulation of the target artificial intelligence model on which the second transformation was performed and determines that the simulation result satisfies the criterion according to the performance prediction value, it may output the target artificial intelligence model transformed or optimized according to the second transformation. In this case, the target transformation scenario may be updated with the parameters defined by the second transformation. As the scenario DB is dynamically updated in this manner, a scenario DB composed of more robust and solid transformation scenarios can be generated and managed.

In an embodiment, the use of the simulator 390 may be associated with a performance improvement of the scenario manager 310. Because the scenario DB can be dynamically updated based on the performance measured through the simulator 390, the reliability and accuracy of the scenario DB can be improved.

In an embodiment, the computing device 100 may convert the target intermediate representation structure 950 into the target artificial intelligence model 300 by using an export manager 360. A converting process of changing each of the target modules of the target intermediate representation structure 950 to a target operator may be performed.

FIG. 10 is a flowchart illustratively showing a method for outputting a target artificial intelligence model to which a performance transformation has been applied, according to an embodiment of the present disclosure.

According to an implementation aspect, an additional step may be added to the flowchart of FIG. 10, or some steps within the flowchart may be omitted. For features among the technical features in FIG. 10 that are redundant with the features described above, the description thereof will be omitted and will be replaced with the features described above.

In an embodiment, the computing device 100 may receive an intermediate representation structure that represents a target artificial intelligence model, which is an object of a performance transformation, with a node corresponding to an atomic operator independent of a framework and a module dependent on a target framework of the target artificial intelligence model (1010).

In an embodiment, the intermediate representation structure may have a graph structure including modules dependent on a specific framework of a specific artificial intelligence model, nodes constituting the modules, and tensors. The graph structure represents the artificial intelligence model, the module represents an operator within the artificial intelligence model, the node represents an atomic operator constituting the operator of the artificial intelligence model, and the tensor may include information for an execution of the artificial intelligence model, the module, and/or the node. For example, the tensor may represent an input of a module, an output of a module, a weight input to the module, and an activation input to the module, on the intermediate representation structure. The intermediate representation structure may include optimization reference information to be used for optimization operations of a model optimization tool. The optimization reference information may include channel axis tracking information, information indicating whether compression is possible, target hardware information, target framework information, and quantization information.

In an embodiment, the computing device 100 may change at least a part of the intermediate representation structure by applying a model optimization tool to the intermediate representation structure (1020).

In an embodiment, the model optimization tool(s) may modify the model by using the hierarchical structure of the intermediate representation structure. In an embodiment, the model optimization tool(s) may modify the intermediate representation structure by using the hierarchical structure of the intermediate representation structure.

In an embodiment, the computing device 100 may, when changing the intermediate representation structure, determine an object of change in the intermediate representation structure by using information of a module of the intermediate representation structure. For example, the computing device 100 may determine an object that is a target of change from among nodes, modules, and tensors within the intermediate representation structure by using the information of the module of the intermediate representation structure. Optimization or lightweighting operations of model optimization tools may be performed on the object of change.

In an embodiment, the intermediate representation structure may be composed of a graph, a node, and a tensor, and may further include a module that logically groups the nodes. The module in the intermediate representation structure may be conceptually used to output a model transformed to be suitable for a framework. The connection relationship between a node and a tensor constituting the graph in the intermediate representation structure does not change depending on the presence or absence of a module. In order to perform the optimization of model optimization tools, a modification of a node and/or a tensor within the intermediate representation structure is necessary. In the process in which the intermediate representation structure is modified by such a model optimization tool, information related to a module may be necessary to maintain the hierarchical structure and dependency of the intermediate representation structure. For example, a compressor may determine a node and/or a tensor that is an object of modification by using a parameter indicating whether compression is possible, such as whether pruning is possible for each module within the intermediate representation structure. For example, a graph optimizer may determine a node to be replaced or changed through a pattern matching of a module. For example, a quantizer may determine a tensor that is an object of quantization based on a module. In these examples, the computing device 100 may determine an object within the intermediate representation structure that is an object of optimization of model optimization tools by using the information of the module within the intermediate representation structure.

In an additional embodiment, the compressor may also determine whether to perform pruning (compression) in a node unit by using a parameter indicating whether compression is possible, such as whether pruning is possible for each node.

The model optimization tool in the present disclosure may be used interchangeably with a model optimization algorithm, a model optimization method, and/or a model optimization scheme. As this model optimization tool is applied on an intermediate representation structure by the computing device 100 (e.g., a server, etc.), a performance change of a model can be achieved.

In an embodiment, when a model optimization tool (e.g., a graph optimizer, etc.) changes an intermediate representation structure, information of a target framework included in the intermediate representation structure may be used by the model optimization tool, and accordingly, a dependency relationship (e.g., a dependency relationship between a module and a node) of a module to the target framework may be maintained before and after the change of the intermediate representation structure. In an embodiment, when a model optimization tool (e.g., a graph optimizer, etc.) changes an intermediate representation structure, as information of a module of the intermediate representation structure is used as optimization reference information used by the model optimization tool, a hierarchical structure (e.g., a hierarchical structure between a module and a node) of the intermediate representation structure may be maintained before and after the change of the intermediate representation structure. In an additional embodiment, when a compressor modifies a channel, a dependency relationship and a hierarchical structure within the intermediate representation structure are not changed. In an additional embodiment, as a quantization result of a quantizer is stored in a tensor, a dependency relationship and a hierarchical structure within the intermediate representation structure are not changed.

In an embodiment, a model optimization tool may perform a change on an intermediate representation structure by using different optimization reference information from an intermediate layer structure. According to a type of a model optimization tool, optimization reference information to be used by the model optimization tool among the optimization reference information stored in the intermediate representation structure may be different. For example, when the model optimization tool is a compressor, a first optimization reference information representing a compressible operator (a prunable operator and/or a filter-decomposable operator) among operators of an artificial intelligence model within the intermediate representation structure may be used in the compressor. For example, the compressor may change an intermediate representation structure by using whether compression is possible for each module and/or whether compression is possible for each node within the intermediate representation structure as optimization reference information. For example, the compressor may perform a compression suitable for a situation of a specific hardware by using platform information of an intermediate representation structure. For example, when the model optimization tool is a graph optimizer, a second optimization reference information comprising quantization information for determining whether to change a module of the intermediate representation structure within the intermediate representation structure may be used in the graph optimizer. For example, when the model optimization tool is a quantizer, a third optimization reference information comprising platform information on which an artificial intelligence model is to be executed within the intermediate representation structure may be used in the quantizer. For example, the quantizer may perform a quantization by using platform information (e.g., hardware information) as optimization reference information.

In an embodiment, the compressor may change an intermediate representation structure (e.g., a module) by using at least one compression technique of a pruning and a filter decomposition. The compressor may perform an optimization of an intermediate representation structure by using tag information and compression method information within the intermediate representation structure. For example, the compressor may extract tag information in which a compressible module or a compressible node is designated from an intermediate representation structure. This tag information is managed for each module and/or for each node and may be stored in the corresponding module or the corresponding node. When a compression configuration value according to the compressor is determined, the intermediate representation structure may be modified by using the compression configuration value and the tag information. For example, the compression configuration value may include a pruning ratio and/or a filter decomposition rank according to the type of a compression algorithm. The compression configuration value and the tag information determined in the compressor are delivered to a model editor 350, and a modification work of the intermediate representation structure may be performed by the model editor 350 based on the compression configuration value and the tag information.

In an embodiment, in the case of a pruning operation of the compressor, information (e.g., information related to whether compression is possible) about a module or a node in a connection relationship may be stored in an intermediate representation structure. For example, when a compression scheme of the compressor is a pruning scheme, information about another module connected to a compressible module or information about another node connected to the compressible node is extracted from an intermediate representation structure, and at least a part of the intermediate representation structure may be changed by the compressor based on the extracted information.

In an embodiment, in the case of a pruning operation of the compressor, information about whether a specific module or a specific node is compressible may also be stored in another module or another node connected to the specific module or the specific node.

In an embodiment, a graph optimizer may determine a target template corresponding to a combination pattern of modules on a received intermediate representation structure, from among pre-stored module combination templates. The graph optimizer may change at least a part of the intermediate representation structure in a template unit representing a combination of modules, by applying the target template to the intermediate representation structure. For example, the graph optimizer may manage a combination of one or more modules in a template form. When a module combination template that matches a combination of modules within an intermediate representation structure is determined, the modules within the intermediate representation structure may be modified to correspond to this module combination template. The computing device 100 stores pattern information of modules for an optimization of a model, and can determine patterns that can be optimized within an intermediate representation structure by using the stored pattern information. The graph optimizer of the computing device 100 determines a pattern (i.e., a combination of modules) that can be optimized within an input intermediate representation structure, and can determine in what form the determined pattern should be changed. For example, the graph optimizer may determine which module(s) and node(s), having what parameters, should constitute the determined pattern, and may allow a modification work of the intermediate representation structure by a model editor 350 to be performed by delivering the determined information to the model editor 350.

In an embodiment, a graph optimizer (or a model editor that communicates with the graph optimizer) may, when changing at least a part of an intermediate representation structure, perform a folding operation of removing a node or a module on the intermediate representation structure, a fusion operation of integrating nodes or modules on the intermediate representation structure into a single node or a single module, a replacement operation of replacing a node or a module on the intermediate representation structure with another node or another module, and/or a change operation of changing an arrangement order of a node or a module on the intermediate representation structure.

In an embodiment, the graph optimizer may manage combination pattern information of modules for an optimization of an intermediate representation structure. The graph optimizer may determine a combination pattern of modules that can be optimized within an intermediate representation structure by comparing a plurality of combination patterns and a combination pattern of modules within the intermediate representation structure (e.g., pattern matching). The graph optimizer may determine how a determined module combination pattern within an intermediate representation structure should be changed. The graph optimizer may determine what configuration of modules and nodes, possessing which parameters, the determined module combination pattern within the intermediate representation structure will have. In this manner, the graph optimizer can implement an optimization that modifies an intermediate representation structure in units of a combination of modules. For example, pattern matching may operate in units of a combination of modules to determine if there are patterns that match each other.

In an embodiment, even if modules perform the same function, the nodes included therein may be different. Accordingly, pattern matching may also be performed by comparing combination patterns of nodes for the same module pattern. Pattern matching may also be performed based on a combination pattern of nodes. The computing device 100 may perform a pattern matching between patterns of an intermediate representation structure and pre-stored patterns by using a module pattern unit and/or a node pattern unit. The expression “the same module” may mean that the targets of the modules are the same. For example, if the target of a module is silu, a node existing in the module may be a single silu node, or it may also be represented by a combination of sigmoid and mul. Therefore, there may be several different patterns for a pattern composed of modules a, b, and c. Accordingly, a comparison between a pattern of an intermediate representation structure and a pre-stored pattern can be performed by considering even a combination of nodes constituting modules a, b, and c. That is, if the nodes constituting the same module combination pattern are different, they can be considered as different combination patterns.

In an embodiment, the graph optimizer may determine whether to apply a module combination template by using quantization information stored in an intermediate representation structure. For example, the graph optimizer may determine whether to apply a module combination template, by using quantization information of an input or an output between a module and a module or by using whether the quantization information exists. For example, the graph optimizer may determine whether to apply a module combination template, by using quantization information of an input or an output between a node and a node or by using whether the quantization information exists. For example, when a graph of an intermediate representation structure is configured in the form of input-[Convolution]-mid-[Add]-output, the graph optimizer may perform an optimization operation of fusing Convolution and Add, if quantization information that mid (e.g., an intermediate output of Convolution) between a Convolution module and an Add module has is empty. If quantization information of mid and output are different from each other, the graph optimizer may not perform a fuse operation according to a hardware requirement included in platform information.

In an additional embodiment, the graph optimizer may perform an optimization operation of performing a pattern matching not only in a module unit but also in a node unit. For example, the graph optimizer may determine a target template corresponding to a combination pattern of modules and a combination pattern of nodes on an intermediate representation structure, from among pre-stored module combination templates. The graph optimizer may change at least a part of the intermediate representation structure in a template unit representing a combination of modules and a combination of nodes, by applying the target template to the intermediate representation structure. For example, when a plurality of target templates are determined according to a combination pattern of modules, the graph optimizer may additionally use a combination pattern of nodes to determine a template to be applied to an intermediate representation structure from among the plurality of target templates.

In an embodiment, when a quantization-related operator is included in a received artificial intelligence model, the computing device 100 may perform a preprocessing step of reflecting the quantization-related operator into a module on an intermediate representation structure and adding the quantization-related module to a tensor on the intermediate representation structure. For example, the preprocessing step may include removing a quantization-related operator transformed into a module on an intermediate representation structure and storing information about the removed quantization-related operator in a tensor on the intermediate representation structure. Model optimization tools may be executed or applied on the intermediate representation structure to which the preprocessing is applied. The computing device 100 may, when a quantization-related operator is included in a received intermediate representation structure, perform a preprocessing step of removing the quantization-related operator from the intermediate representation structure and adding quantization information corresponding to the quantization-related operator to a tensor within the intermediate representation structure, before changing at least a part of the intermediate representation structure by using a model optimization tool.

In an embodiment, a quantizer may determine a range of a tensor value for an intermediate representation structure by using target platform information (e.g., target hardware information) on which an artificial intelligence model is to be executed. For example, the target platform information may include target hardware information on which the target artificial intelligence model is to be executed, target compiler information for connecting the target artificial intelligence model to a target hardware, and/or runtime information representing an environment of the target hardware on which the target artificial intelligence model is to be executed. The quantizer may determine a quantization parameter for quantizing a model by using the range of the tensor value. For example, the quantization parameter may be information indicating how to change a value when changing a data type (e.g., changing float 34 to INT 8), and may include a scale, a zero point, and/or a maximum and a minimum value (min and max). For example, the quantization parameter may be a component of a change formula for changing a data type. For example, a scale can quantitatively represent how much to reduce a float value. For example, a zero point can specify a position corresponding to 0 in an integer representation. For example, a maximum and a minimum value can represent a range of a float. The quantizer may generate a quantized intermediate representation structure by changing a tensor within an intermediate representation structure based on the quantization parameter. For example, the quantization may include a tensor-unit quantization and/or a channel-unit quantization.

In an embodiment, the quantizer may determine a tensor to be quantized on an intermediate representation structure and may search for a quantization parameter to determine how to quantize the determined tensor. The quantizer may perform a search for a quantization parameter by using platform information (e.g., hardware information on which a model is to be executed). A quantization for a tensor can be performed by using a quantization parameter according to a search result. The quantization result can be stored in a tensor of the intermediate representation structure. For example, a quantization parameter may be added to a tensor of the intermediate representation structure.

In an embodiment, the quantizer may determine a tensor that is an object of quantization within an intermediate representation structure, or may determine a tensor that is an object for storing quantization information within the intermediate representation structure, based on module boundary information in the intermediate representation structure. For example, the quantizer may process a quantization process by distinguishing a tensor to store quantization information and a tensor that does not, by using a module or a boundary of a module (e.g., an input or an output of a module) in an intermediate representation structure.

In an embodiment, the computing device 100 may perform a method for preventing a duplicate operation of model optimization tools. For example, when an intermediate representation structure is cumulatively changed by a plurality of model optimization tools, information on the number of times the model optimization tools have been applied to the intermediate representation structure may be stored within the intermediate representation structure. A duplicate application of model optimization tools can be prevented by using this information on the number of times. That is, when a model optimization tool is applied to an intermediate representation structure, whether to apply the model optimization tool can be determined by using the information on the number of times.

In an embodiment, when the intermediate representation structure is changed by a plurality of model optimization tools, a target lightweighting value that defines a lightweighting target may be stored in the intermediate representation structure. A cumulative value for a lightweighting value applied to the intermediate representation structure by each of the model optimization tools may be stored in the intermediate representation structure. In this situation, when a model optimization tool is applied to the intermediate representation structure, a target lightweighting value for the intermediate representation structure of the model optimization tool may be determined based on a comparison between the cumulative value and the target lightweighting value. The target lightweighting value can be used as a quantitative value that is an object of a target or a comparison of an optimization or a lightweighting. The target lightweighting value can be compared with a simulation result of an intermediate representation structure to which model optimization tools have been applied, and whether to change the model optimization tools and/or whether to change a target transformation scenario, etc., can be determined.

In an embodiment, when the model optimization tool is a simulator, the simulator may simulate or imitate a quantization value by adding a quantization node (or a module) and/or a dequantization node (or a module) to an intermediate representation structure by using quantization information stored in a tensor of the intermediate representation structure in a simulation process. This addition operation may be performed by the simulator or by a quantizer or by a model editor. When an addition operation in the quantizer is performed, after the quantizer adds a quantization node (or a module) and/or a dequantization node (or a module) to an intermediate representation structure, a simulation by a simulator may be performed by using the added intermediate representation structure. For example, a position where a Q/DQ node (or a module) is added on an intermediate representation structure may be determined based on a position of a module or a boundary of a module on the intermediate representation structure.

In an embodiment, platform information may be stored in a graph, a module, a node, and/or a tensor in an intermediate representation structure. When a hardware uses different processing units, modules on an intermediate representation structure may include information about the different processing units. When this information is changed, nodes constituting a module or nodes constituting a quantization/dequantization module may be changed at the time of an execution of a simulator. For example, for an intermediate representation structure including in_tensor-module_A(node_a-node_b)-out_tensor, when hardware_1 is designated as a simulation target, the configuration of module_A is the same at the time of an operation of the simulator, and a Q/DQ module that simulates a quantization operating on hardware_1 may be added to in_tensor and out_tensor. When hardware_2 is designated as a simulation target, a parameter of node_a or node_b constituting module_A may be modified and they may be respectively transformed into node_a2 and node_b2. A Q/DQ module related to hardware_2 may be added to in_tensor and out_tensor.

In an embodiment, a model editor may, in the execution process of a simulator, add a Q/DQ module to an intermediate representation structure based on quantization information stored in tensors of the intermediate representation structure, and may deliver the intermediate representation structure to the simulator. The simulator may perform a simulation by using the reconstructed intermediate representation structure.

In an embodiment, the computing device 100 may output a target artificial intelligence model to which a performance transformation has been applied, by using the changed intermediate representation structure (1030).

In an embodiment, the target artificial intelligence model may refer to a result converted from an intermediate representation structure to which model optimization tool(s) has been applied. Since a model optimization tool has been applied, when the target artificial intelligence model is executed on a target platform, an execution performance can be improved.

In an embodiment, the computing device 100 may output a target artificial intelligence model by converting modules of an intermediate representation structure changed by model optimization tools into target operators.

In an embodiment, the computing device 100 may output a target artificial intelligence model to which a performance transformation has been applied, by converting an intermediate representation structure into a target artificial intelligence model by using a converter (or an export manager). For example, the converter may convert the changed intermediate representation structure into a target artificial intelligence model by using a channel dimension that represents a channel axis among the dimensions of tensors of the changed intermediate representation structure. The channel dimension may be stored in the changed intermediate representation structure.

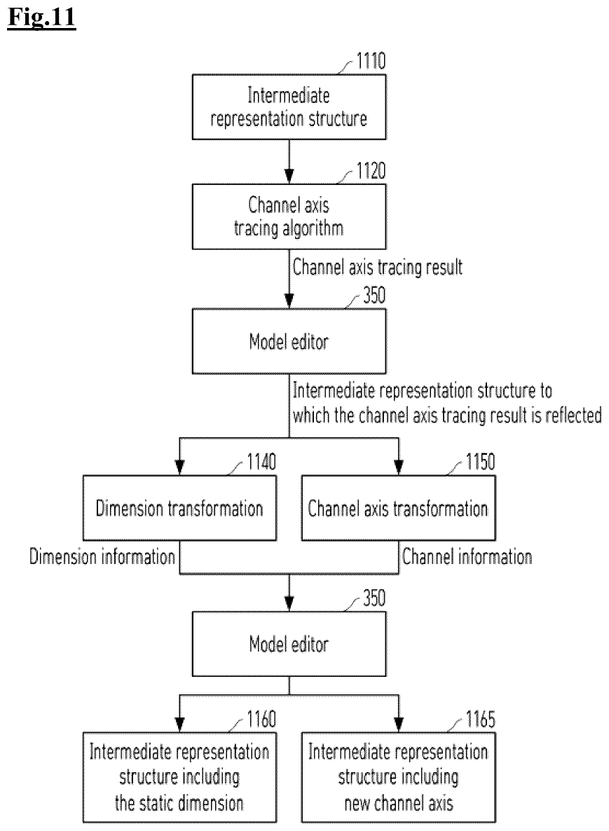

FIG. 11 illustratively shows an intermediate representation structure to which a channel axis tracing (or tracking) result is applied,

In an embodiment, the computing device 100 may receive an intermediate representation structure 1110.

In an embodiment, the computing device 100 may generate a channel axis tracing result by using a channel axis tracing algorithm 1120 on the intermediate representation structure.

The channel axis tracing result may be included in optimization reference information used by a model optimization tool. For example, the optimization reference information may include the channel axis tracing result, information indicating whether it is prunable or decomposable, target platform information, framework information, and/or quantization information stored in a tensor. For example, data input to and output from an operation of an artificial intelligence model can be represented in a multi-dimensional tensor form. For example, in the case of visual data such as images or videos, a tensor is composed of axes such as batch, channel, and spatial. Among these, the channel implies features, i.e., channel information, for representing input/output data such as color (e.g., RGB), feature maps, depth, and filter output. A channel axis may refer to an axis that represents this channel information. Accurate identification and tracing of the channel axis can be used as an essential process in artificial intelligence model optimization and transformation processes. For example, for artificial intelligence model optimization, when transforming a specific operator within a model into an operator that is optimized for or supported by a target hardware (e.g., CPU, GPU, NPU, FPGA, etc.), it is essential to accurately trace the channel axis to maintain channel information. As another example, when transforming an artificial intelligence model to a target framework (e.g., PyTorch, TensorFlow, ONNX, etc.), the position of the channel axis may be defined differently between different frameworks during the transformation process, and accordingly, by accurately tracing the channel axis, channel information must be maintained even if the position of the channel axis is changed to match the operator or layout rules of the target framework.

In the present disclosure, the channel axis may refer to an axis that encompasses a channel utilized to distinguish specific attributes, features, or information of data processed in an artificial intelligence model, among various axes of a tensor processed in the artificial intelligence model. For example, in the case of a tensor corresponding to image data, the channel may correspond to dimensions such as color, depth, etc., of a feature map. For instance, a grayscale image has one channel representing a binary classification of grayscale, and a color RGB image has three channels corresponding to respective color attributes (Red, Green and Blue).

Taking a CNN (Convolutional Neural Network)-based artificial intelligence model as an example, the model internally processes input data using multiple filters when undergoing a convolution operation, and the number of channels can change between input data and output data. For example, if 64 filters are applied to RGB input image data of 224×224×3 size, the output feature map may have a size of 224×224×64. In this case, the number of channels expands from 3 to 64, which may mean that the features of the input image data, which were represented by three feature maps containing color information, are subdivided and represented by 64 feature maps containing high-level abstract features such as edges, textures, and parts of specific objects. That is, the number of channels may refer to the type or the number of features extracted in an intermediate layer within an artificial intelligence model.

Meanwhile, the position of the channel axis can be set differently for each framework that designs the artificial intelligence model. For example, in the case of the PyTorch framework, an input tensor has a shape of (N, C, H, W) (N: batch, C: channel, H: height, W: width) according to the channel first format, and the channel axis can be preset as the second axis (axis 1). If the artificial intelligence model processes single image data rather than in batch units, the input tensor has a shape of (C, H, W), and the channel axis can be preset as the first axis. Hereinafter, for convenience of explanation, a case where input/output tensors are processed in batch units will be described as an example. In the case of the TensorFlow framework, an input tensor has a shape of (N, H, W, C) according to the channel last format, and the channel axis can be preset as the last axis (e.g., the fourth axis in the case of a 4-dimensional tensor).

The channel axis in the present disclosure has been used for illustrative purposes for convenience of explanation, and can be interpreted to comprehensively include a feature axis. The feature axis may refer to an axis that implies multi-dimensional features of input/output data processed in an artificial intelligence model. In the case of the channel axis mainly disclosed in the present disclosure, it can be understood as a feature of an input/output tensor distinguished in a CNN-based artificial intelligence model, that is, an axis implying a channel. Furthermore, in the case of a transformer-based artificial intelligence model, that is, a Large Language Model (LLM), the feature axis of input/output data may correspond to a head axis and/or a neuron axis. A head axis may refer to a dimension that represents the number of attention heads that are branched in parallel and computed independently in multi-head attention, when an artificial intelligence model is implemented with a multi-head attention mechanism. A neuron axis may refer to a dimension of a feature vector output from each attention head, and can be used interchangeably with a hidden dimension.

In an embodiment, a channel axis tracing algorithm 1120 may refer to an algorithm that determines or estimates a dimension expressing the channel axis among the dimensions of tensors in an intermediate representation structure by tracing a bidirectional operation flow of an artificial intelligence model (e.g., the intermediate representation structure). The computing device 100 can store the dimension expressing the inferred channel axis through the channel axis tracing algorithm in a tensor of the intermediate representation structure. For example, the computing device 100 can bidirectionally trace the channel axes of intermediate tensors of intermediate operators connected between reference operators, based on the positions of the channel axes of input/output tensors of each of reference operators (reference modules or reference nodes) within the intermediate representation structure, to determine or estimate the positions of the channel axes of the intermediate tensors. That is, the computing device (100) can accurately identify the position of the channel axis on input/output tensors with just a single reference operator. The reference operator may include a linear transformation operator that performs a linear transformation-based operation such as a convolution operation, an affine transformation operation, or a matrix multiplication operation. The reference operator may correspond to an operator (a module or a node) that serves as a reference for tracing the position of the channel axis of input/output tensors of each of operators (modules or nodes) included in an artificial intelligence model (e.g., the intermediate representation structure). The position of the channel axis of an input/output tensor corresponding to the reference operator can be preset.

In an embodiment, the model editor 350 can generate an intermediate representation structure reflecting a channel axis tracing result by using the channel axis tracing result. The model editor 350 can generate an intermediate representation structure reflecting a channel axis tracing result by storing information about a channel axis included in the channel axis tracing result in a tensor of the intermediate representation structure.

In an embodiment, the computing device 100 can perform a dimension transformation 1140 in the intermediate representation structure by using the intermediate representation structure to which the channel axis tracing result is reflected. Accordingly, transformed (e.g., fixed) dimension information can be generated. The computing device 100 can fix dimensions of tensors within the intermediate representation structure to specific dimensions by utilizing the channel axis tracing result. For example, the computing device 100 can fix all tensors configured differently with 2, 3, 4, 5, and 6 dimensions to 3 dimensions.

In an embodiment, the computing device 100 can perform a channel axis transformation on the intermediate representation structure by using the intermediate representation structure to which the channel axis tracing result is reflected. Accordingly, transformed channel information can be generated. The computing device 100 can perform a channel axis transformation by using the inputs and outputs of the intermediate representation structure (e.g., the inputs/outputs of modules and/or the inputs/outputs of the intermediate representation structure graph). The computing device 100 can determine whether to align the axis constituting a channel to a channel-first or channel-last criterion based on the inputs and outputs of the intermediate representation structure. For example, if an input of the intermediate representation structure is configured in a channel-first form of B, C, H, W, but an output of the intermediate representation structure is configured in a channel-last form of B, H, W, C, the computing device 100 can change the position of the channel axis to either channel-first or channel-last to unify the position of the channel axis.

In an embodiment, the model editor 350 can generate an intermediate representation structure 1160 including static dimensions by using the transformed (e.g., fixed) dimension information. For example, a static dimension may mean that the dimensions (e.g., dimension values and/or dimension sizes) of tensors of the intermediate representation structure are fixed. The intermediate representation structure 1160 including static dimensions may mean that fixed dimension values are stored in the tensors of the intermediate representation structure.

In an embodiment, the model editor 350 can generate an intermediate representation structure 1165 including new channel axes by using the transformed channel information. For example, the intermediate representation structure 1165 including new channel axes may mean that information about changed or new channel axes is stored in the tensors of the intermediate representation structure.

Information related to these channel axes can be utilized by a compressor to modify modules and/or nodes, or by a graph optimizer to transform the dimension.

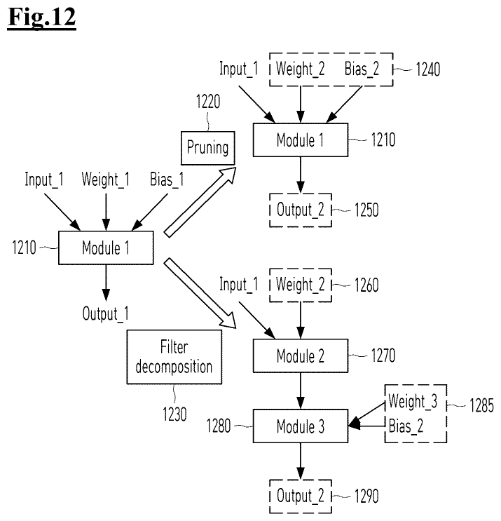

FIG. 12 illustrates an example in which a compression technique is applied to an intermediate representation structure according to an embodiment of the present disclosure.

The compressor in the present disclosure can support model lightweighting methods represented by pruning and filter decomposition. In the intermediate representation structure exemplified in FIG. 12, information specifying a module (or node) capable of lightweighting may be stored, and/or information regarding modules (or nodes) connected to the module (or node) capable of lightweighting may be stored.

In an embodiment, the computing device 100 can receive an intermediate representation structure as input and assign True or False to the value of prunable or decomposable for a module or node to which pruning and/or filter decomposition can be applied. If a pruning compression method is used, information regarding a connected module (or node) can also be stored in a tensor of the intermediate representation structure. The compressor can determine a pruning ratio or a filter decomposition rank according to the setting of a compression algorithm. The compressor can transmit the determined value to the model editor 350, allowing the model editor 350 to modify the intermediate representation structure based on the transmitted value. Accordingly, the number of filters on the intermediate representation structure is reduced, or the target module (or node) is changed to a plurality of modules (or nodes) to which filter decomposition is applied.

In the example of FIG. 12, a module 1210 on the intermediate representation structure is a targeted module on which a compression algorithm is to be performed, and Input_1, Weight_1, and Bias_1 can be input to the module 1210, and Output_1 can be output from the module 1210. For example, the module 1210 can correspond to an operator that performs a Convolution operation. For example, Input_1, Weight_1, Bias_1, and Output_1 can be stored in a tensor of the intermediate representation structure.

For example, when a pruning algorithm 1220 is applied to the module 1210, as indicated by reference numeral 1240, Weight_1 and Bias_1 can be changed to Weight_2 and Bias_2, and as indicated by reference numeral 1250, Output_1 can be changed to Output_2. In this example, even if the pruning algorithm 1220 is applied, the module 1210 and Input_1 can be maintained without being changed. When the pruning algorithm 1220 is applied to the module 1210, the intermediate representation structure can be modified or optimized in a form where the tensor is changed.

For example, when a filter decomposition algorithm 1230 is applied to the module 1210, the module 1210 can be changed to a module 1270 and a module 1280. The changed modules 1270 and 1280 can replace the operation of the module 1210. Also, when the filter decomposition algorithm 1230 is applied to the module 1210, Weight_1 and Bias_1 of the module 1210 can be changed, and Output_1 of the module 1210 can be changed. In this case, Input_1 of the module 1210 can be maintained without being changed. As exemplified in FIG. 12, as the filter decomposition algorithm 1230 is applied to the module 1210, Input_1 and Weight_2 1260 are input to the module 1270, the output of the module 1270 is input to the module 1280, and Output_2 1290 can be output by the module 1280 along with Weight_3 and Bias_2 1285. When the filter decomposition algorithm 1230 is applied to the module 1210, the intermediate representation structure can be modified or optimized in a form where the module and the tensor are changed.

In an additional embodiment, FIG. 12 exemplifies the modification of a module within an intermediate representation structure according to a compression algorithm, but modification of a node can also be applied within the scope of the technical features described in FIG. 12.

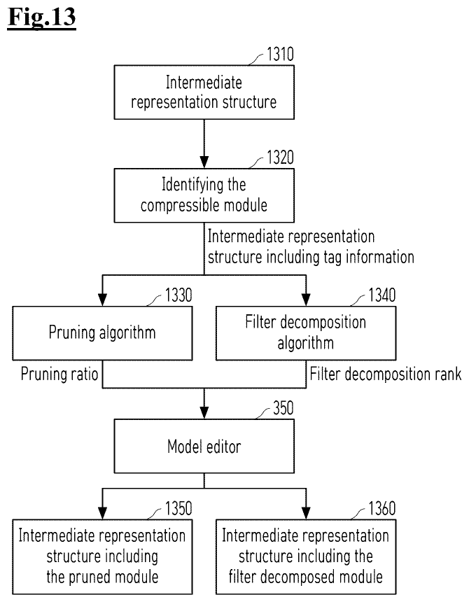

FIG. 13 illustrates an example in which a compression technique is applied to an intermediate representation structure according to an embodiment of the present disclosure.

The computing device 100 can obtain an intermediate representation structure 1310 and identify a compressible module on the intermediate representation structure 1310 (1320).

In an embodiment, information on prunable and/or decomposable can be stored in a module and/or a node of the intermediate representation structure 1310. This information can be generated by a compressor in the process where compression algorithms 1330 and 1340 are applied to the intermediate representation structure 1310. The compressor and/or the model editor 350 can generate an intermediate representation structure including tag information by storing identification information for a compressible module as tag information in a tensor. Additionally, such compression-related information can also be generated and stored in the process where the intermediate representation structure 1310 is generated.

In an embodiment, identification information and/or name information for modules and/or nodes considering the connection relationship within the intermediate representation structure 1310 can be stored in each of the modules and/or nodes of the intermediate representation structure 1310. Depending on the implementation aspect, it may also be possible to implement it in a form that includes information on prunable and/or decomposable only in the modules of the intermediate representation structure.

The pruning algorithm 1330 can determine a pruning ratio for the intermediate representation structure based on the setting value of the pruning algorithm and/or tag information of the intermediate representation structure.

The filter decomposition algorithm 1340 can determine a filter decomposition rank for the intermediate representation structure based on the setting value of the filter decomposition algorithm and/or tag information of the intermediate representation structure.

In an embodiment, the pruning ratio and/or the filter decomposition rank are transmitted to the model editor 350, and the model editor 350 can generate an intermediate representation structure to which compression is applied by modifying the intermediate representation structure using the transmitted information. For example, the model editor 350 can generate an intermediate representation structure 1350 including a pruned module by using the pruning ratio and/or tag information. For example, the model editor 350 can generate an intermediate representation structure 1350 including a filter-decomposed module by using the filter decomposition rank and/or tag information.

In an embodiment, the compressor can perform a platform-considered compression by using platform information (e.g., hardware information) stored in the intermediate representation structure 1310. For example, when increasing the number of output channels (Cout) of a neural network in a specific hardware, a phenomenon where inference latency does not increase linearly but remains constant in a specific section and then rapidly increases at a specific point can be considered in the compression process. As a compression algorithm considering such hardware characteristics is performed, optimized lightweighting assuming that the model is actually executed on the hardware can be achieved.

In an additional embodiment, FIG. 13 exemplifies the modification of a module within an intermediate representation structure according to a compression algorithm, but modification of a node can also be applied within the scope of the technical features described in FIG. 13.

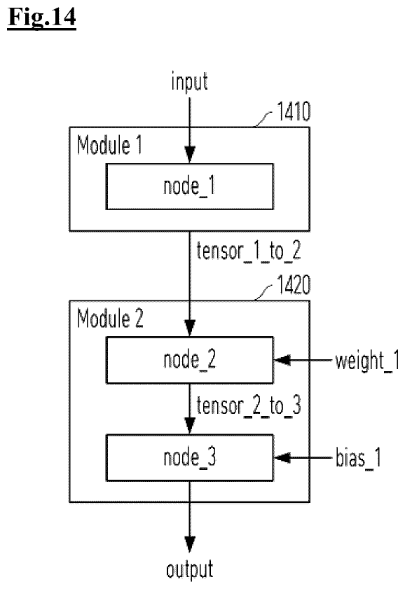

FIG. 14 illustratively shows an intermediate representation structure including tensor information, according to an embodiment of the present disclosure.

A module 1410 of the intermediate representation structure can receive “input” as input and include a node_1.

A module 1420 of the intermediate representation structure can receive tensor_1_to_2, which is an output of the module 1410, as input, and can receive weight_1 as input. The tensor_1_to_2 and the weight_1 are input to a node_2, processed by the node_2, and the node_2 can output a tensor_2_to_3. The tensor_2_to_3, which is an output of the node_2, and bias_1 are input to a node_3, and the node_3 can generate an output. This output corresponds to the output of the module 1420.

In FIG. 14, tensor_1_to_2, tensor_2_to_3, output, weight_1, and bias_1 are represented as tensors of the intermediate representation structure. These values can be stored and managed in tensors in the intermediate representation structure. The tensor_1_to_2, tensor_2_to_3, output, weight_1, and bias_1 can be targets for quantization. The tensor_1_to_2 is an output of the module 1410 and an activation leading to an input of the module 1420, and the weight_1 and bias_1 are learnable parameters that can be used in an operation process. While weight_1 and bias_1 are learnable parameters of the module 1420, they can also be input to the module 1420 because they are directly used in the operation of the module 1420. For example, weight_1 and bias_1 can be stored in the computing device 100 (e.g., memory) and called during the operation of the module 1420. In an embodiment of the present disclosure, not only inputs in a data flow but also learnable parameters such as weight_1 and bias_1 can be used together as inputs in an actual operation process. Tensors such as weight_1 and bias_1 are treated together as inputs of the intermediate representation structure from a computational or operational perspective. Each of these tensors can be configured to also store quantization information (e.g., scale and zero point, etc.).

In an embodiment, a situation may occur where the operation of the quantizer is skipped according to a result of the graph optimizer. For example, if two modules on the intermediate representation structure are changed into one module through the graph optimizer, the tensors between the two modules are included in one module, so quantization for these tensors may be skipped. For example, assume that the module 1420 in FIG. 14 is a result transformed from two modules through the graph optimizer. Under this assumption, tensor_2_to_3 between node_2 and node_3 can be set not to be quantized.

In an embodiment, if optimization of the intermediate representation structure is performed through the graph optimizer, a tensor (e.g., tensor_2_to_3 in FIG. 14) connecting nodes constituting a module of the intermediate representation structure can be configured not to have quantization information.

In an embodiment, when model optimization tools are applied or executed to the intermediate representation structure, quantization information can be stored in a tensor of the intermediate representation structure. Accordingly, in the preprocessing 810 of FIG. 8, an operation of removing a Q/DQ node and storing quantization information in a tensor can be performed.

In an embodiment, in a quantization and preprocessing process, a module (or a boundary of a module) of the intermediate representation structure can be used to distinguish between tensors to store quantization information and tensors not to store quantization information. For example, a boundary of a module can represent information related to the start and end of a module. For example, the computing device 100 can determine whether to store quantization information in a tensor based on whether the tensor to store quantization information is at the boundary of a module. Whether it is at the boundary of a module can include whether it is information input to and output from a module. For example, in the example of FIG. 14, tensor_1_to_2 can be considered a tensor at the boundary of a module because it is between the output of the module 1410 and the input of the module 1420. For example, in the example of FIG. 14, weight_1, bias_1, and output can be determined as targets for quantization or targets for storing quantization information (i.e., quantization information included in Q/DQ of an input model) because they are tensors related to the input and output of a module. For example, in the example of FIG. 14, tensor_2_to_3 is a tensor connecting nodes inside the module 1420, so it is not determined as a target for quantization, and quantization information is not stored in that tensor.

In an embodiment, when quantization through a quantizer is applied to the module 1420, a Q/DQ operator can be added to an operation flow related to inputs and outputs of the module 1420, or quantization information can be stored in tensors. In a quantization process, tensor_1_to_2, weight_1, and bias_1 can undergo Q/DQ operations and be used in calculations of the module 1420, or quantization information stored in tensors can be used in calculations.

In an embodiment, inside the module 1420, tensor_2_to_3 exists as an intermediate result between node_2 and node_3. The tensor_2_to_3 is an activation in tensor form, representing an intermediate calculation result of the module 1420. The Q/DQ operator and quantization information are applied to reflect quantization in the flow between modules. Therefore, the computing device 100 may not separately add a Q/DQ operator or store quantization information in tensor_2_to_3, which is an internal intermediate result of the module 1420.

In an embodiment, in a simulation process of a simulator, a Q/DQ node for an activation of the module 1420 of the intermediate representation structure can be added between the module 1410 and the module 1420, and to the output of the module 1420.

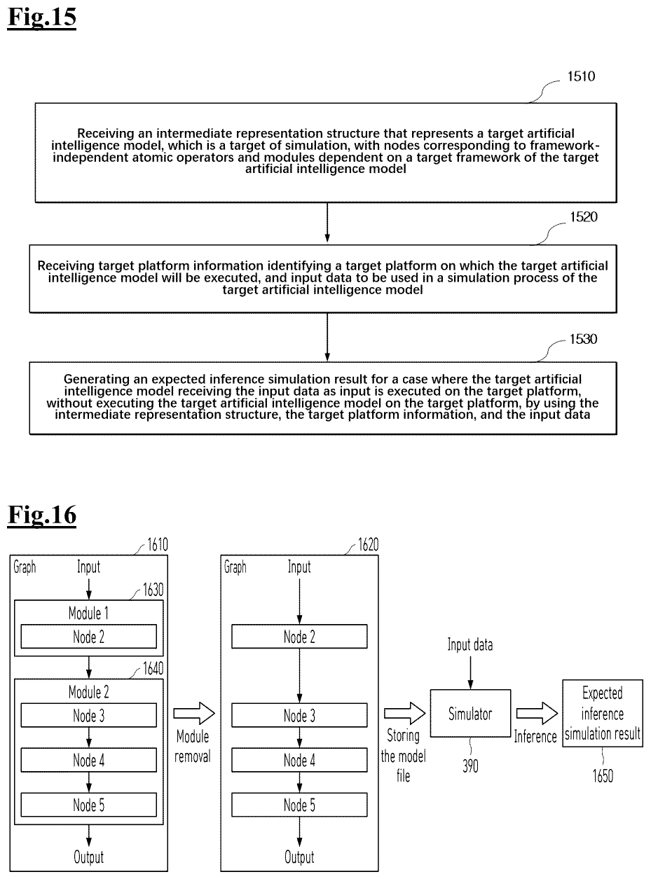

FIG. 15 is a flowchart illustratively showing a method for generating an expected inference simulation result according to an embodiment of the present disclosure.

Depending on implementation aspects, additional steps may be added to the flowchart in FIG. 15, or some steps in the flowchart in FIG. 15 may be omitted or changed.

Among the descriptions in FIG. 15, descriptions overlapping with the above-described descriptions will be replaced with the above-described descriptions.

In an embodiment, the computing device 100 can receive an intermediate representation structure that represents a target artificial intelligence model, which is a target of simulation, with nodes corresponding to framework-independent atomic operators and modules dependent on a target framework of the target artificial intelligence model (1510).

For example, the intermediate representation structure may include a source intermediate representation structure corresponding to a source artificial intelligence model, a target intermediate representation structure converted from the source intermediate representation structure, and an optimized intermediate representation structure to which performance transformation by model optimization tools has been applied.

The target artificial intelligence model in FIG. 15 can be defined as an artificial intelligence model that is a target of simulation. The target artificial intelligence model herein is intended to comprehensively include a source artificial intelligence model and/or an artificial intelligence model converted to fit a target framework from the source artificial intelligence model.

In an embodiment, the computing device 100 can receive target platform information identifying a target platform on which the target artificial intelligence model will be executed, and input data to be used in a simulation process of the target artificial intelligence model (1520).

For example, the target platform information may include target hardware information on which the target artificial intelligence model will be executed, target compiler information for connecting the target artificial intelligence model to the target hardware, and/or runtime information indicating an environment of the target hardware on which the target artificial intelligence model will be executed. For example, the target platform information can be received from a user terminal. For example, the target platform information may be pre-stored on the intermediate representation structure and extracted from the intermediate representation structure during the simulation process.

For example, the input data is input data used to generate an inference simulation result, and a simulation operation by a simulator can be performed using the input data. For example, the input data can be received from a user terminal. For example, the input data may include sample input data pre-stored in the computing device 100 or an external computing device.

In an embodiment, the target platform information can be used to perform a calibration operation of a quantizer. For example, the computing device 100 can determine a range of tensor values when inputting input data to the intermediate representation structure, based on the target platform information. The computing device 100 can determine quantization parameters for quantizing the target artificial intelligence model using the range of tensor values. The computing device 100 can generate a quantized intermediate representation structure by changing tensors within the intermediate representation structure based on the quantization parameters.

In an embodiment, the target platform information can be stored in modules, nodes, and/or tensors of the intermediate representation structure.

In an embodiment, the target platform information can be compared with platform information pre-stored in the intermediate representation structure. If, as a result of this comparison, the target platform information and the platform information pre-stored in the intermediate representation structure are different, the computing device 100 can change nodes constituting modules within the intermediate representation structure, or modules within the intermediate representation structure, or tensors within the intermediate representation structure, based on the target platform information. For example, the computing device 100 can change nodes and/or modules of the intermediate representation structure using information of nodes and/or modules supported by the target platform. For example, the computing device 100 can modify platform information stored in tensors within the intermediate representation structure to target platform information, so that the target platform information is stored within the intermediate representation structure. For example, the computing device 100 can add target platform information to platform information stored in tensors within the intermediate representation structure, so that the target platform information is added to the intermediate representation structure. Accordingly, the simulator can generate an expected inference simulation result for a case where the target artificial intelligence model receiving the input data as input is executed on the target platform, without actually executing the target artificial intelligence model on the target platform, by using the changed intermediate representation structure and the input data.

In another embodiment, the computing device 100 can add information about a target platform to an intermediate representation structure that does not have hardware information to be executed, and can generate an expected inference simulation result when the model is executed on the hardware, by using the intermediate representation structure with the added target platform information.

In another embodiment, the computing device 100 can receive an intermediate representation structure including hardware information on which an artificial intelligence model will be executed, and can generate a changed intermediate representation structure to be a target of simulation by modifying the received intermediate representation structure (e.g., modifying hardware information in the intermediate representation structure) using the target platform information.

In an embodiment, the computing device 100 can generate an expected inference simulation result for a case where the target artificial intelligence model receiving the input data as input is executed on the target platform, without executing the target artificial intelligence model on the target platform, by using the intermediate representation structure, the target platform information, and the input data (1530).

In an embodiment, the expected inference simulation result may mean output data generated by simulating a situation where input data is input after the artificial intelligence model is compiled and deployed to hardware. For example, the expected inference simulation result can be generated using platform information, the intermediate representation structure, and the input data. For example, the expected inference simulation result may include an expected performance assuming that the model is executed on the platform without performing a compilation operation. For example, the expected inference simulation result may include expected performance information and/or inference result information when the model is executed on the platform, without deploying the model to hardware and/or a compiler.

In an embodiment, the computing device 100 can generate at least one of target platform nodes and target platform modules supported by the target platform, by using the received target platform information. For example, the generated target platform nodes and/or target platform modules can correspond to quantization-related nodes and/or modules corresponding to the target platform. Quantization-related nodes and/or modules may include quantization nodes (or modules) and dequantization nodes (or modules).

In an embodiment, the computing device 100 can change the intermediate representation structure by using at least one of the target platform nodes and the target platform modules. For example, changing the intermediate representation structure may mean adding quantization nodes and dequantization nodes to the intermediate representation structure. For example, changing the intermediate representation structure may mean adding quantization modules and dequantization modules to the intermediate representation structure. This change of the intermediate representation structure is a procedure for implementing the execution of the target artificial intelligence model on the target platform on the intermediate representation structure. The change of the intermediate representation structure means adding quantization-related information of the target platform to the intermediate representation structure, and through this change of the intermediate representation structure, a simulation operation on the intermediate representation structure can be efficiently implemented without actually executing the actual model on the actual platform. For example, the target platform information can be used to determine positions where quantization nodes and dequantization nodes will be added to the intermediate representation structure.

In an embodiment, quantization modules (and/or nodes) and dequantization modules (and/or nodes) can be added to boundaries of modules and/or edges connecting modules within the intermediate representation structure.

In an embodiment, the position within the intermediate representation structure where quantization modules (and/or nodes) and dequantization modules (and/or nodes) will be added can have a correlation with the target platform information.

In an embodiment, the computing device 100 can generate an expected inference simulation result for a case where the target artificial intelligence model receiving the input data as input is executed on the target platform, without executing the target artificial intelligence model on the target platform, by using the changed intermediate representation structure and the input data.

In an embodiment, the computing device 100 can generate a simulation intermediate representation structure represented by connections of nodes, by maintaining nodes but removing modules on the intermediate representation structure. For example, as modules are removed on the intermediate representation structure, the simulation intermediate representation structure may have a graph structure indicating connection relationships of nodes. For example, the simulation intermediate representation structure can be generated by removing dependency relationships or hierarchical structures between modules and nodes. For example, the simulation intermediate representation structure may have a graph structure composed of nodes and edges connecting the nodes. The computing device 100 can generate an expected inference simulation result for a case where the target artificial intelligence model receiving the input data as input is executed on the target platform, without executing the target artificial intelligence model on the target platform, by using the simulation intermediate representation structure and the input data. For example, the simulator can perform inference in the unit of a node according to a connection order of nodes within the intermediate representation structure. For example, the simulator can perform simulation inference in the unit of a node.

In an embodiment, the computing device 100 can generate an expected inference simulation result by performing a node-by-node simulation on an intermediate representation structure including modules and nodes constituting the modules. For example, the simulator can perform inference node by node according to a connection order of nodes within the intermediate representation structure. For example, the simulator can perform simulation inference node by node. In this embodiment, when an intermediate representation structure composed of modules and nodes is used by a simulator, simulation can be performed considering connection relationships of nodes included within modules.

In an embodiment, the computing device 100 can generate a simulation intermediate representation structure by, after adding quantization-related information determined using the target platform to the intermediate representation structure to create a changed intermediate representation structure, removing modules within the changed intermediate representation structure. For example, a simulator or a model editor can generate a changed intermediate representation structure by adding quantization nodes and de-quantization nodes corresponding to the target platform to the intermediate representation structure, using the received target platform information. For example, a simulator or a model editor can generate a simulation intermediate representation structure represented by connections of nodes, by maintaining nodes but removing modules within the changed intermediate representation structure. For example, the simulator can output an expected inference simulation result for a case where the target artificial intelligence model receiving the input data as input is executed on the target platform, without executing the target artificial intelligence model on the target platform, by receiving the simulation intermediate representation structure and the input data as input.

In an embodiment, the computing device 100 can change the intermediate representation structure based on information about the target platform. In an embodiment, the computing device 100 can modify an intermediate representation structure that is a target of simulation using information about the target platform. For example, the computing device 100 can add nodes and/or modules corresponding to operators supportable by the target platform to the intermediate representation structure using the target platform information. For example, the computing device 100 can delete nodes and/or modules corresponding to operators not supportable by the target platform from the intermediate representation structure using the target platform information. Information about operators supportable by the target platform, information indicating a correspondence relationship between operators and nodes, and/or information indicating a correspondence relationship between operators and modules can be obtained using a database and/or a mapping table. The intermediate representation structure changed in this manner can be used to generate an expected inference simulation result by a simulator.

In an embodiment, the simulator can operate in conjunction with various model optimization tools. For example, the computing device 100 can generate an optimized intermediate representation structure by modifying nodes, modules, and/or tensors within the intermediate representation structure using model optimization tool(s). For example, the computing device 100 can delete at least one node (or module) among nodes (or modules) included in the intermediate representation structure, compress at least one node (or module) among nodes (or modules) included in the intermediate representation structure, or move at least one node among nodes included in the intermediate representation structure from a first module to a second module on the intermediate representation structure, by using a model optimization tool. The simulator can generate an optimized expected inference simulation result for a case where an optimized target artificial intelligence model receiving the input data as input is executed on the target platform, without executing the target artificial intelligence model on the target platform, by using the optimized intermediate representation structure and the input data. The simulator can change the optimized intermediate representation structure to perform simulation using the target platform information.

In an embodiment, the computing device 100 can compare a first simulation result for an optimized intermediate representation structure on which model optimization tools have been executed with a second simulation result for an intermediate representation structure on which model optimization tools have not been executed. For example, if a result of the comparison is degraded compared to an expected performance change prediction value for model optimization tools, or if it deviates from a range of the performance change prediction value, it can be determined to modify the expected performance change prediction value for the model optimization tools. For example, such a comparison result can control a scenario manager 310 to modify a transformation scenario identifying an application order of a plurality of model optimization tools. Furthermore, by comparing these simulation results, a technical effect can be achieved in that performance evaluation for optimization operations of model optimization tools for an artificial intelligence model can be performed in a resource-efficient manner.

In an embodiment, the simulator can operate in conjunction with a converter. The computing device 100 can convert the intermediate representation structure into a target artificial intelligence model using the converter. The computing device 100 can generate an expected inference simulation result when the converted target artificial intelligence model is executed through the input data on the target platform, by using the converted target artificial intelligence model, the target platform information, and the input data. For example, such an inference simulation result can be generated by performing a simulation of the converted target artificial intelligence model using runtime in the simulator. In addition, the computing device 100 can generate benchmark results (e.g., performance information such as latency, memory usage, and/or accuracy) by executing the converted target artificial intelligence model using input data on actual hardware, by using the converted target artificial intelligence model, the target platform information, and the input data. In this embodiment, the computing device 100 can compare a simulation result or benchmark result for the converted target artificial intelligence model with an expected inference simulation result generated using an intermediate representation structure of the target artificial intelligence model before conversion. Through this comparison, it may be possible to evaluate whether the performance of the simulator on the intermediate representation structure can accurately simulate the results of actual execution on the actual platform. Through this comparison, self-evaluation of the simulator's performance can be performed, and through this evaluation, performance updates for the simulator can be easily made.

An artificial intelligence model may require optimization and transformation to suit specific hardware or compilers. This transformation process may include optimization through a compiler, optimization utilizing hardware accelerators, and data type conversion (e.g., FP32→INT8). However, such methods require individual optimization processes for each hardware, and it may be difficult to uniformly compare or predict the results of various optimization methods across various hardware and compilers. Predicting simulation results in a hardware environment other than pre-measured hardware and comparing simulation results in various environments can be said to be a solution not existing in the art.

In conventional techniques, lightweighting or optimization tools for artificial intelligence models must be developed separately for each of various hardware and compilers. Furthermore, to compare and evaluate inference results of lightweighting or optimization tools, actual compilation must be performed and the artificial intelligence model must be executed on hardware. A technique according to an embodiment of the present disclosure can have technical effects of unifying various intermediate representations into a universally usable intermediate representation structure, allowing lightweighting or optimization tools to operate based on the unified intermediate representation structure, and simulating expected inference results based on the unified intermediate representation structure without the process of deploying compilers and hardware. Through such simulation, inference results can be easily estimated in a resource-efficient manner, and lightweighting or optimization performance can be predicted.

Conventional techniques have not presented a function to compare execution results through pre-simulation in various hardware and compiler environments. A simulation technique according to an embodiment of the present disclosure can predict inference results in various hardware and compiler environments without a compilation process. Accordingly, a technical effect can be achieved in that effective and computationally resource-efficient support for artificial intelligence model optimization can be provided.

FIG. 16 illustratively shows a process for generating an expected inference simulation result using an intermediate representation structure according to an embodiment of the present disclosure.

In an embodiment, the computing device 100 can receive or obtain an intermediate representation structure 1610 that is an object of simulation. The intermediate representation structure 1610 may include a module 1630 composed of Node_2 and a module 1640 composed of Node_3, Node_4, and Node_5.

In an embodiment, the computing device 100 can generate a changed intermediate representation structure 1620 by removing modules on the intermediate representation structure 1610. As exemplified in FIG. 16, the changed intermediate representation structure 1620 can be generated, as the module 1630 and the module 1640 are removed from the intermediate representation structure 1610. The nodes and the connection relationships between the nodes in the changed intermediate representation structure 1620 are maintained during this change process.

In an embodiment, the computing device 100 can store a model file corresponding to the changed intermediate representation structure. A simulator 390 can generate an expected inference simulation result 1650 by using the changed intermediate representation structure. The simulator can generate the expected inference simulation result 1650 by using the changed intermediate representation structure and input data. The simulator 390 can generate the expected inference simulation result 1650 by using the changed intermediate representation structure, target platform information, and input data.

In an embodiment, the intermediate representation structure may have a modularized structure that is grouped into module units based on Input or Output. Modules in the modularized structure correspond to information mapped to operators of an artificial intelligence model. The simulator 390 according to an embodiment of the present disclosure is configured to perform inference in node units, not in module units. Considering the inference unit of the simulator 390, a graph structure 1620 generated by removing information about modules within the intermediate representation structure and connecting nodes can be generated during an operation process of the simulator 390. The computing device 100 can obtain output data for input data by operating the simulator 390 to use the generated graph structure 1620.

In an additional embodiment, depending on implementation aspects, the computing device 100 may generate the expected inference simulation result 1650 by identifying nodes within modules without removing the modules 1630 and 1640 in the intermediate representation structure 1610, and by performing inference operations in node units.

In an embodiment, the simulator 390 can be configured to confirm expected inference results of the intermediate representation structure suitable for combinations of various hardware and compilers. The simulator 390 can predict the performance (e.g., results after framework conversion, results after converting, results after lightweighting, and/or results after optimization) of an artificial intelligence model using the intermediate representation structure without performing a compilation process and a hardware deployment process.

In an embodiment, the simulator 390 can receive target platform information, the intermediate representation structure, and input data of the artificial intelligence model as input, and based thereon, after the artificial intelligence model is compiled and deployed, can simulate a situation where the input data is processed and output an expected inference simulation result 1650.

In an embodiment, the intermediate representation structure may not include information about hardware and a compiler. In this embodiment, when performing simulation using hardware and/or compiler information, the computing device 100 can dynamically generate modules and/or nodes associated with hardware and/or a compiler. The computing device 100 can make the intermediate representation structure reflect hardware and/or a compiler by adding the generated modules and/or nodes to the intermediate representation structure. As the intermediate representation structure reflecting hardware and/or a compiler is simulated by the simulator 390, an accurate inference simulation result can be generated without actually using hardware and a compiler.

In an embodiment, the computing device 100 can change the intermediate representation structure for simulation and can generate an expected simulation result in a manner that efficiently uses computing resources, using the changed intermediate representation structure.

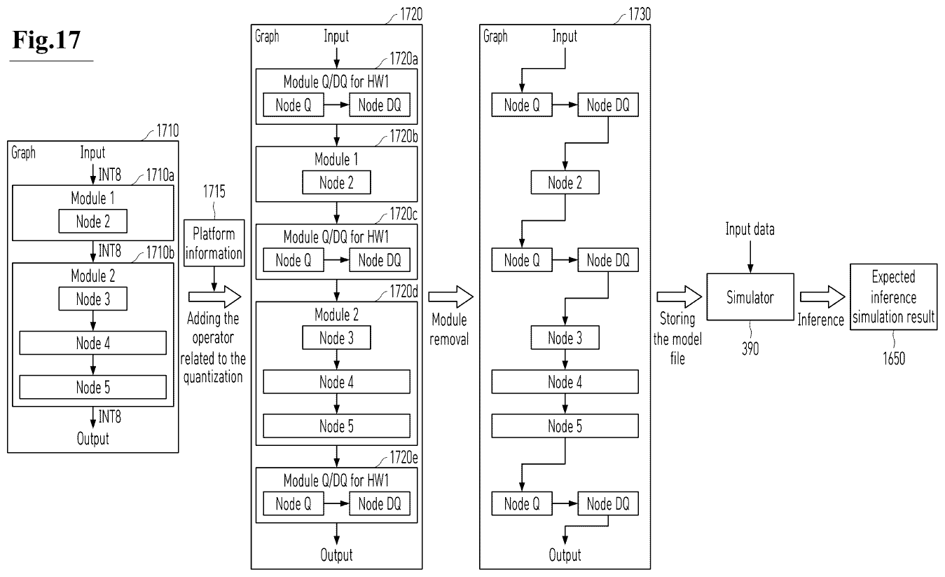

FIG. 17 illustratively shows a process for generating an expected inference simulation result considering platform information according to an embodiment of the present disclosure.

In an embodiment, the computing device 100 can receive or obtain an intermediate representation structure 1710 that is an object of simulation. The intermediate representation structure 1710 may include a module 1710a composed of Node_2 and a module 1710b composed of Node_3, Node_4, and Node_5. Node 2 of the module 1710a of the intermediate representation structure 1710 is in a state where optimization has been applied by a model optimization tool (e.g., a compressor and/or a model optimizer). Node 3 of the module 1710b of the intermediate representation structure 1710 is in a state where optimization has been applied by a model optimization tool (e.g., a compressor and/or a model optimizer). A tensor of the intermediate representation structure 1710 can be configured to include INT8 as quantization information. For example, the intermediate representation structure 1710 can represent a state where quantization from Float 32 to INT8 has been applied by a model optimization tool (e.g., a quantizer and/or a compressor).

In an embodiment, the computing device 100 can receive platform information 1715. The platform information 1715 can identify hardware information and/or compiler information in a process of performing simulation.

In an embodiment, the computing device 100 can set quantization-related information to be reflected in an operation process of the simulator 390 by transforming quantization-related information stored in a tensor into the form of quantization-related modules and/or nodes. As exemplified in FIG. 17, the computing device 100 can generate a changed intermediate representation structure 1720 by adding quantization-related operators (modules and/or nodes) reflecting quantization-related information to the intermediate representation structure 1710. As exemplified in FIG. 17, the computing device 100 can add quantization-related operators (modules and/or nodes) corresponding to the platform information to the intermediate representation structure 1710 in a process of generating the changed intermediate representation structure 1720 to reflect the platform information 1715 in the intermediate representation structure 1710. Accordingly, the intermediate representation structure 1720 reflecting the platform information and the quantization information can be generated.

In an embodiment, the intermediate representation structure 1720 can be configured to have a connection structure of a module 1720a including a quantization node and a dequantization node for hardware 1 (HW1) included in the platform information 1715, a module 1720b corresponding to the module 1710a, a module 1720c including a quantization node and a dequantization node for hardware 1 (HW1), a module 1720d corresponding to the module 1710b, and a module 1720e including a quantization node and a dequantization node for hardware 1 (HW1). In this manner, as changes are performed on the intermediate representation structure 1710, considering the platform information 1715 on which the artificial intelligence model of the intermediate representation structure will be executed and the quantization information of the artificial intelligence model, the intermediate representation structure 1720 changed for simulation can be generated.

In an embodiment, the computing device 100 can generate a simulation intermediate representation structure 1730 by removing modules 1720a, 1720b, 1720c, 1720d, and 1720e on the intermediate representation structure 1720. As exemplified in FIG. 17, the simulation intermediate representation structure 1730 can be generated as the modules 1720a, 1720b, 1720c, 1720d, and 1720e are removed from the intermediate representation structure 1720. The simulation intermediate representation structure 1730 can be generated such that nodes and connection relationships between nodes in the intermediate representation structure 1720 are maintained during this change process.

In an embodiment, the computing device 100 can store a model file corresponding to the simulation intermediate representation structure. The simulator 390 can generate an expected inference simulation result 1650 by using the simulation intermediate representation structure. The simulator 390 can generate the expected inference simulation result 1650 by using the simulation intermediate representation structure and input data. The simulator 390 can generate the expected inference simulation result 1650 by using the simulation intermediate representation structure, target platform information, and input data.

FIG. 17 illustratively shows a process of performing simulation considering platform information when an intermediate representation structure composed of modules is executed in environments of various hardware and/or compilers. For example, in the case of a tensor having an INT8 data type, it can be represented in the form of fake quantization through a process of quantization and dequantization. For example, to represent that operation methods differ by platform (e.g., by HW), for simulation on HW1, a Q/DQ module (and/or node) for HW1 can be added to the intermediate representation structure, and for simulation on HW2, a Q/DQ module (and/or node) for HW2 can be added to the intermediate representation structure. As such, simulation according to an embodiment of the present disclosure can simulate an operation process on different HWs through configurations of different nodes (and/or configurations of modules) on the intermediate representation structure.

In an embodiment, the simulator 390 can be configured to simulate inference results of a model in various platform environments. In an additional embodiment, the simulator 390 may be configured to perform actual inference of a model in various platform environments. Data input to the simulator 390 can be prepared to match the input of the artificial intelligence model. For example, if an artificial intelligence model A has three inputs and each of these inputs is defined as follows, the input data for the execution of the simulator 390 can be prepared with data identical to the shape and datatype of the three inputs.
name: input_1, shape: [1, 3, 224, 224], datatype: float32
name: input_2, shape: [1, 3, 224, 224], datatype: float32
name: input_3, shape: [1, 256], datatype: int16

For example, the format of a data file for expressing data may include various formats such as numpy, bin, and raw.

In an embodiment, it is necessary to load a file from a location where a data file is stored and mount it in memory, and it is necessary to map a plurality of input data to inputs of an artificial intelligence model. For example, when input_1_data, input_2_data, and input_3_data are prepared to match input_1, input_2, and input_3, mapping can be performed such that input_1_data is used for input_1 and input_2_data is used for input_2. In an additional embodiment, preprocessing such as normalization for input data may be performed depending on implementation aspects.

In an embodiment, after an artificial intelligence model and mapped input data are input into a simulator 390, the simulator 390 can operate to simulate the operation of the artificial intelligence model in hardware. Even if the same operator is executed, code can be executed such that a method of processing quantization values (e.g., round), a data type for processing the operation of the operator, and precision, etc., operate as similarly as possible to execution in hardware.

In an embodiment, input data is input into an artificial intelligence model, and a result after executing code or an operator combination that simulates hardware can be output through the simulator 390. The number of output data corresponding to the number of outputs of the artificial intelligence model can be generated by the simulator 390. Output data of the simulator 390 can also be output in a form mapped to a plurality of output names, similar to input data.

In an embodiment, the simulator 390 can compare errors for a plurality of models by utilizing a function that obtains an inference result for one model. The simulator 390 can compare output data obtained as a result of inference with the same input data for a plurality of models having the same inputs and outputs, such as before and after application of a model optimization tool. The simulator 390 can compare a plurality of models using metrics that measure errors such as SNR and MSE, and through this comparison, a technical effect can be achieved in that the difference in accuracy of models before and after lightweighting or optimization can be evaluated. Through this simulation method, inference results for the intermediate representation structure can be obtained in various platform environments (e.g., hardware environments), and furthermore, inference results for various data types can also be efficiently obtained.

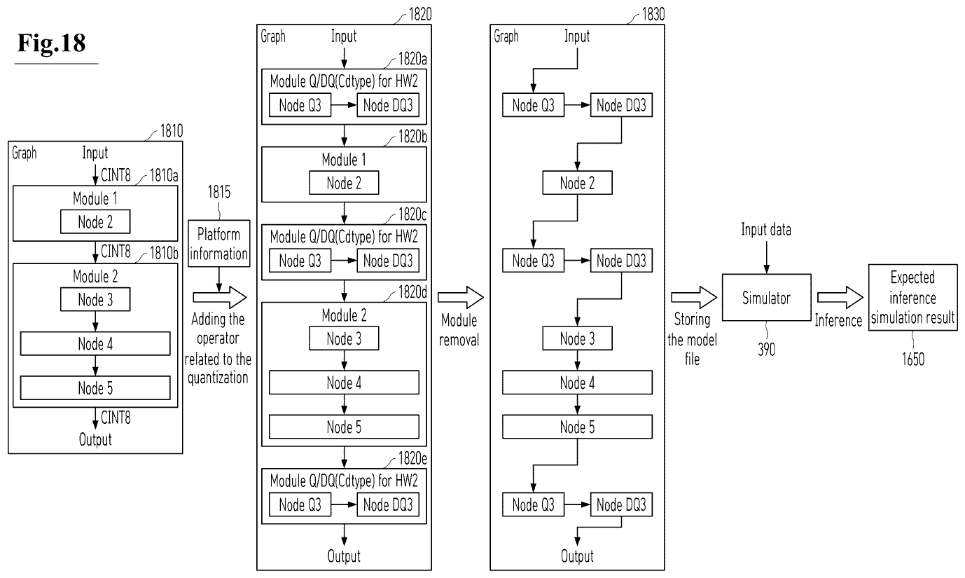

FIG. 18 illustratively shows a process for generating an expected inference simulation result considering platform information and data type information according to an embodiment of the present disclosure.

FIG. 18 illustratively shows a process for generating an expected inference result for an artificial intelligence model having a custom data type of CINT8 in hardware 2 (HW2).

As exemplified in FIG. 18, if a custom data type rather than a general data type such as INT8 constitutes an artificial intelligence model, the computing device 100 can operate the simulator 390 by adding a Q/DQ module (and/or node) that can express the custom data type to the intermediate representation structure.

In an embodiment, the computing device 100 can receive or obtain an intermediate representation structure 1810 that is an object of simulation. The intermediate representation structure 1810 may include a module 1810a composed of Node_2 and a module 1810b composed of Node_3, Node_4, and Node_5. Node 2 of the module 1810a of the intermediate representation structure 1810 is in a state where optimization has been applied by a model optimization tool (e.g., a compressor and/or a model optimizer). Node 3 of the module 1810b of the intermediate representation structure 1810 is in a state where optimization has been applied by a model optimization tool (e.g., a compressor and/or a model optimizer). A tensor of the intermediate representation structure 1810 can be configured to include CINT8 (Compressed INT8) as quantization information. For example, CINT8 is an 8-bit integer type but can represent a data type that supports additional compression. For example, CINT8 is the same representation as INT8 but can represent a data structure for increasing efficiency by further compression regarding a storage method and/or an operation method in hardware, etc. Data type information for this CINT8 can be stored in a tensor of the intermediate representation structure 1810.

In an embodiment, the computing device 100 can receive platform information 1815. The platform information 1815 can identify hardware information and/or compiler information in a process of performing simulation.

In an embodiment, the computing device 100 can set quantization-related information to be reflected in an operation process of the simulator 390 by transforming quantization-related information (e.g., CINT8) stored in a tensor into the form of quantization-related modules and/or nodes. As exemplified in FIG. 18, the computing device 100 can generate a changed intermediate representation structure 1820 by adding quantization-related operators (modules and/or nodes) reflecting quantization-related information to the intermediate representation structure 1810. As exemplified in FIG. 18, the computing device 100 can add quantization-related operators (modules and/or nodes) corresponding to the platform information to the intermediate representation structure 1810 in a process of generating the changed intermediate representation structure 1820 to reflect the platform information 1815 in the intermediate representation structure 1810. Accordingly, the intermediate representation structure 1820 reflecting the platform information and the quantization information can be generated.

In an embodiment, the intermediate representation structure 1820 can be configured to have a connection structure of a module 1820a including a CINT8 quantization node and a dequantization node for hardware 2 (HW2) included in the platform information 1815, a module 1820b corresponding to the module 1810a, a module 1820c including a CINT8 quantization node and a dequantization node for hardware 2 (HW2), a module 1820d corresponding to the module 1810b, and a module 1820e including a CINT8 quantization node and a dequantization node for hardware 2 (HW2). In this manner, as changes are performed on the intermediate representation structure 1810, considering both the platform information 1815 on which the artificial intelligence model of the intermediate representation structure will be executed and the quantization information of the artificial intelligence model, the intermediate representation structure 1820 changed for simulation can be generated. As a non-limiting example, this modification of the intermediate representation structure can be implemented through communication between the simulator 390 and the model editor 350.

In an embodiment, the computing device 100 can generate a simulation intermediate representation structure 1830 by removing modules 1820a, 1820b, 1820c, 1820d, and 1820e on the intermediate representation structure 1820. As exemplified in FIG. 18, the simulation intermediate representation structure 1830 can be generated as the modules 1820a, 1820b, 1820c, 1820d, and 1820e are removed from the intermediate representation structure 1820. The simulation intermediate representation structure 1830 can be generated in a form where nodes and connection relationships between nodes in the intermediate representation structure 1820 are maintained during this change process.

In an embodiment, the computing device 100 can store a model file corresponding to the simulation intermediate representation structure. The simulator 390 can generate an expected inference simulation result 1650 by using the simulation intermediate representation structure. The simulator can generate the expected inference simulation result 1650 by using the simulation intermediate representation structure and input data. The simulator 390 can generate the expected inference simulation result 1650 by using the simulation intermediate representation structure, target platform information, and input data.

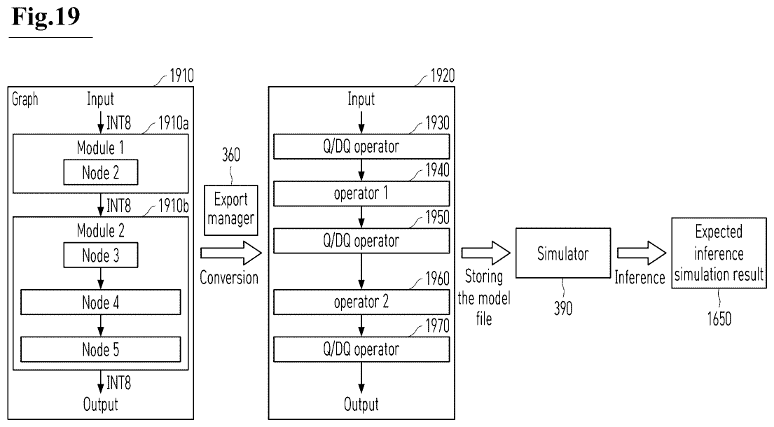

FIG. 19 illustrates an example of applying a simulator after conversion into a target artificial intelligence model, according to an embodiment of the present disclosure.

In an embodiment, the simulator 390 may be linked with the execution results of various model optimization tools to generate a simulation result. An expected inference simulation result may be generated for various target platform environments from the intermediate representation structure that has been lightened or optimized by the execution results of the various model optimization tools. Modules, nodes, and/or tensors within the intermediate representation structure may be changed as lightening and optimization are performed through the various model optimization tools. A simulation is performed on the intermediate representation structure to reflect the execution result of the model optimization tool, and accordingly, the inference results of the artificial intelligence model when driven on hardware before and after the application of the model optimization tool may be effectively compared.

In an embodiment, the simulator 390 may be linked with a calibration process of a quantizer for quantization. The calibration process may refer to a process of obtaining the min and max values of each tensor when input data is fed into the intermediate representation structure. Through this calibration process, the quantizer may determine a quantization parameter. In the calibration process, the values obtained from a tensor may vary depending on which hardware is being simulated. The simulator 390 may be used in the calibration process, and a simulation result may be generated as the intermediate representation structure is changed to fit the target hardware for use in the simulator 390. Calibration may be performed using this simulation result.

The example of FIG. 19 exemplarily illustrates a simulation process for comparing performance after an intermediate representation structure composed of module units is converted into a target artificial intelligence model.

In an embodiment, the computing device 100 may receive or obtain an intermediate representation structure 1910 to be simulated. The intermediate representation structure 1910 may include a module 1910a composed of Node_2 and a module 1910b composed of Node_3, Node_4, and Node_5. Node 2 of the module 1910a of the intermediate representation structure 1910 is in a state where optimization has been applied by a model optimization tool (e.g., a compressor and/or a model optimizer). Node 3 of the module 1910b of the intermediate representation structure 1910 is in a state where optimization has been applied by a model optimization tool (e.g., a compressor and/or a model optimizer). A tensor of the intermediate representation structure 1910 may be configured to include INT8 as quantization information. For example, INT8 may represent an 8-bit integer data type.

In an embodiment, the computing device 100 may convert the intermediate representation structure 1910 into a target artificial intelligence model 1920 supportable by a target framework, using an export manager 360.

In an embodiment, the computing device 100 may convert quantization-related information (e.g., INT8) stored in a tensor into the form of a quantization-related operator, thereby setting the quantization-related information to be reflected in the operation process of the simulator 390.

In an embodiment, the computing device 100 may perform the conversion into the target artificial intelligence model by adding a Q/DQ operator 1930 before a first module 1910a, converting the first module 1910a into an operator 1 1940, adding a Q/DQ operator 1950 between the first module 1910a and a second module 1910b, converting the second module 1910b into an operator 2 1960, and adding a Q/DQ operator 1960 after the second module 1910b.

In an embodiment, the computing device 100 may store a model file corresponding to the target artificial intelligence model. The simulator 390 may generate an expected inference simulation result 1650 using the target artificial intelligence model. The simulator 390 may generate the expected inference simulation result 1650 using the target artificial intelligence model and a target platform. The simulator 390 may generate the expected inference simulation result 1650 by executing the target artificial intelligence model on the target platform.

In an embodiment, the simulator 390, which simulates a result of running on hardware using the intermediate representation structure, may generate inference result output data using a runtime environment after the intermediate representation structure is converted into a target intermediate representation structure corresponding to a target framework.

In an embodiment, the simulator 390, which simulates a result of running on hardware using the intermediate representation structure, may generate inference result output data using a runtime environment after the intermediate representation structure is converted into a target artificial intelligence model corresponding to a target framework.

In an embodiment, the computing device 100 may also generate inference result output data by transmitting the target artificial intelligence model and input data to an actual platform environment using a benchmarker and then running a runtime on the actual hardware. Through such a benchmarker, the actual inference speed on the actual hardware may be measured.

In an embodiment, the computing device 100 may compare the output data after performing inference on the intermediate representation structure with the simulator 390 and the output data after running a model compiled into the target artificial intelligence model with a runtime on a server or a local personal computer. The computing device 100 may use this comparison result to evaluate whether the simulator 390 accurately simulates the result of running on hardware. The computing device 100 may compare the output data after performing inference on the intermediate representation structure with the simulator 390 and the output data after running with a runtime on actual hardware through the benchmarker. The computing device 100 may use this comparison result to evaluate whether the simulator 390 accurately simulates the result of running on hardware.

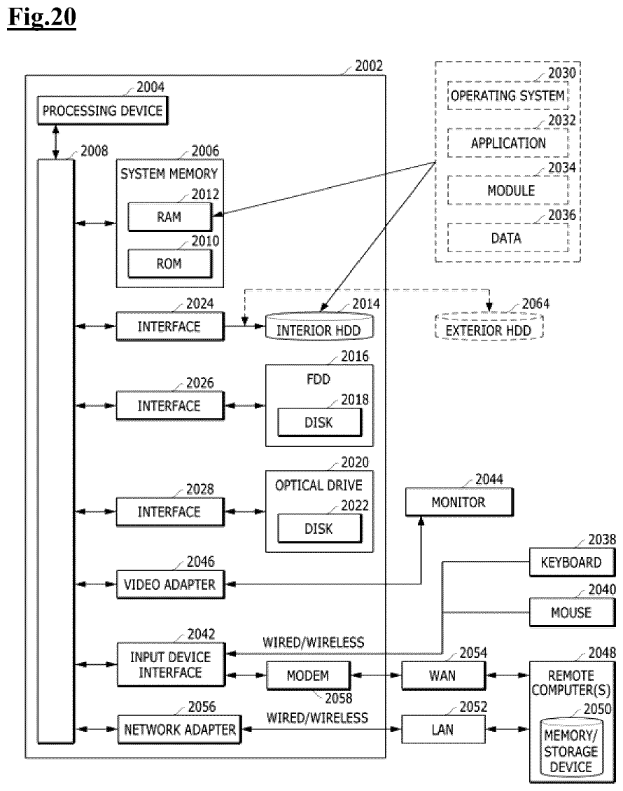

FIG. 20 is a simplified and general schematic diagram of an exemplary computing environment of a computing device in which embodiments of the present disclosure may be implemented.

In the present disclosure, the computing device, the computing apparatus, the computer, the component, the system or the unit includes a routine, a procedure, a program, a component, and a data structure that perform a specific task or implement a specific abstract data type. Further, it will be well appreciated by those skilled in the art that the methods presented by the present disclosure can be implemented by other computer system configurations including a personal computer, a handheld computing device, microprocessor-based or programmable home appliances, and others (the respective devices may operate in connection with one or more associated devices) as well as a single-processor or multi-processor computing device, a mini computer, and a main frame computer.

The embodiments described in the present disclosure may also be implemented in a distributed computing environment in which predetermined tasks are performed by remote processing devices connected through a communication network. In the distributed computing environment, the program module may be positioned in both local and remote memory storage devices.

The computing device generally includes various computer readable media. Media accessible by the computer may be computer readable media regardless of types thereof and the computer readable media include volatile and non-volatile media, transitory and non-transitory media, and mobile and non-mobile media. As a non-limiting example, the computer readable media may include both computer readable storage media and computer readable transmission media.

The computer readable storage media include volatile and non-volatile media, transitory and non-transitory media, and mobile and non-mobile media implemented by a predetermined method or technology for storing information such as a computer readable instruction, a data structure, a program module, or other data. The computer readable storage media include a RAM, a ROM, an EEPROM, a flash memory or other memory technologies, a CD-ROM, a digital video disk (DVD) or other optical disk storage devices, a magnetic cassette, a magnetic tape, a magnetic disk storage device or other magnetic storage devices or predetermined other media which may be accessed by the computer or may be used to store desired information, but are not limited thereto.

The computer readable transmission media generally implement the computer readable instruction, the data structure, the program module, or other data in a carrier wave or a modulated data signal such as other transport mechanism and include all information transfer media. The term “modulated data signal” means a signal acquired by setting or changing at least one of characteristics of the signal so as to encode information in the signal. As a non-limiting example, the computer readable transmission media include wired media such as a wired network or a direct-wired connection and wireless media such as acoustic, RF, infrared and other wireless media. A combination of any media among the aforementioned media is also included in a range of the computer readable transmission media.

An exemplary environment 2000 that implements various aspects of the present disclosure including a computer 2002 is shown and the computer 2002 includes a processing device 2004, a system memory 2006, and a system bus 2008. The computer 2002 in the present disclosure may be used intercompatibly with the computing device 100. The system bus 2008 connects system components including the system memory 2006 (not limited thereto) to the processing device 2004. The processing device 2004 may be a predetermined processor among various commercial processors. A dual processor and other multi-processor architectures may also be used as the processing device 2004.

The system bus 2008 may be any one of several types of bus structures which may be additionally interconnected to a local bus using any one of a memory bus, a peripheral device bus, and various commercial bus architectures. The system memory 2006 includes a read only memory (ROM) 2010 and a random access memory (RAM) 2012. A basic input/output system (BIOS) is stored in the non-volatile memories 2010 including the ROM, the EPROM, the EEPROM, and the like and the BIOS includes a basic routine that assists in transmitting information among components in the computer 2002 at a time such as in-starting. The RAM 2012 may also include a high-speed RAM including a static RAM for caching data, and the like.

The computer 2002 also includes an internal hard disk drive (HDD) 2014 (for example, EIDE and SATA), an external hard disk drive (e.g., USB, Thunderbolt and/or eSATA) 2064, a magnetic floppy disk drive (FDD) 2016 (for example, for reading from or writing in a mobile diskette 2018), SSD and an optical disk drive 2020 (for example, for reading a CD-ROM disk 2022 or reading from or writing in other high-capacity optical media such as the DVD). The hard disk drive 2014, the magnetic disk drive 2016, and the optical disk drive 2020 may be connected to the system bus 2008 by a hard disk drive interface 2024, a magnetic disk drive interface 2026, and an optical drive interface 2028, respectively. An interface 2024 for implementing an exterior drive includes at least one of a universal serial bus (USB) and an IEEE 1394 interface technology or both of them.

The drives and the computer readable media associated therewith provide non-volatile storage of the data, the data structure, the computer executable instruction, and others. In the case of the computer 2002, the drives and the media correspond to storing of predetermined data in an appropriate digital format. In the description of the computer readable storage media, the mobile optical media such as the HDD, the mobile magnetic disk, and the CD or the DVD are mentioned, but it will be well appreciated by those skilled in the art that other types of storage media readable by the computer such as a zip drive, a magnetic cassette, a flash memory card, a cartridge, and others may also be used in an exemplary operating environment and further, the predetermined media may include computer executable commands for executing the methods of the present disclosure.

Multiple program modules including an operating system 2030, one or more application programs 2032, other program module 2034, and program data 2036 may be stored in the drive and the RAM 2012. All or some of the operating system, the application, the module, and/or the data may also be cached in the RAM 2012. It will be well appreciated that the present disclosure may be implemented in operating systems which are commercially usable or a combination of the operating systems.

A user may input instructions and information in the computer 2002 through one or more wired/wireless input devices, for example, pointing devices such as a keyboard 2038 and a mouse 2040. Other input devices (not illustrated) may include a microphone, an IR remote controller, a joystick, a game pad, a stylus pen, a touch screen, and others. These and other input devices are often connected to the processing device 2004 through an input device interface 2042 connected to the system bus 2008, but may be connected by other interfaces including a parallel port, an IEEE 1394 serial port, a game port, a USB port, an IR interface, and others.

A monitor 2044 or other types of display devices are also connected to the system bus 2008 through interfaces such as a video adapter 2046, and the like. In addition to the monitor 2044, the computer generally includes a speaker, a printer, and other peripheral output devices (not illustrated).

The computer 2002 may operate in a networked environment by using a logical connection to one or more remote computers including remote computer(s) 2048 through wired and/or wireless communication. The remote computer(s) 2048 may be a workstation, a server computer, a router, a personal computer, a portable computer, a micro-processor based entertainment apparatus, a peer device, or other general network nodes and generally includes multiple components or all of the components described with respect to the computer 2002, but only a memory storage device 2050 is illustrated for brief description. The illustrated logical connection includes a wired/wireless connection to a local area network (LAN) 2052 and/or a larger network, for example, a wide area network (WAN) 2054. The LAN and WAN networking environments are general environments in offices and companies and facilitate an enterprise-wide computer network such as Intranet, and all of them may be connected to a worldwide computer network, for example, the Internet.

When the computer 2002 is used in the LAN networking environment, the computer 2002 is connected to a local network 2052 through a wired and/or wireless communication network interface or an adapter 2056. The adapter 2056 may facilitate the wired or wireless communication to the LAN 2052 and the LAN 2052 also includes a wireless access point installed therein in order to communicate with the wireless adapter 2056. When the computer 2002 is used in the WAN networking environment, the computer 2002 may include a modem 2058, is connected to a communication server on the WAN 2054, or has other means that configure communication through the WAN 2054 such as the Internet, etc. The modem 2058 which may be an internal or external and wired or wireless device is connected to the system bus 2008 through the serial port interface 2042. In the networked environment, the program modules described with respect to the computer 2002 or some thereof may be stored in the remote memory/storage device 2050. It will be well known that an illustrated network connection is exemplary and other means configuring a communication link among computers may be used.

The computer 2002 performs an operation of communicating with predetermined wireless devices or entities which are disposed and operated by the wireless communication, for example, the printer, a scanner, a desktop and/or a portable computer, a portable data assistant (PDA), a communication satellite, predetermined equipment or place associated with a wireless detectable tag, and a telephone. This at least includes wireless fidelity (Wi-Fi) and Bluetooth wireless technology. Accordingly, communication may be a predefined structure like the network in the related art or just ad hoc communication between at least two devices.

It will be appreciated that a specific order or a hierarchical structure of steps in the presented processes is one example of exemplary accesses. It will be appreciated that the specific order or the hierarchical structure of the steps in the processes within the scope of the present disclosure may be rearranged based on design priorities. Method claims provide elements of various steps in a sample order, but the method claims are not limited to the presented specific order or hierarchical structure.

What is claimed is:

1. A method, performed by a computing device, for generating an expected inference simulation result of an artificial intelligence model, the method comprising:
receiving an intermediate representation structure that represents a target artificial intelligence model which is an object of a simulation, with a node corresponding to an atomic operator independent of a framework and a module dependent on a target framework of the target artificial intelligence model, wherein the intermediate representation structure has a hierarchical structure in which one or more nodes constitute the module;
receiving target platform information for identifying a target platform on which the target artificial intelligence model is to be executed and input data to be used in a simulation process of the target artificial intelligence model; and
generating an expected inference simulation result for a case where the target artificial intelligence model with the input data as an input is to be executed on the target platform, without executing the target artificial intelligence model on the target platform, by using the intermediate representation structure, the target platform information, and the input data.

2. The method of claim 1, wherein the generating the expected inference simulation result comprises:
generating at least one of a target platform node and a target platform module supported on the target platform, by using the received target platform information;
changing the intermediate representation structure by using the at least one of the target platform node and the target platform module; and
generating the expected inference simulation result for a case where the target artificial intelligence model with the input data as an input is to be executed on the target platform, without executing the target artificial intelligence model on the target platform, by using the changed intermediate representation structure and the input data.

3. The method of claim 2, wherein the target platform module comprises a quantization node and a dequantization node, in a structure where an output of the quantization node corresponding to the target platform and an input of the dequantization node corresponding to the target platform are connected to each other.

4. The method of claim 1, wherein the generating the expected inference simulation result comprises:
changing the intermediate representation structure, by generating a quantization node and a dequantization node corresponding to the target platform by using the received target platform information, and adding the quantization node and the dequantization node to the intermediate representation structure; and
generating the expected inference simulation result for a case where the target artificial intelligence model with the input data as an input is to be executed on the target platform, without executing the target artificial intelligence model on the target platform, by using the changed intermediate representation structure and the input data,
wherein a position where the quantization node and the dequantization node are to be added on the intermediate representation structure is determined by using the received target platform information.

5. The method of claim 1, wherein the generating the expected inference simulation result comprises:
generating a simulation intermediate representation structure represented by a connection of nodes, by maintaining nodes and removing modules on the intermediate representation structure; and
generating the expected inference simulation result for a case where the target artificial intelligence model with the input data as an input is to be executed on the target platform, without executing the target artificial intelligence model on the target platform, by using the simulation intermediate representation structure and the input data.

6. The method of claim 5, wherein the simulation intermediate representation structure is a graph structure composed of a node and an internal edge connecting nodes.

7. The method of claim 1, wherein the expected inference simulation result is generated by a scheme of performing inference in a unit of node according to a connection order of nodes within the intermediate representation structure.

8. The method of claim 1, wherein the generating the expected inference simulation result comprises:
generating a changed intermediate representation structure by adding a quantization node and a dequantization node corresponding to the target platform to the intermediate representation structure by using the received target platform information;
generating a simulation intermediate representation structure represented by a connection of nodes, by maintaining nodes and removing modules within the changed intermediate representation structure; and
generating the expected inference simulation result for the case where the target artificial intelligence model with the input data as an input is to be executed on the target platform, without executing the target artificial intelligence model on the target platform, by using a simulator with the simulation intermediate representation structure and the input data as an input.

9. The method of claim 1, wherein the intermediate representation structure is a graph structure comprising a node, a tensor connecting nodes, a module configured with one or more nodes, and a tensor connecting modules.

10. The method of claim 1, wherein the intermediate representation structure further comprises a tensor representing inputs and outputs, a weight, and an activation of modules on the intermediate representation structure, and
a module of the intermediate representation structure comprises a combination of nodes corresponding to a minimum unit of atomic operators universally applicable to a plurality of frameworks.

11. The method of claim 1, wherein the generating the expected inference simulation result comprises:
comparing platform information stored in the intermediate representation structure and the target platform information;
when the stored platform information and the target platform information are different as a result of the comparing, changing a node constituting a module within the intermediate representation structure, or the module within the intermediate representation structure, or a tensor within the intermediate representation structure, based on the target platform information; and
generating the expected inference simulation result for a case where the target artificial intelligence model with the input data as an input is to be executed on the target platform, without executing the target artificial intelligence model on the target platform, by using the intermediate representation structure to which the change is applied and the input data.

12. The method of claim 1, wherein the target platform information comprises target hardware information on which the target artificial intelligence model is to be executed, target compiler information for connecting the target artificial intelligence model to a target hardware, and runtime information representing an environment of the target hardware on which the target artificial intelligence model is to be executed.

13. The method of claim 1, wherein the generating the expected inference simulation result comprises:
generating a changed intermediate representation structure by adding to the intermediate representation structure at least one of a node supportable on the target platform and a module including the supportable node, or deleting from the intermediate representation structure a node unsupportable on the target platform and a module including the unsupportable node, by using the received target platform information; and
generating the expected inference simulation result for a case where the target artificial intelligence model with the input data as an input is to be executed on the target platform, without executing the target artificial intelligence model on the target platform, by using the changed intermediate representation structure and the input data.

14. The method of claim 1, further comprising:
generating an optimized intermediate representation structure by modifying a combination of nodes within the intermediate representation structure by using a model optimization tool comprising at least one of a compressor, a graph optimizer, and a quantizer,
wherein the generating the expected inference simulation result comprises generating an optimized expected inference simulation result for a case where an optimized target artificial intelligence model with the input data as an input is to be executed on the target platform, without executing the target artificial intelligence model on the target platform, by using the optimized intermediate representation structure and the input data.

15. The method of claim 14, wherein the generating the optimized intermediate representation structure comprises:
deleting at least one node among nodes included in the intermediate representation structure, compressing at least one node among the nodes included in the intermediate representation structure, or moving at least one node among the nodes included in the intermediate representation structure from a first module to a second module on the intermediate representation structure.

16. The method of claim 14, further comprising:
generating a performance evaluation result for an optimization of the target artificial intelligence model, by comparing the optimized expected inference simulation result generated by using the optimized intermediate representation structure and the expected inference simulation result generated by using the intermediate representation structure.

17. The method of claim 1, further comprising:
converting the intermediate representation structure into the target artificial intelligence model by using a model converter;
generating an expected inference simulation result or a benchmark result for a case where the input data and the target artificial intelligence model are to be executed on the target platform and in a target framework of the target artificial intelligence model, by using the converted target artificial intelligence model and the input data; and
comparing the expected inference simulation result generated by using the intermediate representation structure and the inference simulation result or the benchmark result.

18. The method of claim 1, further comprising:
determining a range of a tensor value when the input data is input to the intermediate representation structure, based on the target platform information;
determining a quantization parameter for quantizing the target artificial intelligence model, by using the range of the tensor value; and
generating a quantized intermediate representation structure by changing a tensor within the intermediate representation structure based on the quantization parameter,
wherein the generating the expected inference simulation result comprises:
generating the expected inference simulation result for a case where a quantized target artificial intelligence model with the input data as an input is to be executed on the target platform, without executing the target artificial intelligence model on the target platform, by using the quantized intermediate representation structure, the target platform information, and the input data.

19. A non-transitory computer-readable medium storing a computer program that, when executed by a computing device, causes the computing device to perform operations for generating an expected inference simulation result of an artificial intelligence model, the operations comprising:
receiving an intermediate representation structure that represents a target artificial intelligence model which is an object of a simulation, with a node corresponding to an atomic operator independent of a framework and a module dependent on a target framework of the target artificial intelligence model, wherein the intermediate representation structure has a hierarchical structure in which one or more nodes constitute the module;
receiving target platform information for identifying a target platform on which the target artificial intelligence model is to be executed and input data to be used in a simulation process of the target artificial intelligence model; and
generating an expected inference simulation result for a case where the target artificial intelligence model with the input data as an input is to be executed on the target platform, without executing the target artificial intelligence model on the target platform, by using the intermediate representation structure, the target platform information, and the input data.

20. A computing device for generating an expected inference simulation result of an artificial intelligence model, the computing device comprising:
at least one processor, wherein the processor is configured to perform operations comprising:
receiving an intermediate representation structure that represents a target artificial intelligence model which is an object of a simulation, with a node corresponding to an atomic operator independent of a framework and a module dependent on a target framework of the target artificial intelligence model, wherein the intermediate representation structure has a hierarchical structure in which one or more nodes constitute the module;
receiving target platform information for identifying a target platform on which the target artificial intelligence model is to be executed and input data to be used in a simulation process of the target artificial intelligence model; and
generating an expected inference simulation result for a case where the target artificial intelligence model with the input data as an input is to be executed on the target platform, without executing the target artificial intelligence model on the target platform, by using the intermediate representation structure, the target platform information, and the input data.
